(19) United States
(12) Patent Application Publication
(10) Pub. No.: US 2026/0314127 A1
(43) Pub. Date: Oct. 8, 2026

(54) LIGHT-EMITTING ASSEMBLY AND DISPLAY SUBSTRATE

(71) Applicants: Beijing BOE Technology Development Co., Ltd., Beijing (CN); BOE TECHNOLOGY GROUP CO., LTD., Beijing (CN)

(72) Inventors: Yanan NIU, Beijing (CN); Shuang SUN, Beijing (CN); Jing NIU, Beijing (CN); Wei WANG, Beijing (CN); Bin QIN, Beijing (CN); Jinyu REN, Beijing (CN); Hongwei TIAN, Beijing (CN)

(73) Assignees: Beijing BOE Technology Development Co., Ltd., Beijing (CN); BOE TECHNOLOGY GROUP CO., LTD., Beijing (CN)

(21) Appl. No.: 18/996,436

(22) PCT Filed: Sep. 19, 2023
(86) PCT No.: PCT/CN2023/119704

§ 371 Date: Jan. 17, 2025

(51) Int. Cl. H10H 20/851; H10H 20/831; H10H 29/01; H10H 29/80; H10H 29/85; H10H 29/853; H10H 29/855

(52) U.S. Cl. CPC H10H 20/8514; H10H 20/831; H10H 29/012; H10H 29/0361; H10H 29/0362; H10H 29/8321; H10H 29/8517; H10H 29/853; H10H 29/8552

(57) ABSTRACT

Provided is a light-emitting assembly. The light-emitting assembly includes a plurality of light-emitting units, wherein each of the plurality of light-emitting units includes a first semiconductor layer, a light-emitting layer, and a second semiconductor layer that are laminated; a color-converting portion, disposed on a side, away from the light-emitting layer, of the first semiconductor layer; a common electrode layer, disposed between the first semiconductor layer and the color-converting portion, electrically connected to the first semiconductor layer, and connected to at least two of the plurality of light-emitting units; first electrodes, disposed on a side, away from the light-emitting layer, of the second semiconductor layer and electrically connected to the second semiconductor layer, the first electrodes being in one-to-one correspondence with the plurality of light-emitting units; and a first encapsulation layer, at least enclosing sidewalls of the plurality of light-emitting units.

### CROSS-REFERENCE TO RELATED APPLICATION

This application is a U.S. national stage of international application No. PCT/CN2023/119704, filed on Sep. 19, 2023, the disclosure of which is herein incorporated by reference in its entirety.

### TECHNICAL FIELD

The present disclosure relates to the field of display technologies, and in particular, relates to a light-emitting assembly and a method for manufacturing the same, a light-emitting chip, and a display substrate.

### BACKGROUND

A display panel includes a display backplane and a plurality of light-emitting assemblies connected to the display backplane. The display backplane supplies drive signals to the plurality of light-emitting assemblies, such that the plurality of light-emitting assemblies emit light to achieve image display.

### SUMMARY

Embodiments of the present disclosure provide a light-emitting assembly and a display substrate. The technical solutions are as follows.

In some embodiments of the present disclosure, a light-emitting assembly is provided. The light-emitting assembly includes:
a plurality of light-emitting units, wherein each of the plurality of light-emitting units includes a first semiconductor layer, a light-emitting layer, and a second semiconductor layer that are laminated;
a color-converting portion, disposed on a side, away from the light-emitting layer, of the first semiconductor layer;
a common electrode layer, disposed between the first semiconductor layer and the color-converting portion, electrically connected to the first semiconductor layer, and connected to at least two of the plurality of light-emitting units;
first electrodes, disposed on a side, away from the light-emitting layer, of the second semiconductor layer and electrically connected to the second semiconductor layer, the first electrodes being in one-to-one correspondence with the plurality of light-emitting units; and
a first encapsulation layer, at least enclosing sidewalls of the plurality of light-emitting units;
wherein in a thickness direction of the light-emitting layer, a distance between the first electrodes and the common electrode layer is less than a span of the first encapsulation layer in the thickness direction.

In some embodiments, the light-emitting assembly further includes a color-converting assembly, wherein the color-converting assembly includes the color-converting portion;
for each of the plurality of light-emitting units, the first encapsulation layer exposes the first semiconductor layer from a side, facing towards the color-converting portion, of the first semiconductor layer, such that the first semiconductor layer is electrically connected to the common electrode layer; and
a target region is present between the first encapsulation layer and the color-converting assembly, and the light-emitting assembly further includes a filling layer, wherein the filling layer is disposed in the target region, and a side, close to the color-converting assembly, of the filling layer is coplanar with an end, close to the color-converting assembly, of the first encapsulation layer.

In some embodiments, the filling layer is made of a conductive material, an opening is defined in a portion, between any adjacent two of the plurality of light-emitting units, in the first encapsulation layer, and the filling layer is exposed from the opening; and
the light-emitting assembly further includes second electrodes, wherein at least part of each of the second electrodes is disposed in the opening, and each of the second electrodes is connected to the common electrode layer via the filling layer exposed from the opening.

In some embodiments, the filling layer includes a first end face in contact with the common electrode layer and a second end face in contact with a side, away from the color-converting assembly, of the first encapsulation layer, wherein the first end face is coplanar with the end, close to the color-converting assembly, of the first encapsulation layer; and
the filling layer further includes a first side face, wherein the first side face is in contact with a portion, surrounding each of at least two of the plurality of light-emitting units, in the first encapsulation layer.

In some embodiments, the light-emitting assembly further includes a color-converting assembly, wherein the color-converting assembly includes the color-converting portion,
and the color-converting assembly further includes:
a retaining wall structure, wherein the retaining wall structure defines a plurality of first accommodation spaces, wherein each of the plurality of first accommodation spaces corresponds to a light-emitting region of one of the plurality of light-emitting units, and the color-converting portion is at least disposed in the plurality of first accommodation spaces, and is configured to convert colors of light emitted by the plurality of light-emitting units;
a light-shielding layer, wherein the light-shielding layer defines a plurality of second accommodation spaces, wherein each of the plurality of second accommodation spaces corresponds to one of the plurality of first accommodation spaces; and
a light-filtering portion, wherein the light-filtering portion is at least disposed in the plurality of second accommodation spaces, and is configured to transmit light converted by the color-converting portion;
wherein the retaining wall structure includes a first portion in an edge region of the plurality of light-emitting units and a second portion between any adjacent two of the plurality of light-emitting units, wherein a height of the second portion is less than a height of the first portion, and a difference between the height of the first portion and the height of the second portion is 10% to 90% of a thickness of each of the plurality of light-emitting units.

In some embodiments, for each of the plurality of light-emitting units, the second semiconductor layer is exposed from a side, away from the color-converting portion, of the first encapsulation layer, such that the second semiconductor layer is electrically connected to the first electrodes; and
a distance between an end portion, close to the color-converting portion, of the first encapsulation layer and the color-converting portion is less than a distance between a face, close to the color-converting portion, of the first semiconductor layer and the color-converting portion.

In some embodiments, a face on the side, away from the color-converting portion, of the first encapsulation layer is coplanar with a side, away from the color-converting portion, of the second semiconductor layer.

In some embodiments, light-emitting assembly further includes a blocking portion at least surrounding the sidewall of the each of the plurality of light-emitting units, wherein the blocking portion absorbs or reflects light emitted by the plurality of light-emitting units, and
the blocking portion surrounding the sidewall of the each of the plurality of light-emitting units is disposed on a side, away from the plurality of light-emitting units, of the first encapsulation layer.

In some embodiments, the blocking portion is made of a metal, and the blocking portion is further disposed on a side, away from the color-converting portion, of the second semiconductor layer and is electrically connected to the second semiconductor layer; wherein
the blocking portion is one of the first electrodes;
the blocking portion is disposed on a side, away from the second semiconductor layer, of the first electrodes, and is electrically connected to the second semiconductor layer over the first electrodes; or
the blocking portion is disposed between the first electrodes and the second semiconductor layer, and is electrically connected to the second semiconductor layer and the first electrodes.

In some embodiments, the first encapsulation layer includes a plurality of separate encapsulation patterns, wherein each of the plurality of encapsulation patterns encloses the sidewall of one of the plurality of light-emitting units.

In some embodiments, the common electrode layer includes a first electrode region and a second electrode region, wherein
the first electrode region is disposed in a groove defined by the first encapsulation layer and the first semiconductor layer, and the second electrode region surrounds the first electrode region.

In some embodiments, the light-emitting assembly further includes a planarization layer between the common electrode layer and the color-converting portion, wherein the planarization layer fills the groove; and
the light-emitting assembly further includes a color-converting assembly, wherein the color-converting assembly includes the color-converting portion, and
the color-converting assembly further includes:
a retaining wall structure, wherein the retaining wall structure defines a plurality of first accommodation spaces, wherein each of the plurality of first accommodation spaces corresponds to a light-emitting region of one of the plurality of light-emitting units, and the color-converting portion is at least disposed in the plurality of first accommodation spaces, and is configured to convert colors of light emitted by the plurality of light-emitting units;
a light-shielding layer, wherein the light-shielding layer defines a plurality of second accommodation spaces, wherein each of the plurality of second accommodation spaces corresponds to one of the plurality of first accommodation spaces; and
a light-filtering portion, wherein the light-filtering portion is at least disposed in the plurality of second accommodation spaces, and is configured to transmit light converted by the color-converting portion.

In some embodiments, a distance between a face, away from the common electrode layer, of the planarization layer and the first electrodes is greater than or equal to the span of the first encapsulation layer in the thickness direction, and in the thickness direction of the light-emitting layer, a ratio h3:h4 of the distance h3 between the first electrodes and the common electrode layer to the span h4 of the first encapsulation layer in the thickness direction ranges from 0.1 to 0.9.

In some embodiments, at least part of the color-converting portion is disposed in the groove, and is disposed on a side, away from the plurality of light-emitting units, of the common electrode layer.

In some embodiments, light-emitting assembly further includes a color-converting assembly, wherein the color-converting assembly includes the color-converting portion, and
the color-converting assembly further includes:
a retaining wall structure, wherein the retaining wall structure defines a plurality of first accommodation spaces, wherein each of the plurality of first accommodation spaces corresponds to a light-emitting region of one of the plurality of light-emitting units, and the color-converting portion is at least disposed in the plurality of first accommodation spaces, and is configured to convert colors of light emitted by the plurality of light-emitting units;
a light-shielding layer, wherein the light-shielding layer defines a plurality of second accommodation spaces, wherein each of the plurality of second accommodation spaces corresponds to one of the plurality of first accommodation spaces; and
a light-filtering portion, wherein the light-filtering portion is at least disposed in the plurality of second accommodation spaces, and is configured to transmit light converted by the color-converting portion.

In some embodiments, the common electrode layer includes a first electrode region and a second electrode region, wherein the first electrode region is disposed in a groove defined by the first encapsulation layer and the first semiconductor layer, and the second electrode region surrounds the first electrode region;
at least part of the color-converting portion is disposed in the groove, and is disposed on a side, away from the plurality of light-emitting units, of the common electrode layer; and
the light-emitting assembly includes the a color-converting assembly, wherein the color-converting assembly includes the color-converting portion, and further includes:
a retaining wall structure, wherein the retaining wall structure defines a plurality of first accommodation spaces, wherein each of the plurality of first accommodation spaces corresponds to a light-emitting region of one of the plurality of light-emitting units, and the color-converting portion is at least disposed in the plurality of first accommodation spaces, and is configured to convert colors of light emitted by the plurality of light-emitting units;
a light-shielding layer, wherein the light-shielding layer defines a plurality of second accommodation spaces, wherein each of the plurality of second accommodation spaces corresponds to one of the plurality of first accommodation spaces; and
a light-filtering portion, wherein the light-filtering portion is at least disposed in the plurality of second accommodation spaces, and is configured to transmit light converted by the color-converting portion;
wherein the retaining wall structure wraps edges of the plurality of encapsulation patterns, and the common electrode layer is disposed between the retaining wall structure and the color-converting portion.

In some embodiments, the color-converting portion includes a red color-converting portion, a green color-converting portion, and a blue color-converting portion; wherein the red color-converting portion is configured to convert the light emitted by the plurality of light-emitting units to red light, the green color-converting portion is configured to convert the light emitted by the plurality of light-emitting units to green light, and the blue color-converting portion is configured to convert the light emitted by the plurality of light-emitting units to blue light; and
the light-filtering portion includes a red light-filtering portion, a green light-filtering portion, and a blue light-filtering portion, wherein the red light-filtering portion is configured to transmit light converted by the red color-converting portion, the green light-filtering portion is configured to transmit light converted by the green color-converting portion, and the blue light-filtering portion is configured to transmit light converted by the blue color-converting portion;
wherein the light emitted by the plurality of light-emitting units is blue light, the blue color-converting portion is a transparent portion, and the blue light-filtering portion is a transparent portion.

In some embodiments, the retaining wall structure is made of a non-transparent material.

In some embodiments of the present disclosure, a display substrate is provided. The display substrate includes: a drive backplane and a plurality of light-emitting assemblies in above embodiments, wherein
the drive backplane is configured to bear the plurality of light-emitting assemblies, and supply drive signals to the plurality of light-emitting assemblies; and
one of the plurality of light-emitting assemblies composes a light-emitting chip, wherein light-emitting chips are arranged on the drive backplane in an array, and are electrically connected to the drive backplane; or some of the plurality of light-emitting assemblies compose a light-emitting chip, and a bonding layer between adjacent light-emitting assemblies in the plurality of light-emitting assemblies is continuous.

In some embodiments of the present disclosure, a display substrate is provided. The display substrate includes: a drive backplane and a plurality of light-emitting assemblies as defined in above embodiments, wherein the drive backplane is configured to bear the plurality of light-emitting assemblies, and supply drive signals to the plurality of light-emitting assemblies.

### BRIEF DESCRIPTION OF DRAWINGS

For clearer description of the technical solutions according to the embodiments of the present disclosure, the following briefly introduces the accompanying drawings required for describing the embodiments. Apparently, the accompanying drawings in the following description show merely some embodiments of the present disclosure, and persons of ordinary skill in the art may still derive other drawings from these accompanying drawings without creative efforts.

FIG. 1 is a schematic structural diagram of a light-emitting assembly according to some embodiments of the present disclosure;

FIG. 2 is a schematic structural diagram of a light-emitting assembly according to some embodiments of the present disclosure;

FIG. 3 is a schematic structural diagram of a light-emitting assembly according to some embodiments of the present disclosure;

FIG. 4 is a schematic structural diagram of a light-emitting assembly according to some embodiments of the present disclosure;

FIG. 5 is a schematic structural diagram of a light-emitting assembly according to some embodiments of the present disclosure;

FIG. 6 is a schematic structural diagram of a drive unit according to some embodiments of the present disclosure;

FIG. 7 is a flowchart of a method for manufacturing a light-emitting assembly according to some embodiments of the present disclosure;

FIG. 8 is a schematic flowchart of a method for manufacturing a light-emitting assembly according to some embodiments of the present disclosure;

FIG. 9 is a top view of a flowchart of some processes in a method for manufacturing a light-emitting assembly according to some embodiments of the present disclosure;

FIG. 10 is a flowchart of acquiring a first target structure according to some embodiments of the present disclosure;

FIG. 11 is a schematic flowchart of acquiring a first target structure according to some embodiments of the present disclosure;

FIG. 12 is a top view of a flowchart of acquiring a first target structure according to some embodiments of the present disclosure;

FIG. 13 is a flowchart of acquiring a second target structure according to some embodiments of the present disclosure;

FIG. 14 is a schematic flowchart of acquiring a second target structure according to some embodiments of the present disclosure;

FIG. 15 is a top view of a flowchart of acquiring a second target structure according to some embodiments of the present disclosure;

FIG. 16 is a schematic diagram of a plurality of sparsely arranged light-emitting assemblies according to some embodiments of the present disclosure;

FIG. 17 is a top view of FIG. 16;

FIG. 18 is a top view of FIG. 16;

FIG. 19 is a schematic diagram of a plurality of closely arranged light-emitting assemblies according to some embodiments of the present disclosure;

FIG. 20 is a top view of FIG. 19;

FIG. 21 is a flowchart of a method for manufacturing a display substrate according to some embodiments of the present disclosure;

FIG. 22 is a schematic flowchart of some processes in a method for manufacturing a display substrate according to some embodiments of the present disclosure;

FIG. 23 is a flowchart of a method for manufacturing a light-emitting assembly according to some embodiments of the present disclosure;

FIG. 24 is a schematic flowchart of a method for manufacturing a light-emitting assembly according to some embodiments of the present disclosure;

FIG. 25 is a top view of a flowchart of some processes in a method for manufacturing a light-emitting assembly according to some embodiments of the present disclosure;

FIG. 26 is a flowchart of acquiring a first target structure according to some embodiments of the present disclosure;

FIG. 27 is a schematic flowchart of acquiring a first target structure according to some embodiments of the present disclosure;

FIG. 28 is a top view of a flowchart of acquiring a first target structure according to some embodiments of the present disclosure;

FIG. 29 is a flowchart of acquiring a second target structure according to some embodiments of the present disclosure;

FIG. 30 is a schematic flowchart of acquiring a second target structure according to some embodiments of the present disclosure;

FIG. 31 is a top view of a flowchart of acquiring a second target structure according to some embodiments of the present disclosure;

FIG. 32 is a schematic diagram of a plurality of sparsely arranged light-emitting assemblies according to some embodiments of the present disclosure;

FIG. 33 is a schematic diagram of a plurality of closely arranged light-emitting assemblies according to some embodiments of the present disclosure;

FIG. 34 is a flowchart of a method for manufacturing a display substrate according to some embodiments of the present disclosure;

FIG. 35 is a schematic flowchart of some processes in a method for manufacturing a display substrate according to some embodiments of the present disclosure;

FIG. 36 is a flowchart of a method for manufacturing a light-emitting assembly according to some embodiments of the present disclosure;

FIG. 37 is a schematic flowchart of a method for manufacturing a light-emitting assembly according to some embodiments of the present disclosure;

FIG. 38 is a top view of a flowchart of some processes in a method for manufacturing a light-emitting assembly according to some embodiments of the present disclosure;

FIG. 39 is a top view of a flowchart of some processes in a method for manufacturing a light-emitting assembly according to some embodiments of the present disclosure

FIG. 40 is a flowchart of acquiring a first target structure according to some embodiments of the present disclosure;

FIG. 41 is a schematic flowchart of acquiring a first target structure according to some embodiments of the present disclosure;

FIG. 42 is a top view of a flowchart of acquiring a first target structure according to some embodiments of the present disclosure;

FIG. 43 is a flowchart of a method for manufacturing a light-emitting assembly according to some embodiments of the present disclosure;

FIG. 44 is a schematic flowchart of a method for manufacturing a light-emitting assembly according to some embodiments of the present disclosure;

FIG. 45 is a top view of a flowchart of some processes in a method for manufacturing a light-emitting assembly according to some embodiments of the present disclosure;

FIG. 46 is a flowchart of acquiring a first target structure according to some embodiments of the present disclosure;

FIG. 47 is a schematic flowchart of acquiring a first target structure according to some embodiments of the present disclosure;

FIG. 48 is a top view of a flowchart of acquiring a first target structure according to some embodiments of the present disclosure;

FIG. 49 is a flowchart of a method for manufacturing a light-emitting assembly according to some embodiments of the present disclosure;

FIG. 50 is a schematic flowchart of a method for manufacturing a light-emitting assembly according to some embodiments of the present disclosure;

FIG. 51 is a top view of a flowchart of some processes in a method for manufacturing a light-emitting assembly according to some embodiments of the present disclosure;

FIG. 52 is a top view of a light-emitting assembly according to some embodiments of the present disclosure;

FIG. 53 is a top view of a light-emitting assembly according to some embodiments of the present disclosure;

FIG. 54 is a top view of a light-emitting assembly according to some embodiments of the present disclosure;

FIG. 55 is a locally schematic structural diagram of a display substrate according to some embodiments of the present disclosure; and

FIG. 56 is a top view of a display substrate according to some embodiments of the present disclosure.

### DETAILED DESCRIPTION

For clearer descriptions of the objects, technical solutions, and advantages of the embodiments of present disclosure, the embodiments of the present disclosure are described in detail hereinafter in combination with the accompanying drawings.

In some embodiments, a light-emitting assembly includes a plurality of light-emitting units and drive units. Each light-emitting unit is connected to the drive unit, such that the drive units supply drive signals to the plurality of light-emitting units, and the plurality of light-emitting units emit light under drive of the drive units. The plurality of light-emitting units in the light-emitting assembly are bonded to the drive units by a massive transfer mode.

However, a massive transfer technology needs to bond the plurality of light-emitting units to the drive units, alignment precision in bonding is low, and yield of products is low.

A micro light-emitting diode (micro LED) technology is a new display technology. The micro LED is acquired by performing film thinning, miniaturizing, and arraying on a common light-emitting unit, such that the light-emitting unit is a size of only microns to tens of microns, and achieves self-luminescence. Furthermore, the micro LED has advantages of high brightness, low power consumption, ultra-high resolution, and the like. In particular, the micro LED may achieve as an ultra-high resolution and high-performance wearable display device, for example, a virtual reality (VR) device and an augmented reality (AR) device.

A micro LED display substrate generally includes a drive backplane, drive units integrated in the drive backplane, and a light-emitting chip bonded to the drive units. In the process of manufacturing the micro LED display substrate, the light-emitting chips of different colors need to be transferred and bonded to the drive backplane integrated with the drive units to achieve color display, the light-emitting chips of a same color are transferred at one time, and the light-emitting chips of different colors are transferred in batches. That is, a number of transfer processes is a number of colors of the light-emitting chips. Optionally, the light-emitting chips include light-emitting chips of three colors, for example, red (R) light-emitting chips, green (G) light-emitting chips, and blue light-emitting chips, and thus three transfer processes is required. In the scheme, the number of transfer processes in manufacturing the micro LED display substrate is great, requirements for the device and process are relatively critical, the process is complex, and the yield is greatly challenged.

In addition, a size of the drive backplane is not large (in the case that the drive backplane is too large, some of the light-emitting chips fail upon being transferred, the product is scrapped, and the cost is high) to reduce the manufacturing cost of the micro LED display substrate. Thus, the large-sized display in the scheme is achieved only by splicing, and the display effect is poor.

The red, green, and blue three-color micro display chip (RGB micro LED) is bonded to the driver unit to form a new active-matrix light-emitting diode (AM-LED) chip including the driver circuit. The AM-LED chip includes a blue light-emitting chip, quantum dots (QDs) that excite red light and green light, and drive units that drive the light-emitting chip. In addition, in the case that a size of the display substrate is needed, a corresponding number of AM-LED chips are transferred and bonded to the driver backplane at one time to manufacture a glass-based color LED display substrate. Meanwhile, only one transfer process is performed in the scheme, and thus the process is simple. Moreover, the large-sized display is achieved without splicing, such that the glass utilization of the drive backplane is improved, and the cost is reduced.

In addition, the AM-LED chip achieves electrical/optical dual detection by a detection technology to screen out chips with optical performances and drive performances that meet requirements. As such, compared with the scheme of integrating the drive circuit on the drive backplane to form the display substrate, the scheme is conducive to improving the yield of the chips on the display substrate and facilitating repair and replacement of poor chips. However, the AM-LED chip is only achieved on the substrate at a wafer size level, and is not suitable for the large-sized glass substrate.

In addition, whether to transfer the red light-emitting chips, the green light-emitting chips, and the blue light-emitting chips three times, or transfer the blue light-emitting chips combined with the QDs once, it is necessary to bond the light-emitting chips and the drive backplane by a massive transfer process. In the massive transfer process, light leakage occurs due to the poor alignment precision or other reasons, such that the yield and the quality of the micro LED display substrate are affected.

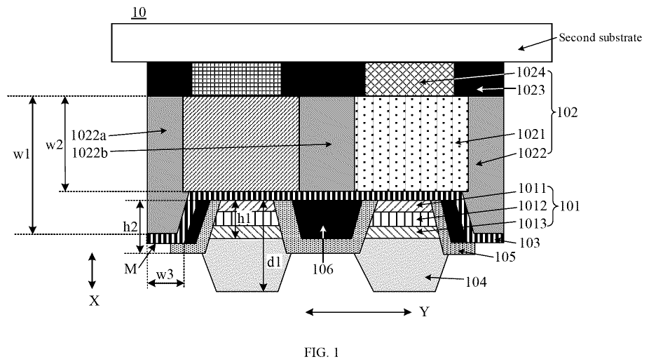

FIG. 1 is a schematic structural diagram of a light-emitting assembly according to some embodiments of the present disclosure. Referring to FIG. 1, the light-emitting assembly 10 includes a plurality of light-emitting units 101, a color-converting portion 1021, a common electrode layer 103, first electrodes 104, and a first encapsulation layer 105.

Each of the plurality of light-emitting units 101 includes a first semiconductor layer 1011, a light-emitting layer 1012, and a second semiconductor layer 1013 that are laminated. A doped type of the first semiconductor layer 1011 is different from a doped type of the second semiconductor layer 1013. Specifically, the first semiconductor layer 1011 is N-type doped, and the second semiconductor layer 1013 is P-type doped. Alternatively, the first semiconductor layer 1011 is P-type doped, and the second semiconductor layer 1013 is N-type doped.

The color-converting portion 1021 is disposed on a side, away from the light-emitting layer 1012, the first semiconductor layer 1011, and is configured to convert colors of light emitted by the light-emitting units 101.

The common electrode layer 103 is disposed between the first semiconductor layer 1011 and a color-converting assembly 102, is electrically connected to the first semiconductor layer 1011, and is connected to at least two light-emitting units 101. For example, the common electrode layer 103 is electrically connected to the first semiconductor layer 1011 of each light-emitting unit 101 in a plurality of light-emitting assemblies 10.

The first electrodes 104 are disposed on a side, away from the light-emitting layer 1012, of the second semiconductor layer 1013, are electrically connected to the second semiconductor layer 1013, and are in one-to-one correspondence with the plurality of light-emitting units 101. The first electrodes 104 are configured to connect the light-emitting units 101 to drive units 112, such that drive signals of the drive units 112 are transmitted to the second semiconductor layer 1013 of the light-emitting unit 101.

The first encapsulation layer 105 at least encloses sidewalls of the light-emitting units 101. The first encapsulation layer 105 is configured to enclose the light-emitting units 101 to avoid mutual effects of the light-emitting units 101.

In the embodiments of the present disclosure, the first electrodes 104 of the light-emitting assembly 10 and the common electrode layer 103 are respectively disposed on two sides of the light-emitting units 101, which is called as a vertical structure. The light-emitting units 101 are light-emitting units in the vertical structure.

In addition, in a thickness direction X of the light-emitting layer 1012, a distance h1 between the first electrodes 104 and the common electrode layer 103 is less than a span h2 of the first encapsulation layer 105 in the thickness direction. The distance between the first electrodes 104 and the common electrode layer 103 refers to a distance between a side, close to the common electrode layer 103, of the first electrodes 104 and a side, close to the first electrodes 104, of the common electrode layer 103.

In the thickness direction X of the light-emitting layer 1012, the distance h1 between the first electrodes 104 and the common electrode layer 103 being less than a span h2 of the first encapsulation layer 105 in the thickness direction means that the first encapsulation layer 105 includes a portion beyond the common electrode layer 103 or the first electrodes 104 in the thickness direction X of the light-emitting layer 1012. As such, the beyond portion of the first encapsulation layer 105 forms an accommodation space to facilitate embedding of other structures in the accommodation space, such that reliability of connection is improved.

In addition, as at least two of the plurality of light-emitting units 101 are connected to each other via the common electrode layer 103, the at least two of the plurality of light-emitting units 101 are integrated, such that the alignment precision of bonding in subsequently bonding process is ensured, and the yield of the products is improved.

In summary, the embodiments of the present disclosure provide a light-emitting assembly. The light-emitting assembly includes a plurality of light-emitting units, a color-converting layer, a common electrode layer, first electrodes, and a first encapsulation layer. The color-converting layer is disposed on one side of the light-emitting units, and is configured to convert colors of light emitted by the light-emitting units. The first electrodes are disposed on the other side of the light-emitting units, and are configured to receive drive signals. The first encapsulation layer is configured to encapsulate the light-emitting units to avoid the mutual effect of any adjacent two light-emitting units 101. At least two of the plurality of light-emitting units are connected as an integrated structure, such that the alignment precision of bonding in subsequently bonding process is ensured, and the yield of the products is improved.

In the embodiments of the present disclosure, the first electrodes 104 are made of at least one of a metal or a conductive oxide, and the common electrode layer 103 is made of a conductive oxide.

In some embodiments, referring to FIG. 1, for each light-emitting unit 101, the first encapsulation layer 105 exposes the first semiconductor layer 1011 of the light-emitting unit 101 from a side, facing towards the color-converting portion 1021, of the first semiconductor layer 1011, such that the first semiconductor layer 1011 is electrically connected to the common electrode layer 103. That is, the first encapsulation layer 105 is only configured to protect a sidewall of the light-emitting unit 101, and does not insulate the first semiconductor layer 1011 from the common electrode layer 103.

Referring to FIG. 1, the first encapsulation layer 105 is further disposed between any adjacent two light-emitting units 101. As various film layers in the light-emitting unit 101 are not disposed between adjacent two light-emitting units 101, a portion, between the ad jacent two light-emitting units 101, in the first encapsulation layer 105 is further away from the color-converting assembly 102 than a portion enclosing the sidewall of the light-emitting unit 101. Thus, in any adjacent two light-emitting units 101, a target region is defined between the first encapsulation layer 105 and the color-converting assembly 102.

Furthermore, referring to FIG. 1, for avoiding collapse of the first encapsulation layer 105 in the subsequent process due to the target region, the light-emitting assembly 10 further includes a filling layer 106. The filling layer 106 is disposed in the target region (for example, fills the target region).

A side, close to the color-converting assembly 102, of the filling layer 106 is coplanar with the end, close to the color-converting assembly 102, of the first encapsulation layer 105. In some embodiments, the filling layer 106 includes a first end face in contact with the common electrode layer 103 and a second end face in contact with a side, away from the color-converting assembly 102, of the first encapsulation layer 105. The first end face is coplanar with the end, close to the color-converting assembly 102, of the first encapsulation layer.

In addition, the filling layer 106 further includes a first side face. The first side face is in contact with a portion, surrounding each of at least two of the plurality of light-emitting units 101, in the first encapsulation layer 105.

The end, close to the color-converting assembly 102, of the first encapsulation layer 105 is an end portion, close to the color-converting assembly 102, in the portion surrounding the sidewalls of the light-emitting units 101. In some embodiments, the side, close to the color-converting assembly 102, of the filling layer 106 and the end, close to the color-converting assembly 102, of the first encapsulation layer 105 are acquired by a same grinding process.

In a first scheme, in a direction perpendicular to the thickness direction X, the common electrode layer includes a target portion M beyond a boundary of the first encapsulation layer 105. As such, the light-emitting assembly further includes second electrodes (not shown in the drawing). The second electrodes are electrically connected to the target portion M, such that the second electrodes are electrically connected to the first semiconductor layer 1011 via the common electrode layer 103.

The second electrodes are disposed to facilitate transmission of the drive signals of the drive unit 112 to the common electrode layer 103 by the second electrodes, and further transmission of the drive signals of the drive unit 112 to the first semiconductor layer 1011 via the common electrode layer 103. In some embodiments, the second electrodes are not disposed, and the common electrode layer is directly connected to the drive unit 112.

Drive signals (referred to as first drive signals) of the drive unit 112 received by the first electrodes 104 are different from drive signals (referred to as second drive signals) of the drive unit 112 received by the second electrodes. The light-emitting layer 1012 of the light-emitting unit 101 emits light under joint action of the first drive signals transmitted in the first electrodes 104 and the second drive signals transmitted in the second electrodes.

In the first scheme, the color-converting assembly 102 is formed on a glass substrate, the common electrode layer 103 is formed on a side of the color-converting assembly 102, and then the plurality of light-emitting unit 101 and the color-converting assembly 102 are aligned and bonded, such that the first semiconductor layers 1011 of at least two light-emitting units 101 are electrically connected to the common electrode layer 103. In this way, the common electrode layer 103 includes the target portion M beyond the boundary of the first encapsulation layer 105 to facilitate disposing the second electrodes.

In addition, the color-converting assembly 102 is formed on a glass substrate in the scheme to achieve fully color display. In addition, the massive transfer process is not required in subsequent bonding to the drive units 112, such that the probability of light leakage from the sidewall and crosstalk leakage between adjacent light-emitting units is reduced, the production efficiency and the yield are improved, and the production cost is reduced.

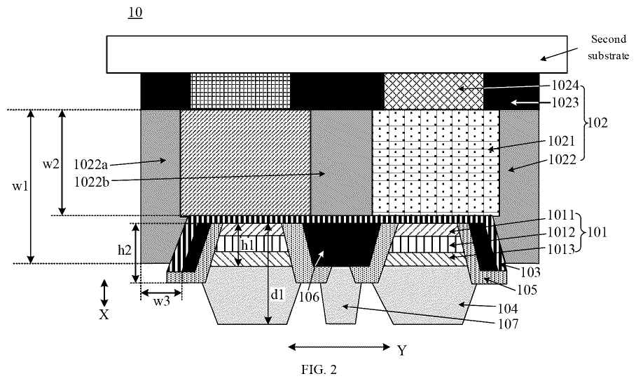

In a second scheme, referring to FIG. 2, the filling layer 106 is made of a conductive material. An opening is defined in a portion, between any adjacent two light-emitting units 101, in the first encapsulation layer 105, and the filling layer 106 is exposed from the opening. The light-emitting assembly 10 further includes second electrodes 107. At least part of each second electrode 107 is disposed in the opening, and each second electrode 107 is connected to the common electrode layer 103 via the filling layer 106 exposed from the opening.

As the filling layer 106 is made of a conductive material, the second electrode 107 transmits the second drive signal to the common electrode layer 103 via the filling layer 106 to achieve conduction of the signal.

In some embodiments, the filling layer 106 is made of a non-transparent metal, for example, copper (Cu), nickel (Ni), aluminum (Al), titanium (Ti), and gold (Au). As the filling layer 106 is non-transparent, light crosstalk is avoided.

In the second scheme, the common electrode layer 103 is first formed on a side of the first semiconductor layer 1011 of the light-emitting unit 101, and is then bonded to the color-converting assembly 102 formed on the glass substrate. The common electrode layer 103 formed in this way does not include the target portion M beyond the boundary of the first encapsulation layer 105, and thus the opening is defined in the portion, between adjacent two light-emitting units 101, in the first encapsulation layer 105, such that the second electrode 107 is connected to the common electrode layer 103 via the filling layer 106 formed by the conductive material.

In addition, the color-converting assembly 102 is formed on a glass substrate in the scheme to achieve fully color display. In addition, the massive transfer process is not required in subsequent bonding to the drive units, such that the probability of the light leakage from the sidewall and crosstalk leakage between adjacent light-emitting units is reduced, the production efficiency and the yield are improved, and the production cost is reduced.

Referring to FIG. 1 and FIG. 2, in the above first scheme and second scheme, the color-converting assembly 102 includes a color-converting portion 1021, a retaining wall structure 1022, a light-shielding layer 1023, and a light-filtering portion 1024.

The retaining wall structure 1022 defines a plurality of first accommodation spaces (not shown in FIG. 1 and FIG. 2). Each first accommodation space exposes a light-emitting region of one light-emitting unit 101. The color-converting portion 1021 is at least disposed in the first accommodation spaces, and is configured to convert colors of light emitted by the plurality of light-emitting units 101.

In some embodiments, the colors of the light emitted by the plurality of light-emitting units 101 in the light-emitting assembly 10 is light at a first wavelength. The color-converting portion 1021 includes a first color-converting portion, a second color-converting portion, and a third color-converting portion. The first color-converting portion converts the light at the first wavelength to light at a second wavelength, the second color-converting portion converts the light at the first wavelength to light at a third wavelength, and the third color-converting portion converts the light at the first wavelength to light at a fourth wavelength.

Illustratively, a color of the light at the first wavelength is blue, that is, the plurality of light-emitting units 101 are all blue light-emitting units. A color of the light at the second wavelength is red, and the first color-converting portion converts blue light at the first wavelength to red light at the second wavelength. A color of the light at the third wavelength is green, and the second color-converting portion converts blue light at the first wavelength to green light at the third wavelength. A color of the light at the fourth wavelength is blue, and the third color-converting portion converts blue light at the first wavelength to blue light at the fourth wavelength. The first wavelength and the fourth wavelength are equal or different.

Illustratively, assuming that the first wavelength and the fourth wavelength are equal, the first color-converting portion includes red QDs, the second color-converting portion includes green QDs, and the third color-converting portion is a transparent portion, then the transparent portion is configured to transmit the light at the first wavelength emitted by the light-emitting units 101. For example, the transparent portion is made of a transparent optical cement (OC).

Furthermore, referring to FIG. 1 and FIG. 2, the light-shielding layer 1023 defines a plurality of second accommodation spaces (not shown in FIG. 1 and FIG. 2), and each of the plurality of second accommodation spaces corresponds to one of the plurality of first accommodation spaces. The light-filtering portion 1024 is at least disposed in the plurality of second accommodation spaces, and is configured to transmit light converted by the color-converting portion 1021.

In some embodiments, the light-filtering portion 1024 includes a first light-filtering portion transmitting the light at the second wavelength, a second light-filtering portion transmitting the light at the third wavelength, and a third light-filtering portion transmitting the light at the fourth wavelength. The first light-filtering portion is a red color resistance block, corresponds to a location of the first color-converting portion, and is configured to transmit red light at the second wavelength converted by the first color-converting portion. The second light-filtering portion is a green color resistance block, corresponds to a location of the second color-converting portion, and is configured to transmit green light at the third wavelength converted by the second color-converting portion. The third light-filtering portion is a blue color resistance block or a transparent portion, corresponds to a location of the third color-converting portion, and is configured to transmit blue light at the fourth wavelength converted by the third color-converting portion.

In the embodiments of the present disclosure, the detailed design pattern of the light-shielding layer 1023 depends on the design pattern of the light-emitting units 101, which is not specifically defined in the embodiments of the present disclosure. The light-shielding layer 1023 is made of a regular resin-type negative adhesive BM material, a width of the second accommodation space formed by the light-shielding layer 1023 ranges from 1 micron (μm) to 15 μm, and a thickness of the light-shielding layer 1023 ranges from 0.5 μm to 5 μm.

The light-filtering portion 1024 is made of a regular resin-type negative adhesive material, and there is no specifical demand on a sequence of processes of light-filtering portions of different colors. A thickness of the light-filtering portion 1024 is the same as the thickness of the light-shielding layer 1023, that is, ranges from 0.5 μm to 5 μm.

The retaining wall structure 1022 is made of a resin-type negative adhesive BM material. A height of the retaining wall structure 1022 is greater than 1 μm without an upper limit. The retaining wall structure 1022 and the light-shielding layer 1023 are made of the same material or different materials. There is no specifical demand on a covering relation between an orthographic projection of the retaining wall structure 1022 on a reference plane and an orthographic projection of the light-shielding layer 1023 on the reference plane. For example, the orthographic projection of the retaining wall structure 1022 on the reference plane covers the orthographic projection of the light-shielding layer 1023 on the reference plane, or the orthographic projection of the light-shielding layer 1023 on the reference plane covers the orthographic projection of the retaining wall structure 1022 on the reference plane. The reference plane is parallel to a disposing face (the disposing face is a bearing face of the substrate) of various structures in the light-emitting assembly 10.

Referring to FIG. 1 and FIG. 2, the retaining wall structure 1022 includes a first portion 1022a in an edge region of the plurality of light-emitting units 101 and a second portion 1022b between any adjacent two of the plurality of light-emitting units 101. A height of the second portion 1022b is less than a height of the first portion 1022a, and a difference between the height w1 of the first portion 1022a and the height w2 of the second portion 1022b is 10% to 90% of a thickness of each of the plurality of light-emitting units 101.

As the light-emitting units 101 and the color-converting assembly 102 in the light-emitting assembly 10 are connected by bonding, a gap is present between a sidewall of the second portion 1022b and the light-emitting unit 101 upon bonding in the case that the height of the second portion 1022b between any adjacent two light-emitting units 101 is great.

In the case that the height w2 of the second portion 1022b is less than the height w1 of the first portion 1022a, the gap between the sidewall of the second portion 1022b and the light-emitting unit 101 is avoided upon bonding, such that a risk of light leakage is reduced.

Furthermore, the first portion 1022a of the retaining wall structure 1022 needs to wraps a periphery of the filling layer 106 (the conductive material), and a length w3 of the first portion 1022a beyond the filling layer 106 is greater than 0.5 μm in a direction Y perpendicular to the thickness direction X.

In the embodiments of the present disclosure, the common electrode layer 103 is a transparent conductive film layer. For example, the common electrode layer 103 is made of indium tin oxide (ITO), indium zinc oxide (IZO), indium gallium zinc oxide (IGZO), or other transparent conductive materials. The common electrode layer 103 mainly functions to connect the first semiconductor layers 1011 of at least two light-emitting units 101 to provide a charge interface to the light-emitting units 101. In addition, a thickness of the common electrode layer 103 ranges from 200 angstroms to 1000 angstroms.

In addition, the light-emitting assembly 10 further includes a second encapsulation layer (not shown in the drawing) between the common electrode layer 103 and the color-converting assembly 102. The second encapsulation layer is made of one or more of aluminum oxide (AlO3), silicon oxide (SiO), and silicon nitride (SiNx). In addition, the second encapsulation layer is manufactured by atomic layer deposition (ALD), plasma enhanced chemical vapor deposition (PECVD), or a sol-gel process. A thickness of the second encapsulation layer is generally not greater than 2 μm, which is thin, and thus is not shown in the drawing.

In the embodiments of the present disclosure, a distance d1 between ends, away from the common electrode layer 103, of the first electrodes 104 and the common electrode layer 103 is greater than or equal to the span h2 of the first encapsulation layer 105 in the thickness direction X. That is, the ends, away from the common electrode layer 103, of the first electrodes 104 protrude from an end, away from the common electrode layer 103, of the first encapsulation layer 105. Alternatively, the ends, away from the common electrode layer 103, of the first electrodes 104 is flushed with the end, away from the common electrode layer 103, of the first encapsulation layer 105.

In the thickness direction X of the light-emitting layer 1012, a ratio h1:h2 of the distance h1 between the first electrodes 104 and the common electrode layer to the span h2 of the first encapsulation layer 105 in the thickness direction X ranges from 0.1 to 0.9. In some embodiments, the ratio h1:h2 ranges from 0.4 to 0.8, for example, 0.6.

In the first scheme and second scheme, the span h2 of the first encapsulation layer 105 in the thickness direction X is greater than the distance h1 between the first electrodes 104 and the common electrode layer, such that the bonding capability of the first electrodes 104 and the second semiconductor layer 1013 is ensured, and the light leakage from the edge position of the light-emitting region of the light-emitting unit 101 is avoided.

In the embodiments of the present disclosure, as an N-type doping layer, a light-emitting layer, and a P-type doping layer need to sequentially formed on a sapphire substrate in manufacturing the light-emitting unit 101, in the case that the first semiconductor layer 1011 is the P-type doping layer, and the second semiconductor layer 1013 is the N-type doping layer, the light-emitting unit 101 and the color-converting assembly 102 that are disposed on the sapphire substrate are directly bonded to cause that the first semiconductor layer 1011 is closer to the color-converting assembly 102 than the second semiconductor layer 1013, the sapphire substrate is then removed from a side of the N-type doping layer, and the light-emitting unit 101 and the drive unit 112 are eventually bonded. In this case, the first semiconductor layers 1011 (the P-type doping layers) of at least two light-emitting units 101 are connected via the common electrode layer 103.

In the case that the first semiconductor layer 1011 is the P-type doping layer, and the second semiconductor layer 1013 is the N-type doping layer, the co-anode is achieved via the common electrode layer 103 in the embodiments. Correspondingly, the first electrodes 104 are electrically connected to the N-type second semiconductor layer 1013, and the first electrodes 104 are referred to as N-type electrodes; the second electrodes are electrically connected to the P-type first semiconductor layer 1011, and the second electrodes are referred to as P-type electrodes. In some embodiments, the first semiconductor layer 1011 includes P-type gallium nitride (GaN), and is denoted as P-GaN. The second semiconductor layer 1013 includes N-type GaN, and is denoted as N-GaN.

In the case that the first semiconductor layer 1011 is the N-type doping layer, and the second semiconductor layer 1013 is the P-type doping layer, in order to cause that the first semiconductor layer 1011 is closer to the color-converting assembly 102 than the second semiconductor layer 1013, the second semiconductor layers 1013, the light-emitting layer 1012, and the first semiconductor layer 1011 are first transferred on an immediate substrate, such that the second semiconductor layers 1013, the light-emitting layer 1012, and the first semiconductor layer 1011 are sequentially laminated in a direction away from the immediate substrate. Then, the light-emitting unit 101 and the color-converting assembly 102 are bonded, the immediate substrate is removed from a side of the P-type doping layer, and the light-emitting unit 101 and the drive unit 112 are eventually bonded. In this case, the first semiconductor layers 1011 (the N-type doping layers) of at least two light-emitting units 101 are connected via the common electrode layer 103.

In the case that the first semiconductor layer 1011 is the N-type doping layer, and the second semiconductor layer 1013 is the P-type doping layer, the co-anode is achieved via the common electrode layer 103 in the embodiments. Correspondingly, the first electrodes 104 are electrically connected to the P-type second semiconductor layer 1013, and the first electrodes 104 are referred to as P-type electrodes; the second electrodes are electrically connected to the N-type first semiconductor layer 1011, and the second electrodes are referred to as N-type electrodes. In some embodiments, the first semiconductor layer 1011 includes N-type GaN, and is denoted as N-GaN. The second semiconductor layer 1013 includes P-type GaN, and is denoted as P-GaN.

However, compared with the scheme that the first semiconductor layer 1011 is the P-type doping layer and the second semiconductor layer 1013 is the N-type doping layer, one more transfer process (transferring to the immediate substrate) is required in the scheme that the first semiconductor layer 1011 is the N-type doping layer and the second semiconductor layer 1013 is the P-type doping layer, and thus the manufacturing efficiency is low. Thus, in the embodiments, the greater scheme is that the first semiconductor layer 1011 is the P-type doping layer and the second semiconductor layer 1013 is the N-type doping layer.

In some embodiments, for each light-emitting unit 101, the first encapsulation layer 105 exposes the second semiconductor layer 1013 of the light-emitting unit 101 from a side, away from the color-converting portion 1021, of the first semiconductor layer 105, such that the second semiconductor layer 1013 is electrically connected to the first electrodes 104. That is, the first encapsulation layer 105 is only configured to protect a sidewall of the light-emitting unit 101, and does not insulate the second semiconductor layer 1013 from the first electrodes 104.

A distance between an end portion, close to the color-converting portion 1021, of the first encapsulation layer 105 and the color-converting portion 1021 is less than a distance between a face, close to the color-converting portion 1021, of the first semiconductor layer 1011 and the color-converting portion 1021. That is, in the thickness direction X, the first encapsulation layer 105 includes a portion beyond the first semiconductor layer 1011, and the beyond portion and the first semiconductor layer 1011 define a groove. In addition, a face, away from the color-converting portion 1021, of the first encapsulation layer 105 is coplanar with a side, away from the color-converting portion 1021, of the second semiconductor layer 1013.

In the embodiments of the present disclosure, the common electrode layer 103 includes a first electrode region and a second electrode region. The first electrode region is disposed in a groove defined by the first encapsulation layer and the first semiconductor layer 1011, and the second electrode region surrounds the first electrode region. That is, the common electrode layer 103 is disposed in the groove, or disposed outside the groove.

The first encapsulation layer 105 is further disposed between any adjacent two light-emitting units 101. As various film layers in the light-emitting unit 101 are not disposed between adjacent two light-emitting units 101, a portion, between the adjacent two light-emitting units 101, in the first encapsulation layer 105 is further away from the color-converting assembly 102 than a portion enclosing the sidewall of the light-emitting unit 101. Thus, in any adjacent two light-emitting units 101, a target region is defined between the first encapsulation layer 105 and the color-converting assembly 102.

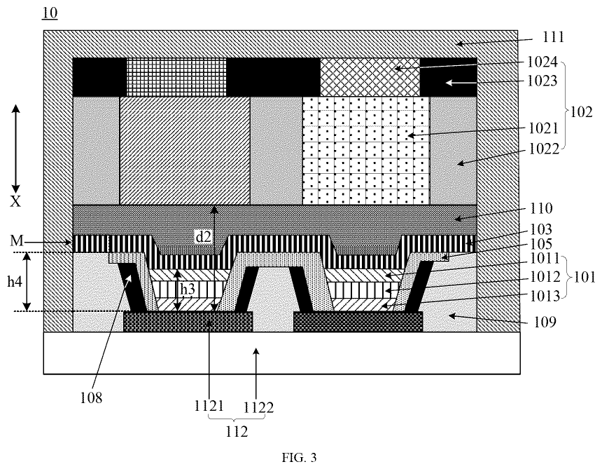

Furthermore, referring to FIG. 3, the light-emitting assembly 10 further includes a blocking portion 108 at least surrounding the sidewall of the each light-emitting unit 101. The blocking portion 108 is at least disposed in the target region, and is configured to absorb or reflect light emitted by the light-emitting units 101, and the blocking portion 108 surrounding the sidewall of the each light-emitting unit 101 is disposed on a side, away from the light-emitting units 101, of the first encapsulation layer 105.

In some embodiments, the light-emitting assembly 10 includes a plurality of blocking portions 108, and each blocking portion 108 at least surrounds a sidewall of a corresponding light-emitting unit 101. Any adjacent two blocking portions 108 are spaced apparat from each other.

Furthermore, referring to FIG. 3 to FIG. 5, as adjacent two blocking portions 108 are spaced apparat from each other, the light-emitting assembly 10 further include a bonding layer 109 in the gap of the blocking portions 108. The bonding layer 109 fills the not filled target region in the blocking portion 108 to avoid collapse of the first encapsulation layer 105.

A side, away from the color-converting assembly 102, of the blocking portion 108 is coplanar with a side, away from the color-converting assembly 102, of the portion in the first encapsulation layer 105 in the sidewall of the light-emitting unit 101. In some embodiments, the side, away from the color-converting assembly 102, of the blocking portion 108 and the side, away from the color-converting assembly 102, of the portion in the first encapsulation layer 105 in the sidewall of the light-emitting unit 101 are acquired by a same grinding process. The blocking portion 108 in the structure is in an annular structure.

Alternatively, the blocking portion 108 is made of a metal. The blocking portion 108 is further disposed on a side, away from the color-converting portion 1021, of the second semiconductor layer 1013, and is electrically connected to the second semiconductor layer 1013. The blocking portion 108 in the structure is in a bowl-shaped structure.

For the bowl-shaped blocking portion 108, the blocking portion 108 is the first electrode. Alternatively, the blocking portion 108 is disposed on a side, away from the second semiconductor layer 1013, of the first electrodes 104, and is electrically connected to the second semiconductor layer 1013 over the first electrodes 104. Alternatively, the blocking portion 108 is disposed between the first electrodes 104 and the second semiconductor layer 1013, and is electrically connected to the second semiconductor layer 1013 and the first electrodes 104.

In a third scheme, referring to FIG. 3, the light-emitting assembly 10 further includes a planarization layer 110 between the common electrode layer 103 and the color-converting assembly 102. The planarization layer 110 fills the groove defined by the first encapsulation layer 105 and the first semiconductor layer 1011, and a face, away from the light-emitting unit 101, of the planarization layer 110 is a flat face.

In some embodiments, it should be noted that a plurality of grooves are defined by the first encapsulation layer 105 and the first semiconductor layer 1011. The planarization layer 110 fills some of the plurality of grooves, or fills all of the plurality of grooves. Furthermore, the planarization layer 110 is disposed on a side, away from the light-emitting unit 101, of the second electrode region of the common electrode layer 103, that is, disposed above the portion of the common electrode layer 103 beyond the groove.

In the embodiments of the present disclosure, referring to FIG. 3, the retaining wall structure 1022 defines a plurality of first accommodation spaces. Each first accommodation space exposes a light-emitting region of one light-emitting unit. The color-converting portion 1021 is at least disposed in the first accommodation spaces, and is configured to convert colors of light emitted by the plurality of light-emitting units 101. As the planarization layer 110 is disposed on a side, away from the light-emitting unit 101, of the common electrode layer 103, the color-converting assembly 102 is subsequently disposed, such that the color-converting portion 1021 in the color-converting assembly 102 is disposed on the side, away from the common electrode layer 103, of the planarization layer 110, the uniformity of the same color-converting portion 1021 at various locations is ensured, and the performance of the color-converting portion 1021 is ensured.

In addition, in the thickness direction X, a distance h3 between the first electrodes 104 and the common electrode layer 103 is less than the span h4 of the first encapsulation layer 105 in the thickness direction X, and thus a connection portion of the common electrode layer 103 and the first semiconductor layer 1011 in the light-emitting unit 101 and a portion, between adjacent two light-emitting units 101, in the common electrode layer 103 in the first encapsulation layer 105 are not flat. In some embodiments, in the thickness direction X, a distance between the connection portion of the common electrode layer 103 and the first semiconductor layer 1011 in the light-emitting unit 101 and the first electrodes 104 is less than a distance between the portion, between adjacent two light-emitting units 101, in the common electrode layer 103 in the first encapsulation layer 105 and the first electrodes 104.

Furthermore, the first encapsulation layer 105 defines a plurality of grooves (not shown in the drawing), and the grooves are defined in a region of the connection portion of the common electrode layer 103 and the first semiconductor layer 1011 in the light-emitting unit 101. Thus, one portion of the planarization layer 110 on a side, away from the light-emitting unit 101, of the common electrode layer 103 is disposed in the groove, and the other portion of the planarization layer 110 is disposed outside the groove to achieve planarization, such that the planarization layer 110 is closely embedded in the groove, and the planarization of the planarization layer 110 is ensured.

Furthermore, referring to FIG. 3, a plurality of second accommodation spaces are defined by the light-shielding layer 1021, and each second accommodation space corresponds to one first accommodation space. The light-filtering portion 1024 is at least disposed in the second accommodation spaces, and is configured to transmit light converted by the color-converting portion 1021.

For related designs of the color-converting portion 1021 and the light-filtering portion 1024, reference may be made to detailed description in the above embodiments, which are not described again in the embodiments of the present disclosure.

In the embodiments of the present disclosure, the detailed design pattern of the light-shielding layer 1023 depends on the design pattern of the light-emitting units 101, which is not specifically defined in the embodiments of the present disclosure. The light-shielding layer 1023 is made of a regular resin-type negative adhesive BM material, a width of the second accommodation space formed by the light-shielding layer 1023 ranges from 1 μm to 15 μm, and a thickness of the light-shielding layer 1023 ranges from 0.5 μm to 5 μm.

The light-filtering portion 1024 is made of a regular resin-type negative adhesive material, and there is no specifical demand on a sequence of processes of light-filtering portions of different colors. A thickness of the light-filtering portion 1024 is the same as the thickness of the light-shielding layer 1023, that is, ranges from 0.5 μm to 5 μm.

The retaining wall structure 1022 is made of a non-transparent material. The non-transparent material is an absorbing material or a reflective material, or has a light absorption characteristic and a light reflecting characteristic. For example, the retaining wall structure 1022 is made of a resin-type negative adhesive BM material.

A height of the retaining wall structure 1022 is greater than 1 μm without an upper limit. The retaining wall structure 1022 and the light-shielding layer 1023 are made of the same material or different materials. There is no specifical demand on a covering relation between an orthographic projection of the retaining wall structure 1022 on a reference plane and an orthographic projection of the light-shielding layer 1023 on the reference plane. For example, the orthographic projection of the retaining wall structure 1022 on the reference plane covers the orthographic projection of the light-shielding layer 1023 on the reference plane, or the orthographic projection of the light-shielding layer 1023 on the reference plane covers the orthographic projection of the retaining wall structure 1022 on the reference plane. The reference plane is parallel to a disposing face of various structures in the light-emitting assembly 10.

In the embodiments of the present disclosure, the retaining wall structure 1022 and the light-shielding layer 1023 are acquired by a signal process. For example, the retaining wall structure 1022 and the light-shielding layer 1023 are all made of resin-type negative adhesive, and the total thickness of the retaining wall structure 1022 and the light-shielding layer 1023 ranges from 1 μm to 10 μm. The thickness of the color-converting portion 1021 ranges from 1 μm to 15 μm, and the thickness of the light-filtering portion 1024 ranges from 1 μm to 5 μm.

In the embodiments of the present disclosure, the common electrode layer 103 is a transparent conductive film layer. For example, the common electrode layer 103 is made of ITO, IZO, IGZO, or other transparent conductive materials. The common electrode layer 103 mainly functions to connect the first semiconductor layers 1011 of at least two light-emitting units 101 to provide a charge interface to the light-emitting units 101. In addition, a thickness of the common electrode layer 103 ranges from 200 angstroms to 1000 angstroms.

In addition, referring to FIG. 3, the light-emitting assembly 10 further includes a third encapsulation layer 111 on a side, away from the light-emitting unit 101, of the color-converting assembly 102. The third encapsulation layer 111 is made of an inorganic material, for example, a single layer of SiNx, SiOx, AlO3, or titanium oxide (TiO), or a laminated later of combination thereof. In addition, the third encapsulation layer 111 further includes an organic material film layer manufactured by an ink jet print mode.

Referring to FIG. 3, the third encapsulation layer 111 wraps edges of a plurality of light-emitting units 101, such that the plurality of light-emitting units 101 are whole encapsulated, corrosion of related structures of the light-emitting assembly 10 due to exposure is avoided, and the yield of the light-emitting assembly 10 is ensured.

In the third scheme, the light-emitting units 101 and the drive units 112 are bonded, and then the common electrode layer 103, the planarization layer 110, and the color-converting assembly 102 are formed on the side, away from the drive units 112, of the light-emitting units 101. The common electrode layer 103 formed by the method includes the target portion M beyond the boundary of the first encapsulation layer 105, and thus the second electrodes (not shown in the drawing) are directly and electrically connected to the target portion M, and are further electrically connected to the first semiconductor layers 1011.

In addition, the color-converting assembly 102 is formed on a substrate of the drive units in the scheme to achieve fully color display, and the massive transfer process is not required, such that the probability of light leakage from the sidewall and crosstalk leakage between adjacent light-emitting units is reduced, the production efficiency and the yield are improved, and the production cost is reduced.

In the light-emitting assembly 10 shown in FIG. 3, the blocking portion 108 is in the annular structure. Each blocking portion 108 surrounds a sidewall of a light-emitting unit 101 and exposes the second semiconductor layer 1013 of the light-emitting unit 101, and the second semiconductor layer 1013 is directly in contact with and electrically connected to the first electrodes 104.

As the second semiconductor layer 1013 is directly in contact with and electrically connected to the first electrodes 104, and is not connected to the first electrodes 104 through other conductive structures, a transmission characteristic of transmitting the first drive signal to the second semiconductor layer 1013 over the first electrodes 104 is ensured, and the yield of the product is great.

In the embodiments of the present disclosure, a distance d2 between a face, away from the common electrode layer 103, of the planarization layer 110 and the first electrodes 104 is greater than or equal to the span h4 of the first encapsulation layer 105 in the thickness direction X. That is, the face, away from the common electrode layer 103, of the planarization layer 110 protrudes from an end, away from the common electrode layer 103, of the first encapsulation layer 105. Alternatively, the face, away from the common electrode layer 103, of the planarization layer 110 is flushed with the end, away from the common electrode layer 103, of the first encapsulation layer 105.

In the thickness direction X of the light-emitting layer 1012, a ratio h3:h4 of the distance h3 between the first electrodes 104 and the common electrode layer to the span h4 of the first encapsulation layer 105 in the thickness direction X ranges from 0.1 to 0.9. In some embodiments, the ratio h3:h4 ranges from 0.3 to 0.7, for example, 0.5.

In the third scheme, the span h4 of the first encapsulation layer 105 in the thickness direction X is greater than the distance h3 between the first electrodes 104 and the common electrode layer, and the planarization layer 110 fills the groove, such that the bonding capability of the planarization layer 110 and the first semiconductor layer 1011 is ensured. In addition, a flat face is provided for subsequently formation of the color-converting assembly 102, such that stability of forward outgoing light of the light-emitting region of the light-emitting unit 101 is ensured, and the light leakage from the edge position of the light-emitting region of the light-emitting unit 101 is avoided.

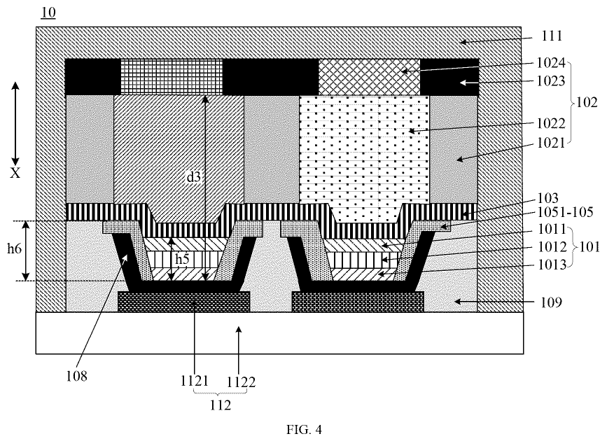

In a fourth scheme, referring to FIG. 4, the light-emitting assembly 10 is not provided with the planarization layer 110, and the color-converting assembly 102 is directly formed on the side, away from the light-emitting unit 101, of the common electrode layer 103. That is, at least part of the color-converting portion 1021 is disposed in the groove formed by the first encapsulation layer 105 and the first semiconductor layer 1011, and the color-converting portion 1021 is disposed on the side, away from the light-emitting unit 101, of the common electrode layer 103.

As in the thickness direction X, a distance h5 between the first electrodes 104 and the common electrode layer 103 is less than the span h6 of the first encapsulation layer 105 in the thickness direction X, a connection portion of the common electrode layer 103 and the first semiconductor layer 1011 in the light-emitting unit 101 and a portion, between adjacent two light-emitting units 101, in the common electrode layer 103 in the first encapsulation layer 105 are not flat. In some embodiments, in the thickness direction X, a distance between the connection portion of the common electrode layer 103 and the first semiconductor layer 1011 in the light-emitting unit 101 and the first electrodes 104 is less than a distance between the portion, between adjacent two light-emitting units 101, in the common electrode layer 103 in the first encapsulation layer 105 and the first electrodes 104.

Furthermore, the first encapsulation layer 105 and the first semiconductor layer 1011 define a plurality of grooves, and the grooves are defined in a region of the connection portion of the common electrode layer 103 and the first semiconductor layer 1011 in the light-emitting unit 101. Thus, the portion of the color-converting portion 1021 in the color-converting assembly 102 directly fills the groove.

In the embodiments of the present disclosure, referring to FIG. 4, the retaining wall structure 1022 defines a plurality of first accommodation spaces. Each first accommodation space exposes a light-emitting region of one light-emitting unit 101. The color-converting portion 1021 is also disposed in the first accommodation spaces of the retaining wall structure 1022 other than the groove, and is configured to convert colors of light emitted by the plurality of light-emitting units 101.

Furthermore, for related designs of the retaining wall structure 1022, the color-converting portion 1021, the light-shielding layer 1023, the light-filtering portion 1024, the common electrode layer 103, and the third encapsulation layer 111 in the fourth scheme, reference may be made to detailed description in the third scheme, which are not described again in the embodiments of the present disclosure.

In the fourth scheme, the light-emitting units 101 and the drive units 112 are bonded, and then the common electrode layer 103 and the color-converting assembly 102 are formed on the side, away from the drive units 112, of the light-emitting units 101. The common electrode layer 103 formed by the method includes the target portion M beyond the boundary of the first encapsulation layer 105, and thus the second electrodes (not shown in the drawing) are directly and electrically connected to the target portion M, and are further electrically connected to the first semiconductor layers 1011.

In addition, the color-converting assembly 102 is formed on a substrate of the drive units in the scheme to achieve fully color display, and the massive transfer process is not required, such that the probability of light leakage from the sidewall and crosstalk leakage between adjacent light-emitting units is reduced, the production efficiency and the yield are improved, and the production cost is reduced.

In the light-emitting assembly 10 shown in FIG. 4, the blocking portion 108 is in the bowl structure. Each blocking portion 108 surrounds a sidewall of a light-emitting unit 101, and covers the second semiconductor layer 1013 of the light-emitting unit 101. Each blocking portion 108 is made of a conductive material, and the second semiconductor layer 1013 of each light-emitting unit 101 is electrically connected to the first electrode 104 through the blocking portion 108.

In some embodiments, the blocking portion 108 is made of a non-transparent (for example, black) metal material. The blocking portion 108 covers the second semiconductor layer 1013 of the light-emitting unit 101, and the non-transparent metal material is configured to block light, such that the light emitted by the light-emitting units 101 is prevented from emitting from a side of the second semiconductor layer 1013, and the light leakage is avoided.

In some embodiments, the blocking portion 108 is made of Cu, Ni, Al, Ti, Au, or other non-transparent metal materials.

It should be noted that as light emitted by each light-emitting unit 101 may crosstalk the adjacent light-emitting unit 101 along the shared film layer (whether the shared film layer is conductive or not) of a plurality of light-emitting units 101, in order to avoid the crosstalk of the light emitted by the light-emitting unit 101 along the first encapsulation layer 105 to the adjacent light-emitting unit 101, referring to FIG. 4, the first encapsulation layer 105 includes a plurality of separate encapsulation patterns 1051. Each encapsulation pattern 1051 encloses the sidewall of one light-emitting unit 101, and exposes the second semiconductor layer 1013 of one light-emitting unit 101.

In a fifth scheme, referring to FIG. 5, the light-emitting assembly 10 is not provided with the planarization layer 110, and the retaining wall structure 1022 and the light-shielding layer 1023 are disposed on the side, close to the plurality of light-emitting units 101, of the common electrode layer 103. That is, the common electrode layer 103 is formed upon the retaining wall structure 1022 and the light-shielding layer 1023, and the color-converting portion 1021 and the light-filtering portion 1024 are directly formed on the side, away from the plurality of light-emitting units 101, of the common electrode layer 103.

As in the thickness direction X, a distance h5 between the first electrodes 104 and the common electrode layer 103 is less than the span h6 of the first encapsulation layer 105 in the thickness direction X, a connection portion of the common electrode layer 103 and the first semiconductor layer 1011 in the light-emitting unit 101 and a portion (the portion is above the light-shielding layer 1023), between adjacent two light-emitting units 101, in the common electrode layer 103 in the first encapsulation layer 105 are not flat. In some embodiments, in the thickness direction X, a distance between the connection portion of the common electrode layer 103 and the first semiconductor layer 1011 in the light-emitting unit 101 and the first electrodes 104 is less than a distance between the portion, between adjacent two light-emitting units 101, in the common electrode layer 103 in the first encapsulation layer 105 and the first electrodes 104.

Furthermore, the first encapsulation layer 105 and the first semiconductor layer 1011 define a plurality of grooves, and the grooves are defined in a region of the connection portion of the common electrode layer 103 and the first semiconductor layer 1011 in the light-emitting unit 101. Thus, the portion of the color-converting portion 1021 in the color-converting assembly 102 directly fills the groove.

In the embodiments of the present disclosure, referring to FIG. 5, the color-converting portion 1021 and the light-filtering portion 1024 are disposed in third accommodation spaces formed by the retaining wall structure 1022 and the light-shielding layer 1023.

Furthermore, for related designs of the retaining wall structure 1022, the color-converting portion 1021, the light-shielding layer 1023, the light-filtering portion 1024, the common electrode layer 103, and the third encapsulation layer 111 in the fifth scheme, reference may be made to detailed description in the third scheme, which are not described again in the embodiments of the present disclosure.

In the fourth scheme, the light-emitting units 101 and the drive units 112 are bonded, and then the retaining wall structure 1022, the light-shielding layer 1023, the common electrode layer 103, the color-converting portion 1021, and the light-filtering portion 1024 are formed on the side, away from the drive units 112, of the light-emitting units 101. The common electrode layer 103 formed by the method includes the target portion M beyond the boundary of the first encapsulation layer 105, and thus the second electrodes are directly and electrically connected to the target portion M, and are further electrically connected to the first semiconductor layers 1011.

In the light-emitting assembly 10 shown in FIG. 5, the blocking portion 108 is in the bowl structure. Each blocking portion 108 surrounds a sidewall of a light-emitting unit 101, and covers the second semiconductor layer 1013 of the light-emitting unit 101. Each blocking portion 108 is made of a conductive material, and the second semiconductor layer 1013 of each light-emitting unit 101 is electrically connected to the first electrode 104 through the blocking portion 108.

In some embodiments, the blocking portion 108 is made of a non-transparent (for example, black) metal material. The blocking portion 108 covers the second semiconductor layer 1013 of the light-emitting unit 101, and the non-transparent metal material is configured to block light, such that the light emitted by the light-emitting units 101 is prevented from emitting from a side of the second semiconductor layer 1013, and the light leakage is avoided.

In some embodiments, the blocking portion 108 is made of Cu, Ni, Al, Ti, Au, or other non-transparent metal materials.

It should be noted that as light emitted by each light-emitting unit 101 may crosstalk the adjacent light-emitting unit along the shared film layer (whether the shared film layer is conductive or not) of a plurality of light-emitting units 101, the light emitted by the light-emitting unit 101 may crosstalk the adjacent light-emitting unit 101 along the common electrode layer 103. By disposing the retaining wall structure 1022 and the light-shielding layer 1023 on the side, close to the light-emitting units 101, of the common electrode layer 103, the common electrode layer 103 is disposed on a slope of the retaining wall structure 1022 and the light-shielding layer 1023, such that a total length of the common electrode layer 103 is increased, a crosstalk path along the common electrode layer 103 is increased, and the possibility of the crosstalk is reduced.

In the embodiments of the present disclosure, a distance d3 between a face, away from the common electrode layer 103, of the color-converting portion 1021 and the first electrodes 104 is greater than or equal to the span h6 of the first encapsulation layer 105 in the thickness direction X. That is, the face, away from the common electrode layer 103, of the color-converting portion 1021 protrudes from an end, away from the common electrode layer 103, of the first encapsulation layer 105. Alternatively, the face, away from the common electrode layer 103, of the color-converting portion 1021 is flushed with the end, away from the common electrode layer 103, of the first encapsulation layer 105.

In the thickness direction X of the light-emitting layer 1012, a ratio h5:h6 of the distance h5 between the first electrodes 104 and the common electrode layer to the span h6 of the first encapsulation layer 105 in the thickness direction X ranges from 0.1 to 0.9. In some embodiments, the ratio h5:h6 ranges from 0.3 to 0.7, for example, 0.5.

In the fourth scheme and fifth scheme, the span h6 of the first encapsulation layer 105 in the thickness direction X is greater than the distance h5 between the first electrodes 104 and the common electrode layer, and the color-converting portion 1021 fills the groove, such that the bonding capability of the color-converting portion 1021 and the first semiconductor layer 1011 is ensured. In addition, the thicker device due to the planarization layer 110 is avoided to facilitate thinning.

In the embodiments of the present disclosure, as an N-type doping layer, a light-emitting layer, and a P-type doping layer need to sequentially formed on a sapphire substrate in manufacturing the light-emitting unit 101, in the case that the first semiconductor layer 1011 is the N-type doping layer, and the second semiconductor layer 1013 is the P-type doping layer, the light-emitting unit 101 and the drive unit 112 that are disposed on the sapphire substrate are directly bonded to cause that the first semiconductor layer 1011 is closer to the color-converting assembly 102 than the second semiconductor layer 1013, and then the sapphire substrate is then removed from a side of the N-type doping layer. Then, the common electrode layer 103, the color-converting assembly 102, and a color film layer 108 are formed on the side, away from the drive unit 112, of the light-emitting unit 101. In this case, the first semiconductor layers 1011 (the N-type doping layers) of at least two light-emitting units 101 are connected via the common electrode layer 103.

In the case that the first semiconductor layer 1011 is the N-type doping layer, and the second semiconductor layer 1013 is the P-type doping layer, the co-anode is achieved via the common electrode layer 103 in the third scheme to the fifth scheme. Correspondingly, the first electrodes 104 are electrically connected to the P-type second semiconductor layer 1013, and the first electrodes 104 are referred to as P-type electrodes; the second electrodes are electrically connected to the N-type first semiconductor layer 1011, and the second electrodes are referred to as N-type electrodes. In some embodiments, the first semiconductor layer 1011 includes N-type GaN, and is denoted as N-GaN. The second semiconductor layer 1013 includes P-type GaN, and is denoted as P-GaN.

In the case that the first semiconductor layer 1011 is the P-type doping layer, and the second semiconductor layer 1013 is the N-type doping layer, in order to cause that the first semiconductor layer 1011 is closer to the color-converting assembly 102 than the second semiconductor layer 1013, the first semiconductor layers 1011, the light-emitting layer 1012, and the second semiconductor layer 1013 are first transferred on an immediate substrate, such that the second semiconductor layers 1013, the light-emitting layer 1012, and the first semiconductor layer 1011 are sequentially laminated in a direction away from the immediate substrate. Then, the light-emitting unit 101 and the drive unit 112 are bonded, the immediate substrate is removed from a side of the P-type doping layer, and the common electrode layer 103, the color-converting assembly 102, and the color film layer 108 are formed on the side, away from the drive unit 112, of the light-emitting unit 101. In this case, the first semiconductor layers 1011 (the P-type doping layers) of at least two light-emitting units 101 are connected via the common electrode layer 103.

In the case that the first semiconductor layer 1011 is the P-type doping layer, and the second semiconductor layer 1013 is the N-type doping layer, the co-anode is achieved via the common electrode layer 103 in the embodiments. Correspondingly, the first electrodes 104 are electrically connected to the N-type second semiconductor layer 1013, and the first electrodes 104 are referred to as N-type electrodes; the second electrodes are electrically connected to the P-type first semiconductor layer 1011, and the second electrodes are referred to as P-type electrodes. In some embodiments, the first semiconductor layer 1011 includes P-type GaN, and is denoted as P-GaN. The second semiconductor layer 1013 includes N-type GaN, and is denoted as N-GaN.

However, compared with the scheme that the first semiconductor layer 1011 is the N-type doping layer and the second semiconductor layer 1013 is the P-type doping layer, one more transfer process (transferring to the immediate substrate) is required in the scheme that the first semiconductor layer 1011 is the P-type doping layer and the second semiconductor layer 1013 is the N-type doping layer, and thus the manufacturing efficiency is low. Thus, in the embodiments, the greater scheme is that the first semiconductor layer 1011 is the N-type doping layer and the second semiconductor layer 1013 is the P-type doping layer.

In the embodiments of the present disclosure, the N-type doping layer (N-GaN) of the light-emitting unit 101 is acquired by doping silicon (Si) in a buffer layer (GaN) formed on the sapphire substrate, and is denoted as GaN:Si. A thickness of the buffer layer is not greater than 10 μm, and a thickness of the N-type doping layer is not greater than 1 μm. The N-type doping layer further includes a supper lattice layer (indium gallium nitride/GaN, InGaN/GaN) for improving lattice quality, and a thickness of the supper lattice layer ranges from 10 nm to 1 μm.

The light-emitting layer 1012 of the light-emitting unit 101 is multi-quantum well (MQW), and the MQW is a laminated layer pair of InGaN/GaN. A number of laminated layer pairs ranges from 4 to 20, and a thickness of each layer ranges from 1 nm to 50 nm.

The P-type doping layer (P-GaN) of the light-emitting unit 101 is acquired by doping magnesium (Mg) in GaN, and a thickness of the P-type doping layer ranges from 100 angstroms to 5 μm.

Furthermore, the light-emitting unit 101 further includes a P-type electron blocking layer between the light-emitting layer 1012 and the P-type doping layer. The P-type electron blocking layer function to block direct passing of electrons, the P-type electron blocking layer is made of aluminum gallium nitride (AlGaN), and a thickness of the P-type electron blocking layer ranges from 1 nm to 1 μm.

The light-emitting unit 101 further includes a current spreading layer on a side, away from the light-emitting layer 1012, of the P-type doping layer. The current spreading layer is made of ITO, and a thickness of the current spreading layer ranges from 10 nm to 1 μm.

In the embodiments of the present disclosure, referring to FIG. 3 to FIG. 5, the drive unit 112 in the light-emitting assembly 10 is disposed on a side, away from the color-converting assembly 102, of the plurality of light-emitting units 101, and is configured to drive the light-emitting units 101 to emit light. The first electrodes and the common electrode layer are electrically connected to the drive unit 112.

The drive unit 112 includes third electrodes 1121. The third electrode 1121 is configured to introduce external signals, for example, the first drive signal or the second drive signal.

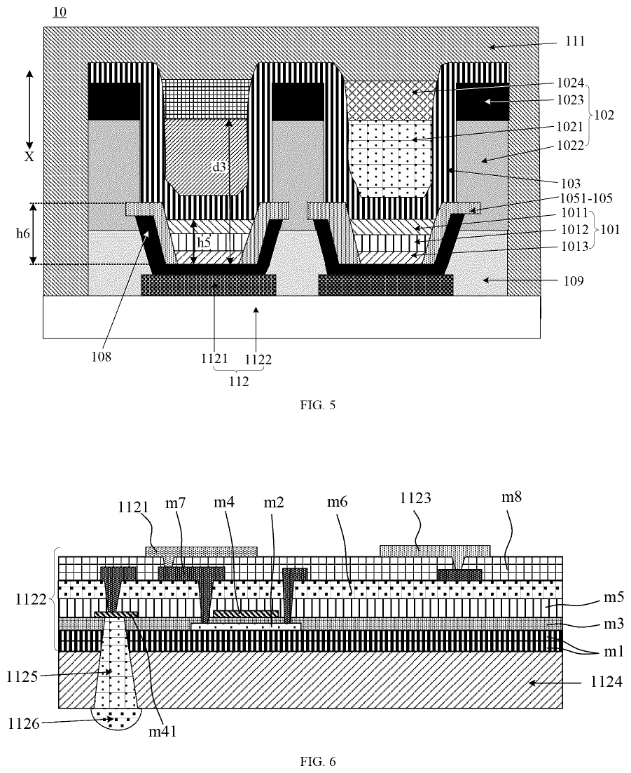

Furthermore, the drive unit 112 further includes a plurality of drive circuits 1122 corresponding to the plurality of light-emitting units 101. The third electrodes 1121 are disposed on a side, facing towards the light-emitting units 101, of the drive unit 112, and are electrically connected to the plurality of drive circuits 1122. In addition, the drive unit 112 further includes a fourth electrode 1123 (shown in FIG. 6). The fourth electrode 1123 is electrically connected to the second electrode 107.

FIG. 6 is a schematic structural diagram of a drive unit according to some embodiments of the present disclosure. It can be seen referring to FIG. 6 that the drive unit 112 further includes a substrate 1124, a connection structure 1125, and a pin 1126. The substrate 1124 is made of polyimide (PI), and the substrate 1124 is a PI substrate. A connect via is defined in the substrate 1124, and the connection structure 1125 is disposed in the connect via.

Referring to FIG. 6, the drive circuit 1122 is disposed on a side of the substrate 1124, and the pin 1126 is disposed on a side, away from the drive circuit 1122, of the substrate and is in contact with the connection structure 112. The pin 1126 is connected to the drive circuit 1122 through the connection structure 1125, such that the pin 1126 transmits drive signals to the drive circuit 1122.

In the embodiments of the present disclosure, the pin 1126 is made of a conductive material, for example, a metal. In some embodiments, the pin 1126 includes a first metal layer and a second metal layer that are laminated. The first metal layer is disposed between the second metal layer and the drive unit 112, that is, the first metal layer is closer to the drive unit 112 than the second metal layer.

A material of the first metal layer includes Ni, and a material of the second metal layer includes Au. For example, the first metal layer is made of Ni, and the second metal layer is made of Au.

By disposing the pin in the embodiments of the present disclosure, the pin is fixedly connected to pads of the drive backplane by a gold plating process by a welding process in affixing the light-emitting assembly 10 and the drive backplane, such that the light-emitting assembly 10 is connected to the drive backplane.

In the embodiments of the present disclosure, the drive circuit 1122 includes a plurality of thin film transistors and at least one storage capacitor. In some embodiments, the drive circuit 1122 includes seven thin film transistors and one storage capacitor, that is, the drive circuit 1122 is a 7T1C drive circuit. Alternatively, the drive circuit 1122 includes another number of thin film transistors and another number of storage capacitors. The number of thin film transistors and the number of storage capacitors in the drive circuit 1122 are not limited in the embodiments of the present disclosure.

Each thin film transistor includes a gate, a source, and a drain. A plurality of thin film transistors in the drive circuit 1122 are connected to drive the light-emitting unit 101 to emit light.

In some embodiments, a plurality of thin film transistors at least include a data write transistor, and a source of the data write transistor is configured to be connected to a data line in the drive backplane in the display substrate. The data line transmits a data drive signal to the drive circuit 1122 through the data write transistor.

In the embodiments of the present disclosure, the pin is connected to the source of the data write transistor in the drive circuit 1122, and the data write transistor is connected to the third electrode 1121 in the drive unit 112 through other thin film transistors, such that the data line in the drive backplane in the display substrate transmits the data drive signal to the first electrode 104 in the light-emitting unit 101 through the pin 1126, the drive circuit 1122, and the third electrode 1121.

It should be noted that the data drive signal is supplied to the first electrode 104 in the light-emitting unit 101, and a power signal (for example, a VSS signal) is also supplied to the second electrode 107 of the light-emitting unit 101 to cause the drive unit 112 to drive the light-emitting unit 101 to emit light.

In some embodiments, power signals supplied by a plurality of light-emitting assemblies 10 in the display substrate by the drive backplane are the same, and thus the power signals are supplied to the second electrodes of the light-emitting units 101 in the plurality of light-emitting assemblies 10 through pins (not shown in the drawing) in a periphery region of the display substrate.

Referring to FIG. 6, the drive circuit 1122 includes a buffer layer (buffer and barrier) m1, an active layer (poly) layer m2, a first gate insulative layer (GI) m3, a first gate layer m4, a second gate insulative layer m5, a second gate layer (not shown in the drawing), an inter level dielectric layer (ILD) m6, a source-drain layer m7, and a planarization layer (PLN) m8. The third electrode 1121 and the fourth electrode in the drive unit 112 are disposed on a side, away from the substrate 1124, of the planarization layer m8.

The buffer layer m1 is made of SiOx, and a thickness of the buffer layer m1 ranges from 300 angstroms to 5000 angstroms.

The active layer m2 includes a plurality of active patterns corresponding to the plurality of thin film transistors, and each active pattern includes a source region, a drain region, and a channel region. The source and the drain of the thin film transistor are disposed in a source-drain layer, the source of the thin film transistor is connected to the source region, and the drain of the thin film transistor is connected to the drain region. The active layer m2 is made of low temperature poly-silicon (p-Si), and a thickness of the active layer m2 ranges from 430 angstroms to 470 angstroms.

The first gate insulative layer m3 is made of generally a laminated layer of SiOx and SiNx, or a single layer of SiOx, and a thickness of the first gate insulative layer m3 ranges from 1100 angstroms to 1500 angstroms, for example, 1200 angstroms.

The first gate layer m4 is made of molybdenum (Mo), or a laminated layer of Ti, Al, and Ti (denoted as Ti/Al/Ti), or a single layer of SiOx, and a thickness of the first gate layer m4 is determined based on circuit simulation requirements, and is generally not greater than 4000 angstroms.

The first gate layer m4 includes a plurality of gate patterns corresponding to the plurality of thin film transistors. The channel region is an overlapped region of an orthographic projection of the gate pattern on the substrate and an orthographic projection of the active pattern on the substrate.

The inter level dielectric layer m6 is made of a laminated layer of SiOx and SiNx (denoted as SiOx/SiNx), and a thickness of the inter level dielectric layer m6 ranges from 4000 angstroms to 6000 angstroms.

The source-drain layer m7 is made of a laminated layer of Ti, Al, and Ti (denoted as Ti/Al/Ti)), and a thickness of the source-drain layer m7 is determined based on circuit simulation requirements, and is generally not greater than 9000 angstroms.

The planarization layer m8 is made of a PI resin, and a thickness of the planarization layer m8 ranges from 1 μm to 3 μm.

The third electrode 1121 and the fourth electrode 1122 are made of Cu, and thickness of the third electrode 1121 and the fourth electrode 1122 range from 8000 angstroms to 3 μm.

Referring to FIG. 6, the first gate layer m4 further includes a gate connection portion m41 connected to the connection structure 1125, and the gate connection portion m41 is configured to be connected to the connection structure and the source of the data write transistor. Connection vias are defined in the buffer layer m1 and the first gate insulative layer m3 to connect the connection structure 1125 to the gate connection portion m41. In addition, the connection structure is disposed in the connection via in the substrate 1124 and the connection vias in the buffer layer m1 and the first gate insulative layer m3.

In the embodiments of the present disclosure, referring to FIG. 6, an area of an orthographic projection of the pin 1126 on the substrate 1124 is greater than an area of an orthographic projection of the connection structure 1125 on the substrate 1124, and the orthographic projection of the pin 1126 on the substrate 1124 covers the orthographic projection of the connection structure 1125 on the substrate 1124. As such, a connection area of the pin 1126 and the connection structure 1125 is as large as possible to ensure connection reliability of the pin 1126 and the connection structure 1125. For example, the connection area is equal to an area of a side, close to the pin 1126, of the connection structure 1125.

In summary, the embodiments of the present disclosure provide a light-emitting assembly. The light-emitting assembly includes a plurality of light-emitting units, a color-converting layer, a common electrode layer, first electrodes, and a first encapsulation layer. The color-converting layer is disposed on one side of the light-emitting units, and is configured to convert colors of light emitted by the light-emitting units. The first electrodes are disposed on the other side of the light-emitting units, and are configured to receive drive signals. The first encapsulation layer is configured to encapsulate the light-emitting units to avoid the mutual effect of any adjacent two light-emitting units 101. At least two of the plurality of light-emitting units are connected as an integrated structure, such that the alignment precision of bonding in subsequently bonding process is ensured, and the yield of the products is improved.

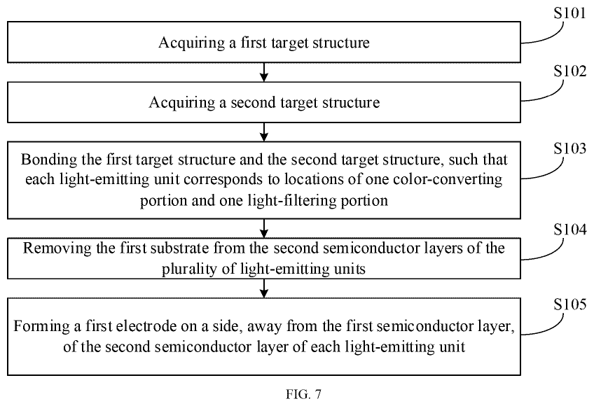

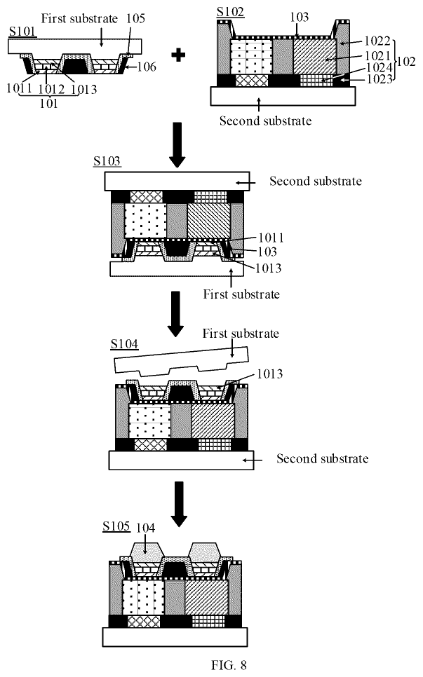

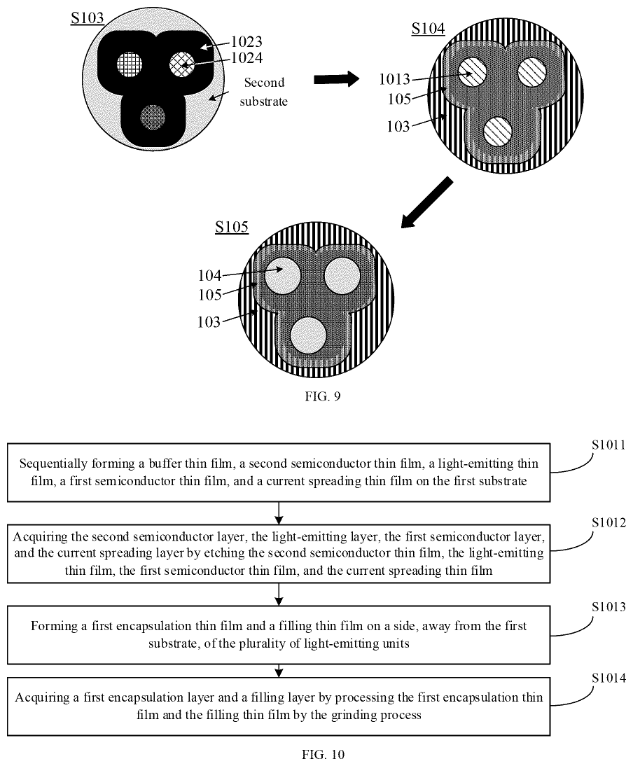

FIG. 7 is a flowchart of a method for manufacturing a light-emitting assembly according to some embodiments of the present disclosure. FIG. 8 is a schematic flowchart of a method for manufacturing a light-emitting assembly according to some embodiments of the present disclosure. FIG. 9 is a top view of a flowchart of some processes in a method for manufacturing a light-emitting assembly according to some embodiments of the present disclosure. Referring to FIG. 7 to FIG. 9, the method includes following processes.

In S101, a first target structure is acquired.

In the embodiments of the present disclosure, the first target structure includes a first substrate, and a plurality of light-emitting units 101, first electrodes 104, a first encapsulation layer 105, and a filling layer 106 that are disposed on the first substrate.

Referring to FIG. 10 to FIG. 12, the process of acquiring the first target structure includes following processes.

In S1011, a buffer thin film, a second semiconductor thin film, a light-emitting thin film, a first semiconductor thin film, and a current spreading thin film are sequentially formed on the first substrate.

The first substrate is a sapphire substrate, the second semiconductor thin film is a N-type thin film, and the first semiconductor thin film is a P-type thin film. FIG. 10 only shows the second semiconductor thin film, the light-emitting thin film, and the first semiconductor thin film for simplifying illustration.

In S1012, the second semiconductor layer, the light-emitting layer, the first semiconductor layer, and the current spreading layer are acquired by etching the second semiconductor thin film, the light-emitting thin film, the first semiconductor thin film, and the current spreading thin film.

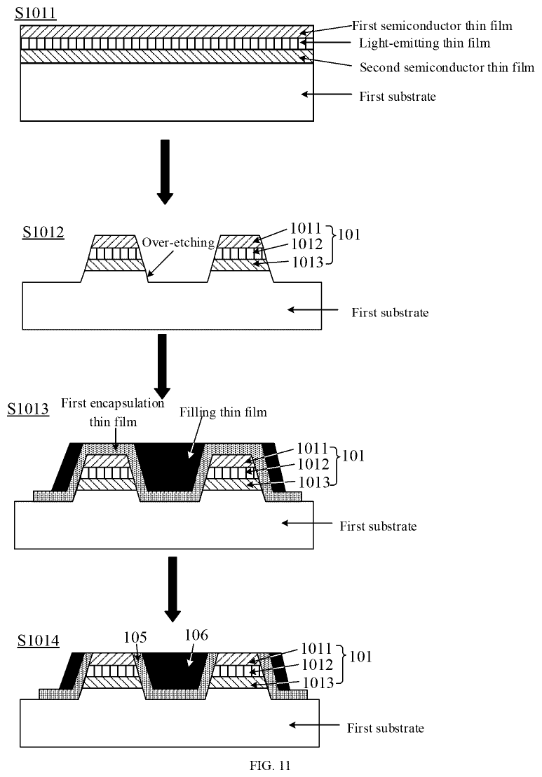

Referring to FIG. 11, in the etching process, the buffer thin film is over-etched to ensure that the second semiconductor thin film is completely etched, such that the buffer layer is acquired. An over-etching amount of the buffer thin film refers to a total thickness of an etched portion of the buffer thin film, and is greater than or equal to 50% of a total thickness of the second semiconductor thin film, the light-emitting thin film, the first semiconductor thin film, and the current spreading thin film.

In S1013, a first encapsulation thin film and a filling thin film are formed on a side, away from the first substrate, of the plurality of light-emitting units.

Referring to FIG. 11, the first encapsulation thin film encloses a sidewall of each light-emitting unit 101, and covers the first semiconductor layer 1011 in each light-emitting unit 101 and covers a region between adjacent two light-emitting units 101. In addition, the filling thin film is disposed on a side, away from the first substrate, of a portion in the first encapsulation thin film between adjacent two light-emitting units 101.

In some embodiments, the first encapsulation thin film is made of one or more of AlO3, SiO, and SiNx. The first encapsulation thin film is manufactured by the ALD, the PECVD, or the sol-gel process. A thickness of the first encapsulation thin film ranges from 100 angstroms to 1 μm.

The filling thin film is made of a non-transparent metal, for example, Cu, Ni, Al, Ti, and Au. The filling thin film is in a single layer structure or a combination structure, and a thickness of the filling thin film ranges from 100 nm to 10 μm.

In S1014, a first encapsulation layer and a filling layer are acquired by processing the first encapsulation thin film and the filling thin film by the grinding process.

The grinding process is a chemical grinding. Referring to FIG. 11 and FIG. 12, the grinding process is performed to completely expose the first semiconductor layers 1011 (expose the current spreading layer in the case that the current spreading layer is disposed) on the side, away from the first substrate, of the second semiconductor layer 1013, such that the subsequent common electrode layer 103 and the first semiconductor layer 1011 are electrically connected to each other.

In the embodiments of the present disclosure, the first encapsulation layer 105 acquired by grinding encloses the sidewall of the light-emitting unit 101, and covers the region between adjacent two light-emitting units 101. The filling layer 106 acquired by grinding is disposed between a side, away from the first substrate, of a portion in the first encapsulation layer 105 between adjacent two light-emitting units 101. That is, referring to FIG. 12, the filling layers 106 enclosing the sidewalls of the adjacent light-emitting units 101 are in an integrated structure.

In S102, a second target structure is acquired.

In the embodiments of the present disclosure, the second target structure includes a second substrate, and a color-converting assembly 102 and a common electrode layer 103 on the second substrate.

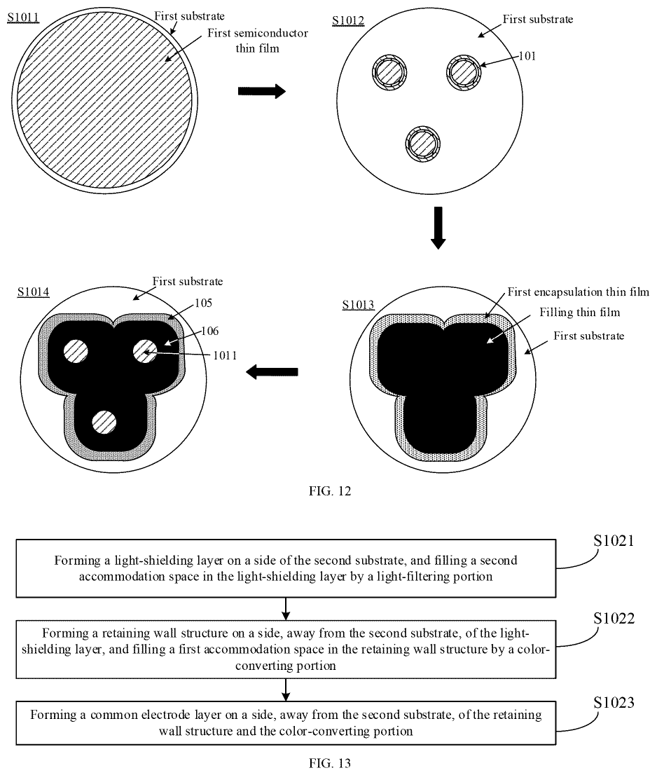

Referring to FIG. 13 to FIG. 15, the process of acquiring the second target structure includes following processes.

In S1021, a light-shielding layer is formed on a side of the second substrate, and a light-filtering portion fills a second accommodation space in the light-shielding layer.

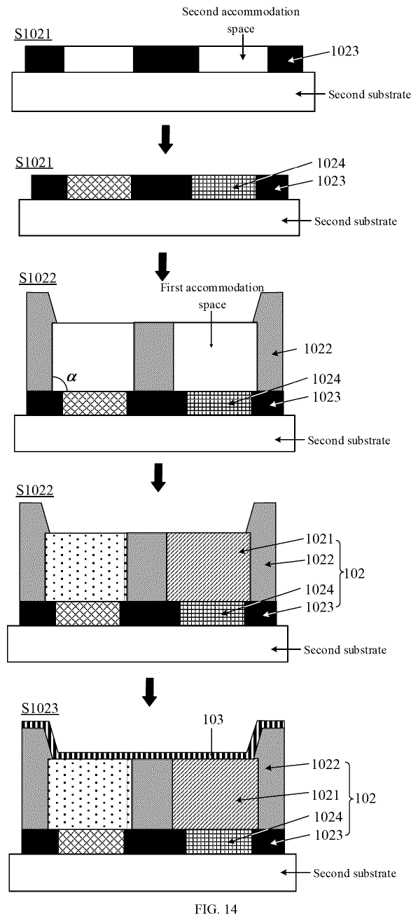

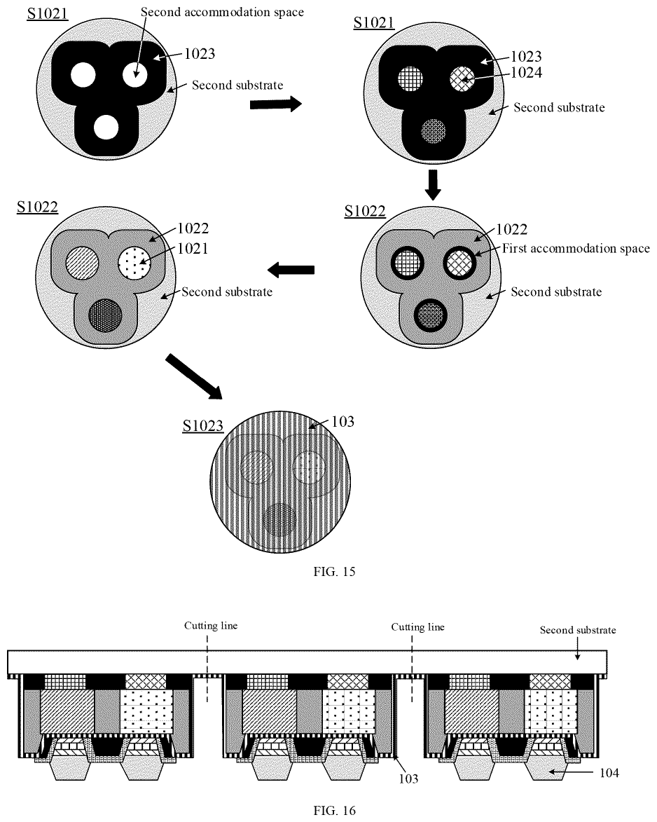

The second substrate is a glass substrate. Referring to FIG. 14 and FIG. 15, the light-shielding layer 1023 is first formed on the side of the second substrate; and then, referring to FIG. 14 and FIG. 15, the light-filtering portion 1024 fills the second accommodation space in the light-shielding layer.

In some embodiments, the light-filtering portion 1024 includes a first light-filtering portion, a second light-filtering portion, and a third light-filtering portion. Each light-filtering portion is disposed in a second accommodation space. The first light-filtering portion is configured to transmit the light at the second wavelength, the second light-filtering portion is configured to transmit the light at the third wavelength, and the third light-filtering portion is configured to transmit the light at the fourth wavelength.

Illustratively, the first light-filtering portion is a red color resistance block, the second light-filtering portion is a green color resistance block, and the third light-filtering portion is a blue color resistance block or a transparent portion.

In S1022, a retaining wall structure is formed on a side, away from the second substrate, of the light-shielding layer, and a color-converting portion fills a first accommodation space in the retaining wall structure.

Referring to FIG. 14 and FIG. 15, the retaining wall structure 1022 is disposed on the side, away from the second substrate, of the light-shielding layer 1023; and then, referring to FIG. 14 and FIG. 15, the color-converting portion 1021 fills the first accommodation space in the retaining wall structure 1022.

The colors of the light emitted by the plurality of light-emitting units 101 in the light-emitting assembly 10 are light at the first wavelength. The color-converting portion 1021 includes a first color-converting portion, a second color-converting portion, and a third color-converting portion. The first color-converting portion converts the light at the first wavelength to light at the second wavelength, the second color-converting portion converts the light at the first wavelength to light at the third wavelength, and the third color-converting portion converts the light at the first wavelength to light at the fourth wavelength.

Illustratively, a color of the light at the first wavelength is blue, that is, the plurality of light-emitting units 101 are all blue light-emitting units. A color of the light at the second wavelength is red, and the first color-converting portion converts blue light at the first wavelength to red light at the second wavelength. A color of the light at the third wavelength is green, and the second color-converting portion converts blue light at the first wavelength to green light at the third wavelength. A color of the light at the fourth wavelength is blue, and the third color-converting portion converts blue light at the first wavelength to blue light at the fourth wavelength. The first wavelength and the fourth wavelength are equal or different.

Illustratively, assuming that the first wavelength and the fourth wavelength are equal, the first color-converting portion includes red QDs, the second color-converting portion includes green QDs, and the third color-converting portion is a transparent portion, then the transparent portion is configured to transmit the light at the first wavelength emitted by the light-emitting units 101. For example, the transparent portion is made of a transparent OC.

In some embodiments, referring to FIG. 14, an included angle between the sidewall of the retaining wall structure 1022 and the bearing face of the second substrate is less than 90°, such that the color-converting portion does not fall from the first accommodation space in the case that the color-converting portion is filled and the whole structure is overturned.

In S1023, a common electrode layer is formed on a side, away from the second substrate, of the retaining wall structure and the color-converting portion.

Referring to FIG. 14 and FIG. 15, the common electrode layer 103 is formed on a whole face. A thickness of the common electrode layer 103 ranges from 200 angstroms to 1000 angstroms, and the common electrode layer 103 is made of ITO, IZO, IGZO, or other transparent conductive materials. The common electrode layer 103 mainly functions to provide a charge interface of the first semiconductor layers 1011 to the light-emitting units 101.

In S103, the first target structure and the second target structure are bonded, such that each light-emitting unit corresponds to locations of one color-converting portion and one light-filtering portion.

In the embodiments of the present disclosure, upon bonding, the first semiconductor layers 1011 of the plurality of light-emitting units 101 are electrically connected to the common electrode layer 103. In addition, the second semiconductor layer 1012 of the light-emitting unit 101 is farther away from the second substrate than the first semiconductor layer 1011.

An opening region of the color-converting assembly 102 refers to a region provided with the color-converting portion 1021 or the transparent portion, and an opening region of the color film layer 108 refers to a region provided with the light-filtering portion 1024.

FIG. 9 is a top view of a flowchart of some processes in a method for manufacturing a light-emitting assembly according to some embodiments of the present disclosure. Referring to FIG. 9, as the second substrate is a transparent glass substrate, the light-shielding layer 1023 and the light-filtering portion 1024 can be seen from the top view. FIG. 9 illustratively shows three light-filtering portions 1024.

FIG. 8 only illustratively shows two light-emitting units 101, two color-converting portions 1021, and two light-filtering portions 1024 in FIG. 9 for simplifying illustration. Upon bonding of the first target structure and the second target structure, a first light-emitting unit corresponds to a location of a first color-converting portion and a portion of a first light-filtering portion, and a second light-emitting unit corresponds to a location of a second color-converting portion and a portion of a second light-filtering portion.

As such, colors of light emitted by the first light-emitting unit are converted by the first color-converting portion, and the light of which the color is converted is emitted through the first light-filtering portion. A color of light emitted by the second light-emitting unit is converted by the second color-converting portion, and the light of which the color is converted is emitted through the second light-filtering portion.

In S104, the first substrate is removed from the second semiconductor layers of the plurality of light-emitting units.

The first substrate (sapphire substrate) is removed by a laser removing method, and the process of removing the first substrate further includes removing the buffer layer. That is, the whole structure upon bonding and removing exposes the second semiconductor layers 1013 (N-type doped) of the light-emitting units 101.

The top view of S104 shown in FIG. 9 is a schematic diagram of removing the first substrate and overturning the top view of S103.

In S105, a first electrode is formed on a side, away from the first semiconductor layer, of the second semiconductor layer of each light-emitting unit.

In the embodiments of the present disclosure, prior to formation of the first electrode 104 and the second electrode, the second semiconductor layer 1013 needs to be shallow etched (shallow etching means that an etching depth is small) to wash the face of the second semiconductor layer 1013 and remove impurities on the face of the second semiconductor layer 1013.

Then referring to FIG. 8 and FIG. 9, the first electrode 104 is formed on a side, away from the first semiconductor layer 1011, of the second semiconductor layer 1013 of each light-emitting unit 101, such that a third target structure is acquired. The third target structure is the light-emitting assembly 10.

In the embodiments of the present disclosure, a size of the third target structure is determined based on a size of the second substrate (the glass substrate). In general, the size of the second substrate in the third target structure is large for mass production of products.

The third target structure is cut based on requirements of clients upon acquisition of a large-sized third target structure, such that a small-sized structure is acquired. Alternatively, the large-sized third target structure is directly bonded to the subsequent drive unit 112, which is not limited in the embodiments of the present disclosure.

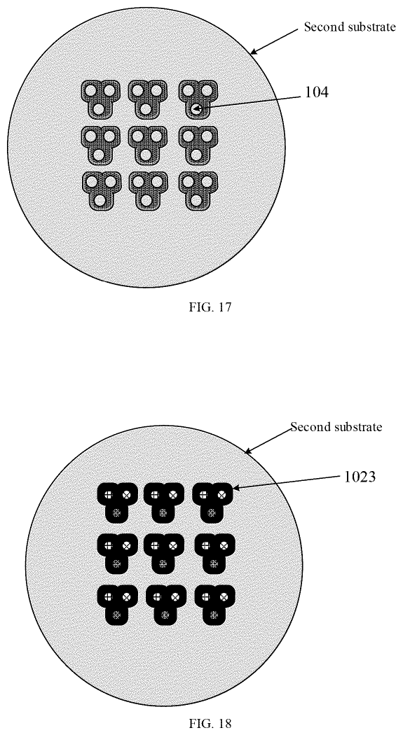

In some embodiments, referring to FIG. 16 to FIG. 18, in the case that the third target structure needs to be cut, cutting positions are reserved in manufacturing process (that is, a plurality of light-emitting assemblies are sparsely arranged). For example, in FIG. 16, the cutting is performed along cutting lines. An arrangement period of sparse arrangement is determined based on requirements the pixel density of the display substrate.

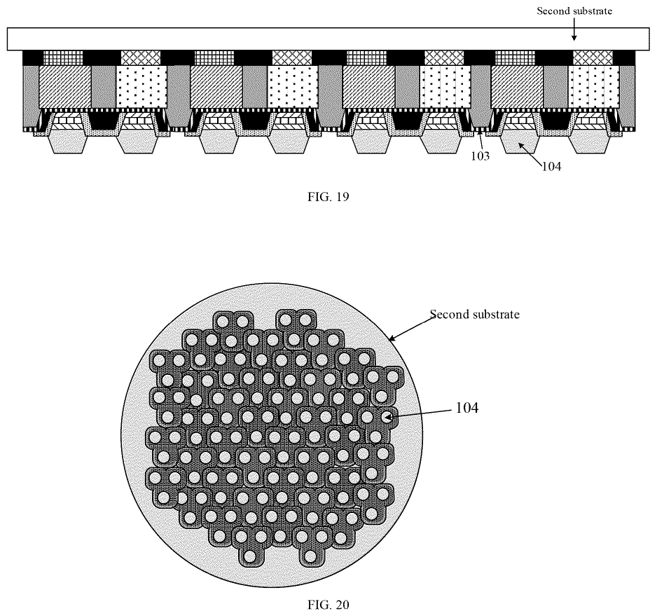

Alternatively, referring to FIG. 19 and FIG. 20, in the case that the third target structure does not need to be cut, any adjacent light-emitting units 101 are closely disposed in the manufacturing process (closely arranged), such that the plurality of light-emitting units 101 are electrically connected to the common electrode layer 103.

In the embodiments of the present disclosure, no matter whether the third target structure is cut in the process, only the sizes and the numbers of light-emitting units are different, and the film layer structures of the light-emitting units are the same. In the subsequent description, the third target structure is still used to collectively refer to the two ways.

In summary, the embodiments of the present disclosure provide a method for manufacturing a light-emitting assembly. The light-emitting assembly includes a plurality of light-emitting units, a color-converting layer, a common electrode layer, first electrodes, and a first encapsulation layer. The color-converting layer is disposed on one side of the light-emitting units, and is configured to convert colors of light emitted by the light-emitting units. The first electrodes are disposed on the other side of the light-emitting units, and are configured to receive drive signals. The first encapsulation layer is configured to encapsulate the light-emitting units to avoid the mutual effect of any adjacent two light-emitting units 101. At least two of the plurality of light-emitting units are connected as an integrated structure, such that the alignment precision of bonding in subsequently bonding process is ensured, and the yield of the products is improved.

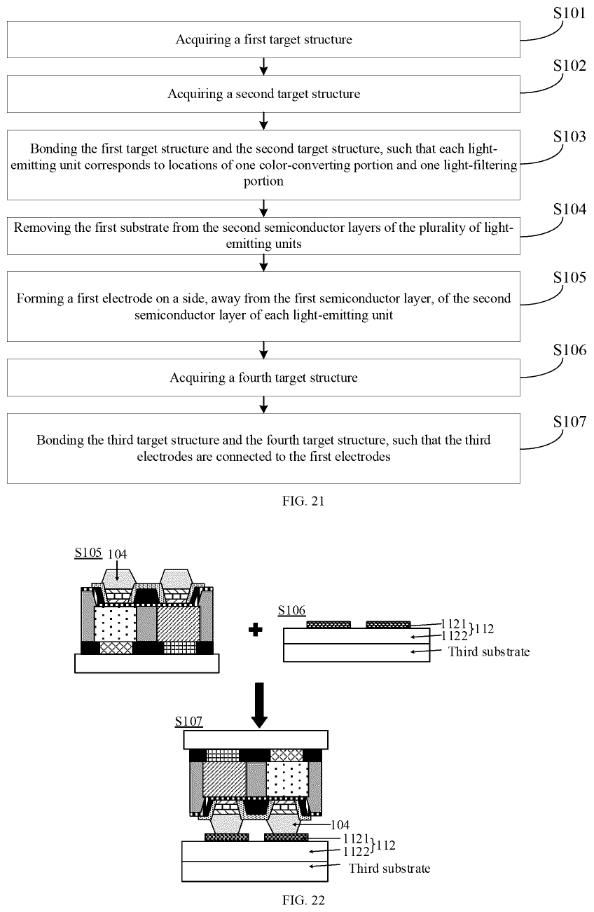

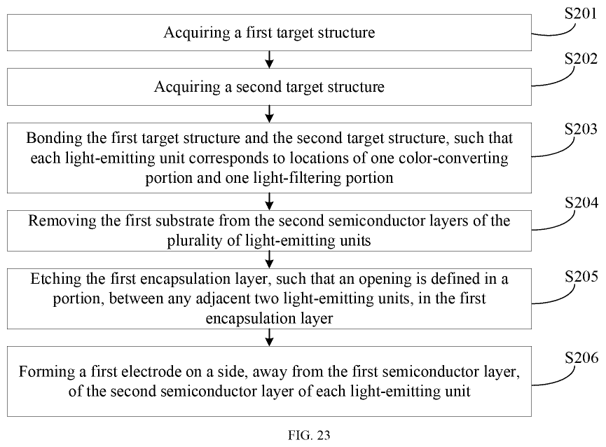

In the embodiments of the present disclosure, upon acquisition of the third target structure, a fourth target structure of a corresponding size (including the drive unit) is acquired no matter whether the third target structure is cut, and the third target structure and the fourth target structure are bonded to acquire a display substrate. Referring to FIG. 21 and FIG. 22, the method includes the following processes.

In S106, a fourth target structure is acquired.

In the embodiments of the present disclosure, referring to FIG. 22, the fourth target structure includes a third substrate, and a drive unit 112 on the third substrate. The drive unit 112 includes third electrodes 1121 and a plurality of drive circuits 1122 corresponding to the plurality of light-emitting units 101. The third electrodes 1121 are electrically connected to the drive circuits 1122.

In S107, the third target structure and the fourth target structure are bonded, such that the third electrodes are connected to the first electrodes.

Referring to FIG. 22, the third target structure and the fourth target structure are bonded, such that the third electrodes 1121 are connected to the first electrodes 104.

Then, the third substrate is removed from the side of the drive circuit 1022, and the pin 1126 is formed on the side of the drive circuit 1022, such that the pads of the drive backplane is fixedly connected to the pin 1126, and the light-emitting assembly 10 is connected to the drive backplane.

In addition, upon bonding the third target structure to the fourth target structure, a gap is present between the third target structure and the fourth target structure. A bonding layer fills the gap, and the bonding layer is made of the OC material, the ink, the black adhesive, and the like, which is not limited in the embodiments of the present disclosure. Alternatively, the gap is not filled with a material.

Furthermore, upon bonding the third target structure to the fourth target structure, an encapsulation layer is formed on a side, away from the drive unit, of the second substrate to encapsulate the product. The encapsulation layer is made of an inorganic material, for example, a single layer of SiNx, SiOx, AlO3, or TiO, or a laminated later of combination thereof. In addition, the encapsulation layer further includes an organic film layer acquired by an ink-jet printing process.

In the embodiments of the present disclosure, the color-converting assembly is formed on the second substrate (the glass substrate) to achieve color display. In addition, the massive transfer process is not required in subsequent bonding to the drive units, such that the probability of the light leakage from the sidewall and crosstalk leakage between adjacent light-emitting units is reduced, the production efficiency and the yield are improved, and the production cost is reduced.

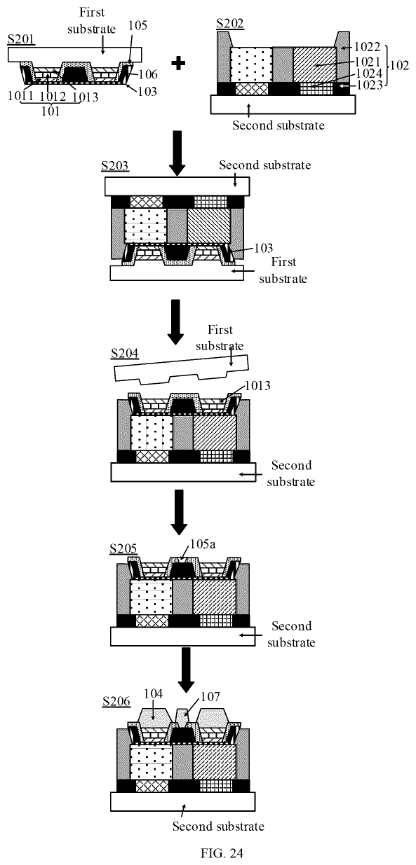

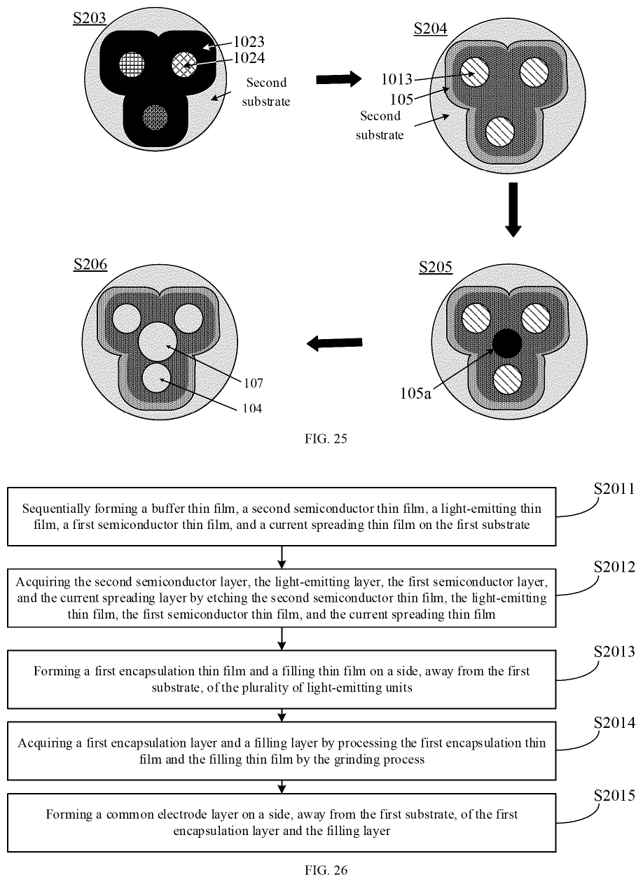

FIG. 23 is a flowchart of a method for manufacturing a light-emitting assembly according to some embodiments of the present disclosure. FIG. 24 is a schematic flowchart of a method for manufacturing a light-emitting assembly according to some embodiments of the present disclosure. FIG. 25 is a top view of a flowchart of some processes in a method for manufacturing a light-emitting assembly according to some embodiments of the present disclosure. Referring to FIG. 23 to FIG. 25, the method includes following processes.

In S201, a first target structure is acquired.

In the embodiments of the present disclosure, the first target structure includes a first substrate, and a plurality of light-emitting units 101, first electrodes 104, a first encapsulation layer 105, a filling layer 106, and a common electrode layer 103 that are disposed on the first substrate.

Referring to FIG. 26 to FIG. 28, the process of acquiring the first target structure includes following processes.

In S2011, a buffer thin film, a second semiconductor thin film, a light-emitting thin film, a first semiconductor thin film, and a current spreading thin film are sequentially formed on the first substrate.

In the embodiments of the present disclosure, for related description of S2011, reference may be made to detailed description of S1011, which is not described again herein in the embodiments of the present disclosure.

In S2012, the second semiconductor layer, the light-emitting layer, the first semiconductor layer, and the current spreading layer are acquired by etching the second semiconductor thin film, the light-emitting thin film, the first semiconductor thin film, and the current spreading thin film.

In the embodiments of the present disclosure, for related description of S2012, reference may be made to detailed description of S1012, which is not described again herein in the embodiments of the present disclosure.

In S2013, a first encapsulation thin film and a filling thin film are formed on a side, away from the first substrate, of the plurality of light-emitting units.

In the embodiments of the present disclosure, for related description of S2013, reference may be made to detailed description of S1013, which is not described again herein in the embodiments of the present disclosure.

In S2014, a first encapsulation layer and a filling layer are acquired by processing the first encapsulation thin film and the filling thin film by the grinding process.

In the embodiments of the present disclosure, for related description of S2014, reference may be made to detailed description of S1014, which is not described again herein in the embodiments of the present disclosure.

In S2015, a common electrode layer is formed on a side, away from the first substrate, of the first encapsulation layer and the filling layer.

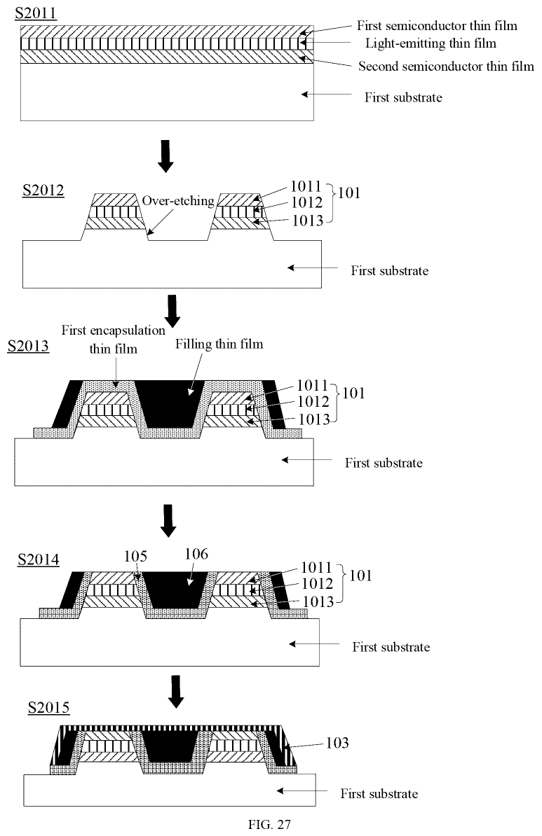

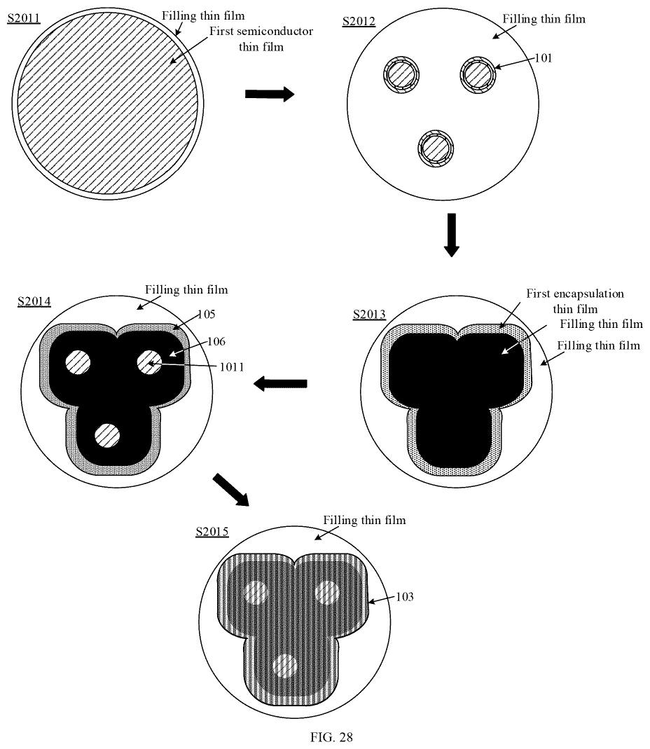

Referring to FIG. 27 and FIG. 28, the common electrode layer 103 connects first semiconductor layers 1011 of different light-emitting units 101. The common electrode layer 103 is a transparent conductive thin film. For example, the common electrode layer 103 is made of ITO, IZO, IGZO, or other transparent conductive materials. The common electrode layer 103 mainly functions to connect the first semiconductor layers 1011 of at least two light-emitting units 101 to provide a charge interface to the light-emitting units 101. In addition, a thickness of the common electrode layer 103 ranges from 200 angstroms to 1000 angstroms.

In S202, a second target structure is acquired.

The second target structure includes a second substrate, and a color-converting assembly 102 on the second substrate.

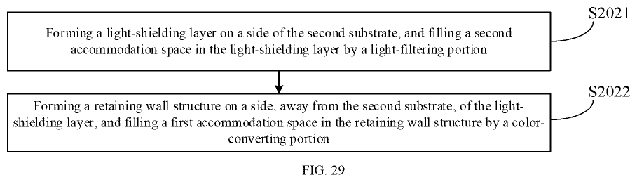

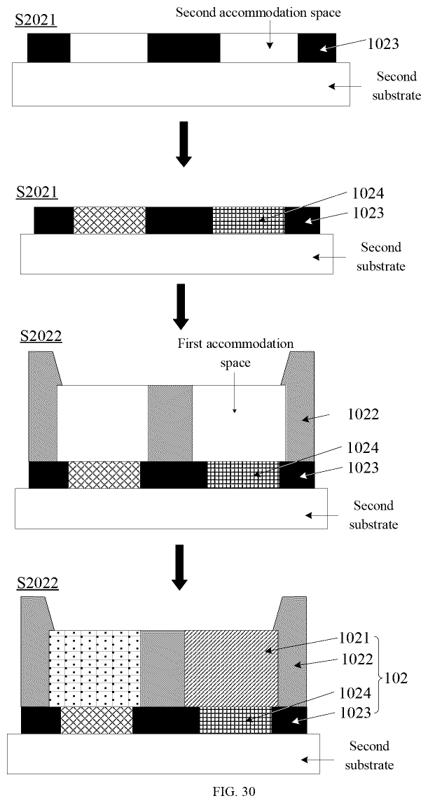

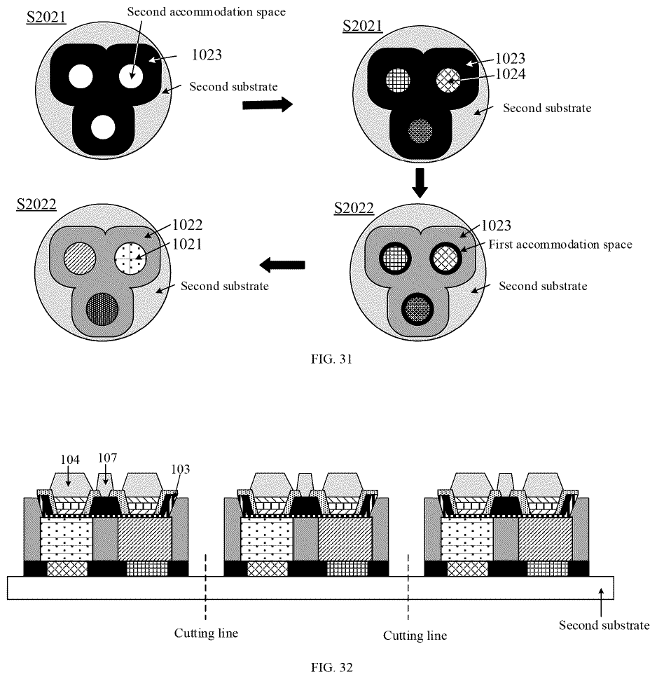

Referring to FIG. 29 to FIG. 31, the process of acquiring the second target structure includes following processes.

In S2021, a light-shielding layer is formed on a side of the second substrate, and a light-filtering portion fills a second accommodation space in the light-shielding layer.

In the embodiments of the present disclosure, for related description of S2021, reference may be made to detailed description of S1021, which is not described again herein in the embodiments of the present disclosure.

In S2022, a retaining wall structure is formed on a side, away from the second substrate, of the light-shielding layer, and a color-converting portion fills a first accommodation space in the retaining wall structure.

In the embodiments of the present disclosure, for related description of S2022, reference may be made to detailed description of S1022, which is not described again herein in the embodiments of the present disclosure.

In S203, the first target structure and the second target structure are bonded, such that each light-emitting unit corresponds to locations of one color-converting portion and one light-filtering portion.

In the embodiments of the present disclosure, for related description of S203, reference may be made to detailed description of S103, which is not described again herein in the embodiments of the present disclosure.

In S204, the first substrate is removed from the second semiconductor layers of the plurality of light-emitting units.

In the embodiments of the present disclosure, for related description of S204, reference may be made to detailed description of S104, which is not described again herein in the embodiments of the present disclosure. The top view of S204 shown in FIG. 28 is a schematic diagram of removing the first substrate and overturning the top view of S203.

In S205, the first encapsulation layer is etched, such that an opening is defined in a portion, between any adjacent two light-emitting units, in the first encapsulation layer.

In the embodiments of the present disclosure, as the common electrode layer 103 is formed on the second substrate including the light-emitting unit 101, the formed common electrode layer 103 does not include the target portion M beyond the boundary of the first encapsulation layer 105. For transmission of signals in the common electrode layer 103, referring to FIG. 24, the first encapsulation layer is etched to acquire the via 105a. The via 105a exposes the filling layer 106 between adjacent two light-emitting units 101.

In some embodiments, the filling layer 106 is made of a conductive material, such that the subsequently formed second electrodes are connected to the common electrode layer 103 via the filling layer 106.

In S206, a first electrode is formed on a side, away from the first semiconductor layer, of the second semiconductor layer of each light-emitting unit.

In the embodiments of the present disclosure, prior to formation of the first electrode 104 and the second electrode 107, the second semiconductor layer 1013 needs to be shallow etched to wash the face of the second semiconductor layer 1013 and remove impurities on the face of the second semiconductor layer 1013.

Then referring to FIG. 24, the first electrode 104 is formed on a side, away from the first semiconductor layer 1011, of the second semiconductor layer 1013 of each light-emitting unit 101, such that a third target structure is acquired. The third target structure includes the light-emitting assembly 10.

In the embodiments of the present disclosure, a size of the third target structure is determined based on a size of the second substrate (the glass substrate). In general, the size of the second substrate in the third target structure is large for mass production of products.

The third target structure is cut based on requirements of clients upon acquisition of a large-sized third target structure, such that a small-sized structure is acquired. Alternatively, the large-sized third target structure is directly bonded to the subsequent drive unit 112, which is not limited in the embodiments of the present disclosure.

In some embodiments, referring to FIG. 32, in the case that the third target structure needs to be cut, cutting positions are reserved in the manufacturing process (that is, a plurality of light-emitting assemblies are sparsely arranged). For example, in FIG. 32, the cutting is performed along cutting lines. An arrangement period of sparse arrangement is determined based on requirements of the pixel density of the display substrate.

Alternatively, referring to FIG. 33, in the case that the third target structure does not need to be cut, any adjacent light-emitting units 101 are closely disposed in the manufacturing process (closely arranged), such that the plurality of light-emitting units 101 are electrically connected to the common electrode layer 103.

In the embodiments of the present disclosure, no matter whether the third target structure is cut in the process, only the sizes are different, and the film layer structures are the same. In the subsequent description, the third target structure is still used to collectively refer to the two ways.

Compared the second manufacturing process (S201 to S206) to the first manufacturing process (S101 to S105), the second manufacturing process and the first manufacturing process mainly differ in that the common electrode layer 103 is formed on the second substrate including the color-converting assembly in the first manufacturing process, and the common electrode layer 103 is formed on the first substrate including the light-emitting unit 101 in the second manufacturing process.

For the first manufacturing process, in the case that the first target structure and the second target structure are bonded, as the common electrode layer 103 is formed on the second substrate, the connection reliability of the common electrode layer 103 and the light-emitting units 101 is poor due to poor alignment precision of the first substrate and the second substrate, such that uniformity of transmission of signals to the first semiconductor layers 1011 of different light-emitting units 101 by the common electrode layer 103 is poor. Thus, the second manufacturing process is provided, such that the common electrode layer 103 is directly formed on the side, away from the first substrate, of the first semiconductor layer 1011.

In summary, the embodiments of the present disclosure provide a method for manufacturing a light-emitting assembly. The light-emitting assembly includes a plurality of light-emitting units, a color-converting layer, a common electrode layer, first electrodes, and a first encapsulation layer. The color-converting layer is disposed on one side of the light-emitting units, and is configured to convert colors of light emitted by the light-emitting units. The first electrodes are disposed on the other side of the light-emitting units, and are configured to receive drive signals. The first encapsulation layer is configured to encapsulate the light-emitting units to avoid the mutual effect of any adjacent two light-emitting units 101. At least two of the plurality of light-emitting units are connected as an integrated structure, such that the alignment precision of bonding in subsequently bonding process is ensured, and the yield of the products is improved.

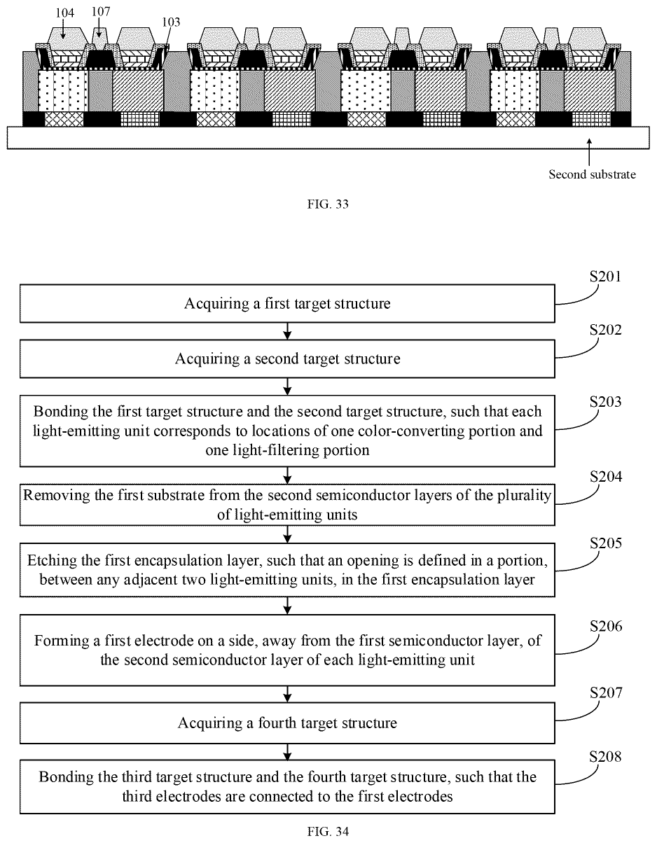

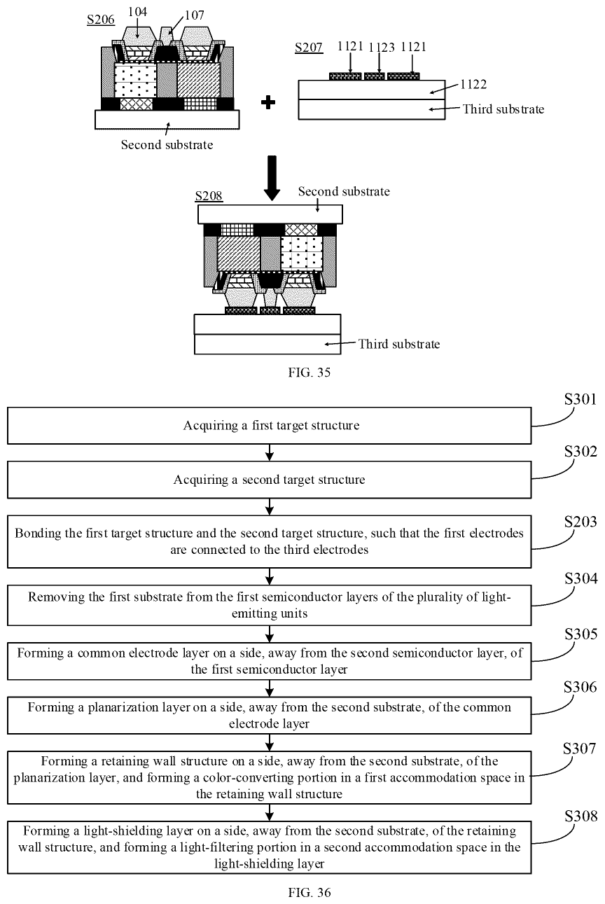

In the embodiments of the present disclosure, upon acquisition of the third target structure, a fourth target structure of a corresponding size (including the drive unit) is acquired no matter whether the third target structure is cut, and the third target structure and the fourth target structure are bonded to acquire a display substrate. Referring to FIG. 34 and FIG. 35, the method includes the following processes.

In S207, a fourth target structure is acquired.

In the embodiments of the present disclosure, for related description of S207, reference may be made to detailed description of S106, which is not described again herein in the embodiments of the present disclosure.

In S208, the third target structure and the fourth target structure are bonded, such that the third electrodes are connected to the first electrodes.

In the embodiments of the present disclosure, for related description of S208, reference may be made to detailed description of S107, which is not described again herein in the embodiments of the present disclosure.

In the embodiments of the present disclosure, the color-converting assembly is formed on the second substrate (the glass substrate) to achieve color display. In addition, the massive transfer process is not required in subsequent bonding to the drive units, such that the probability of the light leakage from the sidewall and crosstalk leakage between adjacent light-emitting units is reduced, the production efficiency and the yield are improved, and the production cost is reduced.

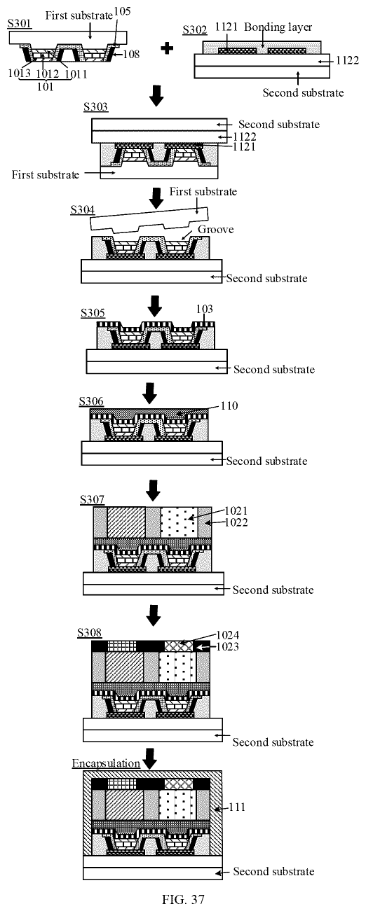

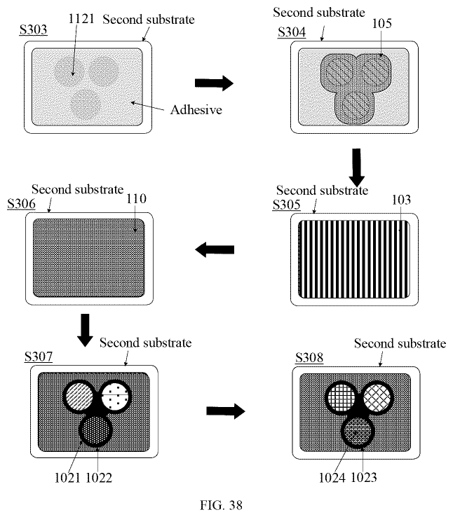

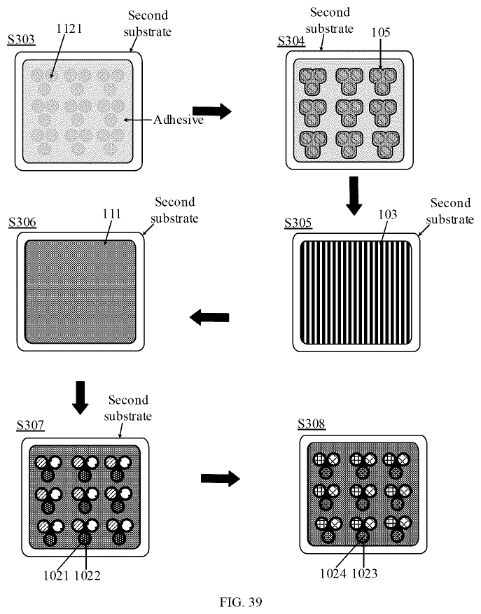

FIG. 36 is a flowchart of a method for manufacturing a light-emitting assembly according to some embodiments of the present disclosure. FIG. 37 is a schematic flowchart of a method for manufacturing a light-emitting assembly according to some embodiments of the present disclosure. FIG. 38 is a top view of a flowchart of some processes in a method for manufacturing a light-emitting assembly according to some embodiments of the present disclosure. FIG. 39 is a top view of a flowchart of some processes in a method for manufacturing a light-emitting assembly according to some embodiments of the present disclosure. Referring to FIG. 36 to FIG. 39, the method includes following processes.

In S301, a first target structure is acquired.

In the embodiments of the present disclosure, the first target structure includes a first substrate, and a plurality of light-emitting units 101, first electrodes 104, a first encapsulation layer 105, and blocking portions 108 that are disposed on the first substrate.

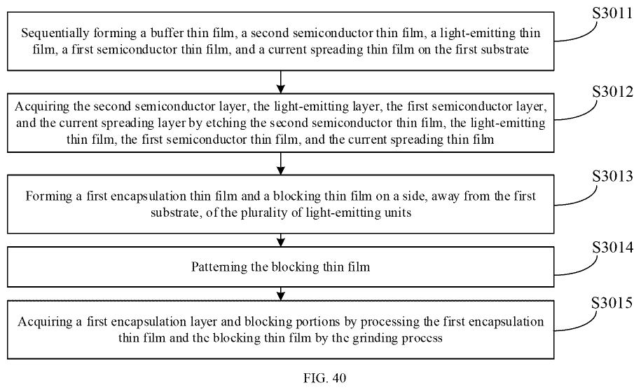

Referring to FIG. 40 to FIG. 42, the process of acquiring the first target structure includes following processes.

In S3011, a buffer thin film, a second semiconductor thin film, a light-emitting thin film, a first semiconductor thin film, and a current spreading thin film are sequentially formed on the first substrate.

In the embodiments of the present disclosure, for related description of S3011, reference may be made to detailed description of S1011, which is not described again herein in the embodiments of the present disclosure.

In S3012, the second semiconductor layer, the light-emitting layer, the first semiconductor layer, and the current spreading layer are acquired by etching the second semiconductor thin film, the light-emitting thin film, the first semiconductor thin film, and the current spreading thin film.

In the embodiments of the present disclosure, for related description of S3012, reference may be made to detailed description of S1012, which is not described again herein in the embodiments of the present disclosure.

In S3013, a first encapsulation thin film and a blocking thin film are formed on a side, away from the first substrate, of the plurality of light-emitting units.

In the embodiments of the present disclosure, for related description of S3013, reference may be made to detailed description of S1013, which is not described again herein in the embodiments of the present disclosure. In addition, for the manufacturing process of the blocking thin film in S3013, reference may be made to detailed description of the manufacturing process of the filling thin film in S1013.

In S3014, the blocking thin film is patterned.

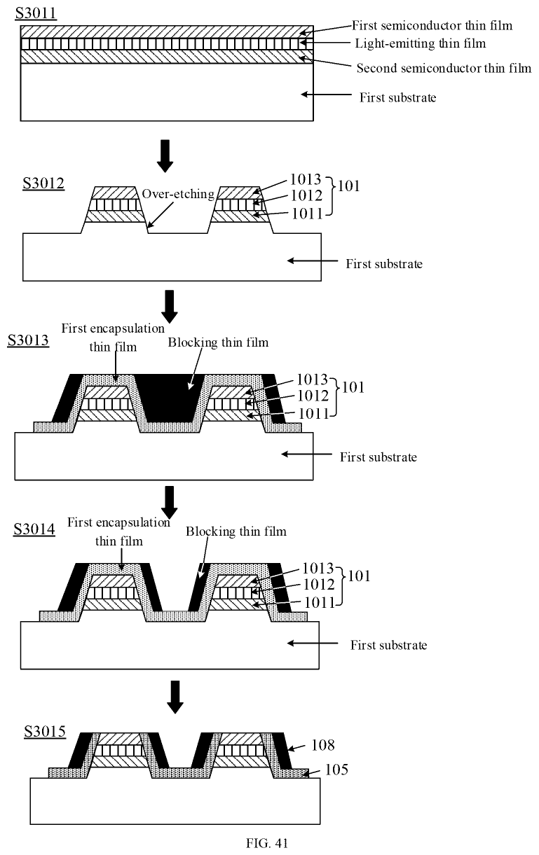

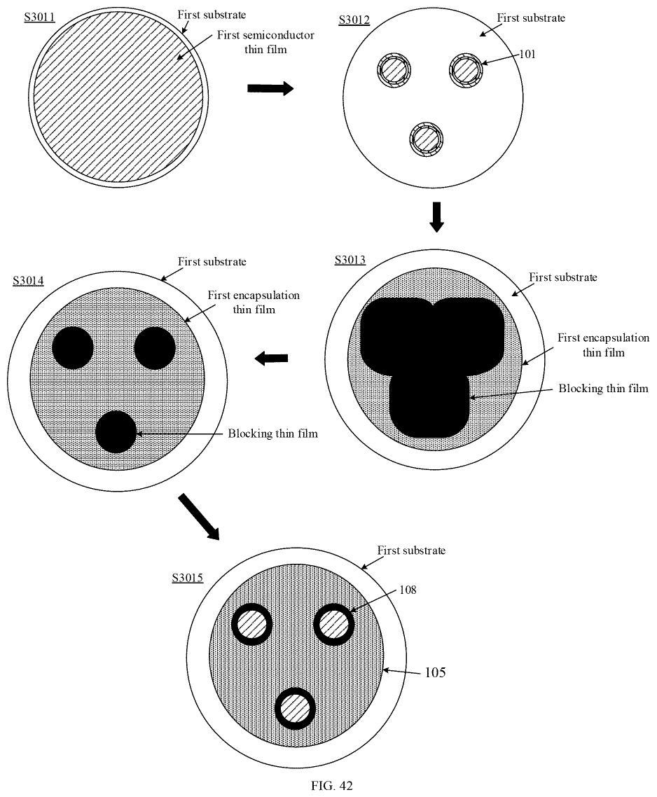

It can be seen referring to FIG. 41 and FIG. 42 that, at least part of the blocking thin film between adjacent light-emitting units 101 is removed upon patterning process of the blocking thin film, such that the blocking thin film includes a plurality of spaced patterns.

In S3015, a first encapsulation layer and blocking portions are acquired by processing the first encapsulation thin film and the blocking thin film by the grinding process.

The grinding process is a chemical grinding. Referring to FIG. 41 and FIG. 42, the grinding process is performed to completely expose the first semiconductor layers 1011 (expose the current spreading layer in the case that the current spreading layer is disposed) on the side, away from the first substrate, of the second semiconductor layer 1013, such that the subsequent common electrode layer 103 is connected to the first semiconductor layer 1011 through the current spreading layer.

In the embodiments of the present disclosure, the first encapsulation layer 105 acquired by grinding encloses the sidewall of the light-emitting unit 101, and covers the region between adjacent two light-emitting units 101. Any adjacent two of the plurality of blocking portions 108 acquired by grinding are spaced apart. That is, referring to FIG. 38, the blocking portion 108 is in an annular structure enclosing the light-emitting unit 101.

In the embodiments of the present disclosure, upon the grinding process, the first electrodes 104 are formed on a side, away from the first semiconductor layer 1011, of the second semiconductor layer 1013, such that the first target structure is bonded to the second target structure. Alternatively, the current spreading layer is determined as the first electrodes to be bonded to the second target structure.

In S302, a second target structure is acquired.

In the embodiments of the present disclosure, the second target structure includes a second substrate, and drive units 112 on the second substrate. The drive unit 112 includes the third electrodes 1121 and a plurality of drive circuits 1122 corresponding to the plurality of light-emitting units 101. The third electrodes 1121 are electrically connected to the plurality of drive circuits 1122.

In S303, the first target structure and the second target structure are bonded, such that the first electrodes are connected to the third electrodes.

In the embodiments of the present disclosure, prior to bonding the first target structure and the second target structure, a bonding layer 109 (a bonding adhesive) is coated on a side of the second target structure provided with the third electrodes 1121. In bonding process, the first target structure squeezes the bonding layer 109, such that the first electrodes 104 are connected to the third electrodes 1121.

Referring to FIG. 37, the bonding layer 109 is disposed in a gap between the drive unit 112 in the second target structure and the first substrate in the first target structure upon bonding the first target structure and the second target structure. The bonding layer 109 is configured to support the first target structure to avoid collapse of part of the structure in removing the first substrate.

In S304, the first substrate is removed from the first semiconductor layers of the plurality of light-emitting units.

The first substrate (sapphire substrate) is removed by a laser removing method, and the process of removing the first substrate further includes removing the buffer layer. That is, the whole structure upon bonding and removing exposes the first semiconductor layers 1011 (N-type doped) of the light-emitting units 101.

In addition, in S3012, the over-etching process is required in acquiring the first target structure, and thus a groove is defined in a side, away from the second substrate, of the first encapsulation layer 105 upon removal of the first substrate. Specifically, in the thickness direction of the light-emitting layer 102, a distance between the first electrodes 104 and the common electrode layer 103 is less than a span of the first encapsulation layer 105 in the thickness direction.

The top view of S304 shown in FIG. 38 is a schematic diagram of removing the first substrate and overturning the top view of S303.

In S305, a common electrode layer is formed on a side, away from the second semiconductor layer, of the first semiconductor layer.

Referring to FIG. 37 and FIG. 38, the common electrode layer 103 is formed on a whole face of a side, away from the second semiconductor layer 1013, of the first semiconductor layer 1011, and the common electrode layer 103 is electrically connected to the first semiconductor layers 1011 of the plurality of light-emitting units 101. A thickness of the common electrode layer 103 ranges from 200 angstroms to 1000 angstroms, and the common electrode layer 103 is made of ITO, IZO, IGZO, or other transparent conductive materials. The common electrode layer 103 mainly functions to provide a charge interface of the first semiconductor layers 1011 to the light-emitting units 101.

In addition, one part of the common electrode layer 103 is disposed in the groove, and the other part of the common electrode layer 103 is disposed outside the groove. A distance between the portion in the groove and the second substrate is less than a distance between the portion outside the accommodation space and the second substrate. That is, a face, away from the second substrate, of the common electrode layer 103 is a non-flat face.

In S306, a planarization layer is formed on a side, away from the second substrate, of the common electrode layer.

In the embodiments of the present disclosure, as the flatness of the face of the whole structure is poor upon formation of the common electrode layer 103, and the color-converting portion 1021 and the light-filtering portion 1024 need to be disposed, the planarization layer 110 is formed on the side, away from the second substrate, of the common electrode layer 103 to ensure the uniformity of the color-converting portion 1021 and the light-filtering portion 1024. Referring to FIG. 37, the face, away from the common electrode layer 103, of the planarization layer 110 is a flat face, such that the color-converting portion 1021 and the light-filtering portion 1024 are subsequently formed on the face to ensure the uniformity of the color-converting portion 1021 and the light-filtering portion 1024.

In addition, one part of the planarization layer 110 is disposed above the portion of the common electrode layer 103 in the groove, and the other part of the planarization layer 110 is disposed above the portion of the common electrode layer 103 outside the groove. As such, a contact area of the face, close to the second substrate, of the planarization layer 110 and the common electrode layer 103 is increased, the contact bonding force of the planarization layer 110 and the common electrode layer 103 is improved, and the reliability of the flattening effect of the planarization layer 110 is ensured.

In S307, a retaining wall structure is formed on a side, away from the second substrate, of the planarization layer, and a color-converting portion is formed in a first accommodation space in the retaining wall structure.

In the embodiments of the present disclosure, referring to FIG. 37, the retaining wall structure 1022 is formed on a flat face, away from the second substrate, of the planarization layer 110, and the color-converting portion 1021 fills the first accommodation space in the retaining wall structure 1022.

The color-converting portion 1021 includes a first color-converting portion, a second color-converting portion, and a third color-converting portion. The first color-converting portion converts the light at the first wavelength to light at the second wavelength, the second color-converting portion converts the light at the first wavelength to light at the third wavelength, and the third color-converting portion converts the light at the first wavelength to light at the fourth wavelength.

A color of the light at the second wavelength is red, and the first color-converting portion converts blue light at the first wavelength to red light at the second wavelength. A color of the light at the third wavelength is green, and the second color-converting portion converts blue light at the first wavelength to green light at the third wavelength. A color of the light at the fourth wavelength is blue, and the third color-converting portion converts blue light at the first wavelength to blue light at the fourth wavelength. The first wavelength and the fourth wavelength are equal or different.

Illustratively, assuming that the first wavelength and the fourth wavelength are equal, the first color-converting portion includes red QDs, the second color-converting portion includes green QDs, and the third color-converting portion is a transparent portion, then the transparent portion is configured to transmit the light at the first wavelength emitted by the light-emitting units 101. For example, the transparent portion is made of a transparent OC.

In S308, a light-shielding layer is formed on a side, away from the second substrate, of the retaining wall structure, and a light-filtering portion is formed in a second accommodation space in the light-shielding layer.

Referring to FIG. 37, the light-shielding layer 1023 is formed on the side, away from the second substrate, of the retaining wall structure 1022, and the light-filtering portion 1024 fills the second accommodation space in the light-shielding layer 1023.

In some embodiments, the light-filtering portion 1024 includes a first light-filtering portion transmitting the light at the second wavelength, a second light-filtering portion transmitting the light at the third wavelength, and a third light-filtering portion transmitting the light at the fourth wavelength. The first light-filtering portion is a red color resistance block, corresponds to a location of the first color-converting portion, and is configured to transmit red light at the second wavelength converted by the first color-converting portion. The second light-filtering portion is a green color resistance block, corresponds to a location of the second color-converting portion, and is configured to transmit green light at the third wavelength converted by the second color-converting portion. The third light-filtering portion is a blue color resistance block or a transparent portion, corresponds to a location of the third color-converting portion, and is configured to transmit blue light at the fourth wavelength converted by the third color-converting portion.

Eventually, a third encapsulation layer 111 is disposed on a side, away from the second substrate, of the color-converting assembly 102 to encapsulate the light-emitting assembly 10. The third encapsulation layer 111 wraps edges of a plurality of light-emitting units 101, such that the plurality of light-emitting units 101 are whole encapsulated, corrosion of related structures of the light-emitting assembly 10 due to exposure is avoided, and the yield of the light-emitting assembly 10 is ensured.

In some embodiments, the encapsulation layer is made of an inorganic material, for example, a single layer of SiNx, SiOx, AlO3, or TiO, or a laminated later of combination thereof. In addition, the encapsulation layer further includes an organic film layer acquired by an ink-jet printing process.

It should be noted that the retaining wall structure 1022 and the light-shielding layer 1023 are acquired by a single process. That is, S307 and S308 are forming the retaining wall structure 1022 and the light-shielding layer 1023 on the side, away from the second substrate, of the planarization layer 110; and the color-converting portion 1021 and the light-filtering portion 1024 are sequentially formed in the groove and the accommodation space formed by the retaining wall structure 1022 and the light-shielding layer 1023.

In the embodiments of the present disclosure, one or more light-emitting assemblies are manufactured by the method, and a number of the light-emitting assemblies is related to a number of drive circuits in the drive unit. A number of drive circuits is determined based on the size of the second substrate. In generally, for mass production of products, a large-sized second substrate is used, and a plurality of drive circuits are formed on the second substrate to acquire a plurality of light-emitting assemblies. As shown in FIG. 39, nine light-emitting assemblies are acquired, and each light-emitting assembly includes three light-emitting units.

In the embodiments of the present disclosure, upon bonding of the light-emitting unit to the drive unit, the color-converting assembly is directly formed on the second substrate (the glass substrate) including the drive unit and the light-emitting unit to achieve color display. The massive transfer process is not required in the method, such that the probability of the light leakage from the sidewall and crosstalk leakage between adjacent light-emitting units is reduced, the production efficiency and the yield are improved, and the production cost is reduced.

In addition, the color-converting assembly is formed on the second substrate (the glass substrate) including the drive unit and the light-emitting unit to achieve color display, such that mismatching in bonding the color-converting assembly is avoided. It should be noted that the basic principle of the manufacturing sequence is to first perform the high temperature process and then perform the low temperature process. As the temperature for manufacturing the color-converting assembly is low, and the temperature for manufacturing the drive circuit is high, the color conversion layer and the color film layer are directly formed on the second substrate (the glass substrate) including the drive unit and the light-emitting unit upon formation of the drive unit and bonding of the light-emitting unit to the drive circuit, and the process compatibility is not violated.

In summary, the embodiments of the present disclosure provide a method for manufacturing a light-emitting assembly. The light-emitting assembly includes a plurality of light-emitting units, a color-converting layer, a common electrode layer, first electrodes, and a first encapsulation layer. The color-converting layer is disposed on one side of the light-emitting units, and is configured to convert colors of light emitted by the light-emitting units. The first electrodes are disposed on the other side of the light-emitting units, and are configured to receive drive signals. The first encapsulation layer is configured to encapsulate the light-emitting units to avoid the mutual effect of any adjacent two light-emitting units 101. At least two of the plurality of light-emitting units are connected as an integrated structure, such that the alignment precision of bonding in subsequently bonding process is ensured, and the yield of the products is improved.

In the embodiments of the present disclosure, S301 to S308 may also be used to manufacture the display substrate. In some embodiments, the display substrate is manufactured upon S301 to S308, the second substrate is removed from the side of the drive circuit 1022, and the pin 1126 is formed on the side of the drive circuit 1022, such that the pads of the drive backplane is fixedly connected to the pin 1126, and the light-emitting assembly 10 is connected to the drive backplane.

In some embodiments, in the case that the display substrate needs to be manufactured, the size of the second target structure acquired in S302 is larger, and the number of drive circuits is great. That is, a desired product is acquired by selecting an appropriate second target structure.

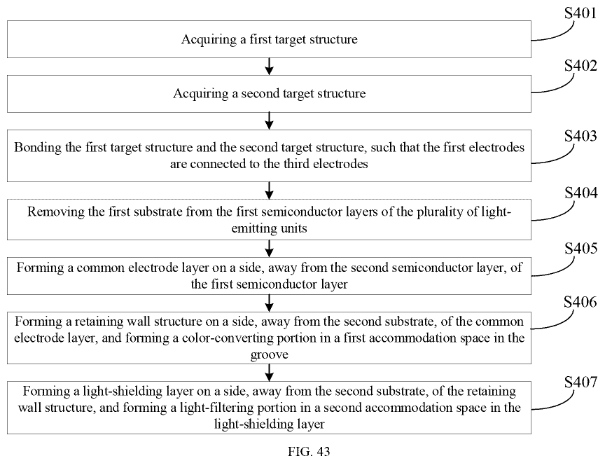

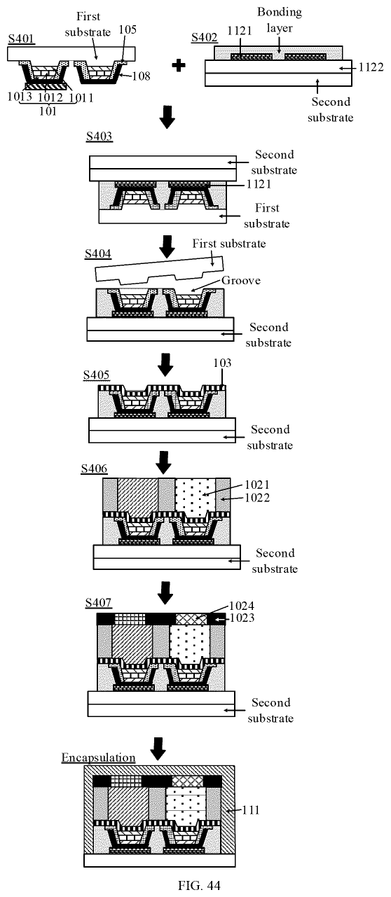

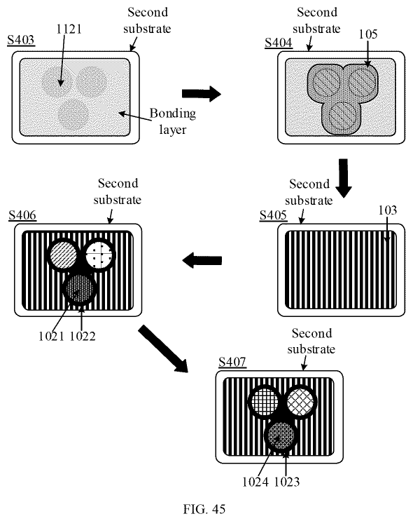

FIG. 43 is a flowchart of a method for manufacturing a light-emitting assembly according to some embodiments of the present disclosure. FIG. 44 is a schematic flowchart of a method for manufacturing a light-emitting assembly according to some embodiments of the present disclosure. FIG. 45 is a top view of a flowchart of some processes in a method for manufacturing a light-emitting assembly according to some embodiments of the present disclosure. Referring to FIG. 43 to FIG. 45, the method includes following processes.

In S401, a first target structure is acquired.

In the embodiments of the present disclosure, the first target structure includes a first substrate, and a plurality of light-emitting units 101, first electrodes 104, a first encapsulation layer 105, and a filling layer 106 that are disposed on the first substrate.

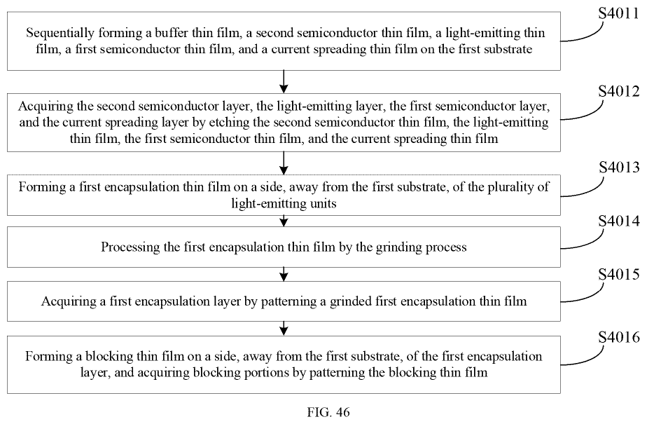

Referring to FIG. 46 to FIG. 48, the process of acquiring the first target structure includes following processes.

In S4011, a buffer thin film, a second semiconductor thin film, a light-emitting thin film, a first semiconductor thin film, and a current spreading thin film are sequentially formed on the first substrate.

In the embodiments of the present disclosure, for related description of S4011, reference may be made to detailed description of S1011, which is not described again herein in the embodiments of the present disclosure.

In S4012, the second semiconductor layer, the light-emitting layer, the first semiconductor layer, and the current spreading layer are acquired by etching the second semiconductor thin film, the light-emitting thin film, the first semiconductor thin film, and the current spreading thin film.

In the embodiments of the present disclosure, for related description of S4012, reference may be made to detailed description of S1012, which is not described again herein in the embodiments of the present disclosure.

In S4013, a first encapsulation thin film is formed on a side, away from the first substrate, of the plurality of light-emitting units.

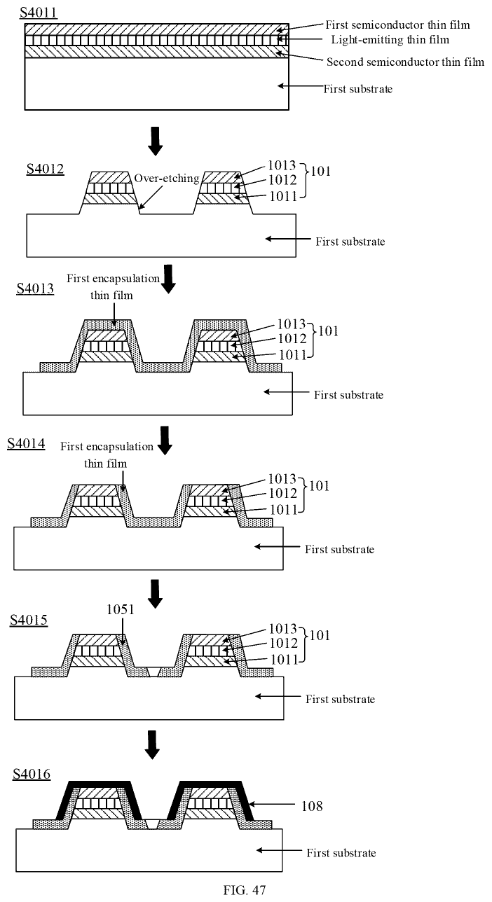

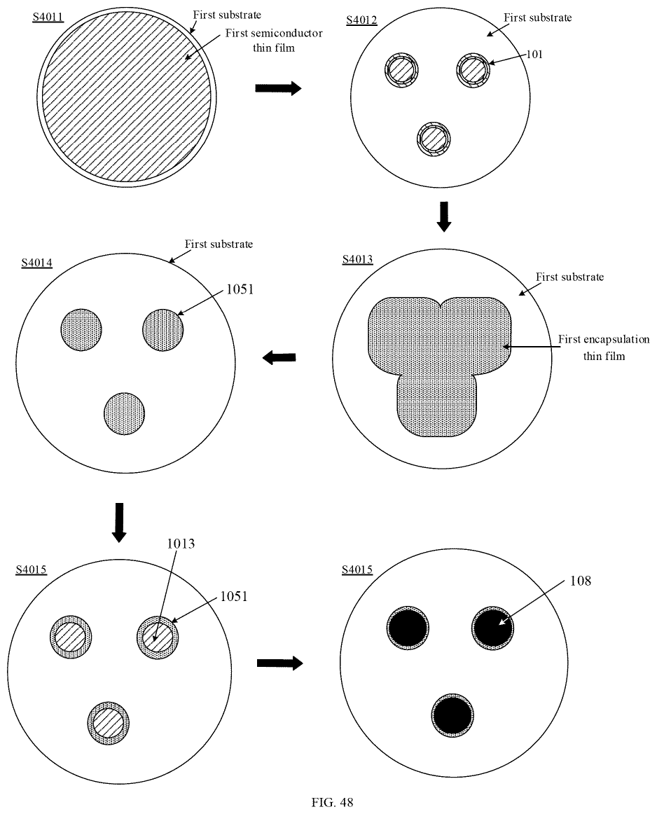

In the embodiments of the present disclosure, referring to FIG. 47 and FIG. 48, the first encapsulation thin film encloses a sidewall of each light-emitting unit 101, and covers the first semiconductor layer 1011 in each light-emitting unit 101 and covers a region between adjacent two light-emitting units 101.

In some embodiments, the first encapsulation thin film is made of one or more of AlO3, SiO, and SiNx. The first encapsulation thin film is manufactured by the ALD, the PECVD, or the sol-gel process. A thickness of the first encapsulation thin film ranges from 100 angstroms to 1 μm.

In S4014, the first encapsulation thin film is processed by the grinding process.

The grinding process is a chemical grinding. Referring to FIG. 43 and FIG. 44, the grinding process is performed to completely expose the second semiconductor layer 1013, such that the subsequent common electrode layer 103 and the first semiconductor layer 1011 are electrically connected to each other.

Referring to FIG. 47 and FIG. 48, the first encapsulation layer acquired by grinding includes the second semiconductor layer 1013 (N-type doped) exposing the light-emitting unit 101.

In S4015, a first encapsulation layer is acquired by patterning a grinded first encapsulation thin film.

Referring to FIG. 47 and FIG. 48, the patterning process is performed to separate the first encapsulation layers 105 enclosing different light-emitting units 101, such that the first encapsulation layer 105 includes a plurality of spaced encapsulation patterns 1051. Each encapsulation pattern 1051 encloses the sidewall of one light-emitting unit 101, and exposes the second semiconductor layer 1013 of one light-emitting unit 101.

As the encapsulation patterns 1051 are spaced apart, crosstalk of light emitted by the light-emitting unit 101 to the adjacent light emitting unit 101 along the first encapsulation layer 105 is avoided to ensure the display effect of the light-emitting assembly 10.

In S4016, a blocking thin film is formed on a side, away from the first substrate, of the first encapsulation layer, and blocking portions are acquired by patterning the blocking thin film.

The blocking thin film is made of a conductive material, for example, Cu, Ni, Al, Ti, Au, or other non-transparent metal materials. The blocking thin film is in a single layer structure or a combination structure, and a thickness of the blocking thin film ranges from 100 nm to 10 μm. Referring to FIG. 47 and FIG. 48, each of the plurality of blocking portions 108 acquired by patterning the blocking thin film is in the bowl structure. Each blocking portion 108 surrounds a sidewall of a light-emitting unit 101, and covers the second semiconductor layer 1013 of the light-emitting unit 101.

In the embodiments of the present disclosure, the first electrodes 104 corresponding to the blocking portions 108 are formed prior to or upon formation of the blocking portions 108 to facilitate bonding the first target structure to the second target structure. In the case that the first electrodes 104 are formed prior to formation of the blocking portions 108, the first electrode 104 is disposed between the blocking portion 108 and the second semiconductor layer 1013, and then the blocking portion 108 is bonded to the second target structure. In the case that the first electrodes 104 are formed upon formation of the blocking portions 108, the first electrode 104 is disposed on a side, away from the second semiconductor layer 1013, of the blocking portion 108, such that the first electrode 104 is bonded to the second target structure. Alternatively, the first electrodes 104 are not disposed, and the blocking portion 108 is determined as the first electrode to be bonded to the second target structure.

In S402, a second target structure is acquired.

In the embodiments of the present disclosure, for related description of S402, reference may be made to detailed description of S302, which is not described again herein in the embodiments of the present disclosure.

In S403, the first target structure and the second target structure are bonded, such that the first electrodes are connected to the third electrodes.

In the embodiments of the present disclosure, for related description of S403, reference may be made to detailed description of S303, which is not described again herein in the embodiments of the present disclosure.

In S404, the first substrate is removed from the first semiconductor layers of the plurality of light-emitting units.

In the embodiments of the present disclosure, for related description of S404, reference may be made to detailed description of S304, which is not described again herein in the embodiments of the present disclosure.

In S405, a common electrode layer is formed on a side, away from the second semiconductor layer, of the first semiconductor layer.

In the embodiments of the present disclosure, for related description of S405, reference may be made to detailed description of S305, which is not described again herein in the embodiments of the present disclosure.

In S406, a retaining wall structure is formed on a side, away from the second substrate, of the common electrode layer, and a color-converting portion is formed in a groove and a first accommodation space.

In the embodiments of the present disclosure, referring to FIG. 43 and FIG. 44, the retaining wall structure 1022 is directly formed on the side, away from the second substrate, of the common electrode layer 103. The retaining wall structure is disposed above the portion of the common electrode layer 103 outside the groove. The first accommodation space formed by the retaining wall structure 1022 exposes the portion of the common electrode layer 103 in the groove.

As such, the color-converting portion 1021 is directly formed in the groove and the first accommodation space. As the color-converting portion 1021 is disposed in the groove, the contact area of the color-converting portion 1021 and the common electrode layer 103 is increased, and the contact bonding force of the color-converting portion 1021 and the common electrode layer 103 is improved to avoid separation of the color-converting portion 1021. In addition, the planarization layer 110 is not disposed in the scheme, and thus the whole thickness of the entire structure is reduced to facilitate achieving the thinning effect.

The color-converting portion 1021 includes a first color-converting portion, a second color-converting portion, and a third color-converting portion. The first color-converting portion converts the light at the first wavelength to light at the second wavelength, the second color-converting portion converts the light at the first wavelength to light at the third wavelength, and the third color-converting portion converts the light at the first wavelength to light at the fourth wavelength.

A color of the light at the second wavelength is red, and the first color-converting portion converts blue light at the first wavelength to red light at the second wavelength. A color of the light at the third wavelength is green, and the second color-converting portion converts blue light at the first wavelength to green light at the third wavelength. A color of the light at the fourth wavelength is blue, and the third color-converting portion converts blue light at the first wavelength to blue light at the fourth wavelength. The first wavelength and the fourth wavelength are equal or different.

Illustratively, assuming that the first wavelength and the fourth wavelength are equal, the first color-converting portion includes red QDs, the second color-converting portion includes green QDs, and the third color-converting portion is a transparent portion, then the transparent portion is configured to transmit the light at the first wavelength emitted by the light-emitting units 101. For example, the transparent portion is made of a transparent OC.

In S407, a light-shielding layer is formed on a side, away from the second substrate, of the retaining wall structure, and a light-filtering portion is formed in a second accommodation space.

Referring to FIG. 47 and FIG. 48, the light-shielding layer 1023 is formed on the side, away from the second substrate, of the retaining wall structure 1022, and the light-filtering portion 1024 fills the second accommodation space in the light-shielding layer 1023.

In some embodiments, the light-filtering portion 1024 includes a first light-filtering portion transmitting the light at the second wavelength, a second light-filtering portion transmitting the light at the third wavelength, and a third light-filtering portion transmitting the light at the fourth wavelength. The first light-filtering portion is a red color resistance block, corresponds to a location of the first color-converting portion, and is configured to transmit red light at the second wavelength converted by the first color-converting portion. The second light-filtering portion is a green color resistance block, corresponds to a location of the second color-converting portion, and is configured to transmit green light at the third wavelength converted by the second color-converting portion. The third light-filtering portion is a blue color resistance block or a transparent portion, corresponds to a location of the third color-converting portion, and is configured to transmit blue light at the fourth wavelength converted by the third color-converting portion.

Eventually, a third encapsulation layer 111 is disposed on a side, away from the second substrate, of the color-converting assembly 102 to encapsulate the light-emitting assembly 10. The third encapsulation layer 111 wraps edges of a plurality of light-emitting units 101, such that the plurality of light-emitting units 101 are whole encapsulated, corrosion of related structures of the light-emitting assembly 10 due to exposure is avoided, and the yield of the light-emitting assembly 10 is ensured.

In some embodiments, the encapsulation layer is made of an inorganic material, for example, a single layer of SiNx, SiOx, AlO3, or TiO, or a laminated later of combination thereof. In addition, the encapsulation layer further includes an organic film layer acquired by an ink-jet printing process.

It should be noted that the retaining wall structure 1022 and the light-shielding layer 1023 are acquired by a single process. That is, S407 and S408 are forming the retaining wall structure 1022 and the light-shielding layer 1023 on the side, away from the second substrate, of the planarization layer 110; and the color-converting portion 1021 and the light-filtering portion 1024 are sequentially formed in the accommodation space formed by the groove, the retaining wall structure 1022 and the light-shielding layer 1023.

In the embodiments of the present disclosure, one or more light-emitting assemblies are manufactured by the method, and a number of the light-emitting assemblies is related to a number of drive circuits in the drive unit. A number of drive circuits is determined based on the size of the second substrate. In generally, for mass production of products, a large-sized second substrate is used, and a plurality of drive circuits are formed on the second substrate to acquire a plurality of light-emitting assemblies.

In the embodiments of the present disclosure, upon bonding of the light-emitting unit to the drive unit, the color-converting assembly is directly formed on the second substrate (the glass substrate) including the drive unit and the light-emitting unit to achieve color display. The massive transfer process is not required in the method, such that the probability of the light leakage from the sidewall and crosstalk leakage between adjacent light-emitting units is reduced, the production efficiency and the yield are improved, and the production cost is reduced.

In addition, the color-converting assembly is formed on the second substrate (the glass substrate) including the drive unit and the light-emitting unit to achieve color display, such that mismatching in bonding the color-converting assembly is avoided. It should be noted that the basic principle of the manufacturing sequence is to first perform the high temperature process and then perform the low temperature process. As the temperature for manufacturing the color-converting assembly is low, and the temperature for manufacturing the drive circuit is high, the color conversion layer and the color film layer are directly formed on the second substrate (the glass substrate) including the drive unit and the light-emitting unit upon formation of the drive unit and bonding of the light-emitting unit to the drive circuit, and the process compatibility is not violated.

In summary, the embodiments of the present disclosure provide a method for manufacturing a light-emitting assembly. The light-emitting assembly includes a plurality of light-emitting units, a color-converting layer, a common electrode layer, first electrodes, and a first encapsulation layer. The color-converting layer is disposed on one side of the light-emitting units, and is configured to convert colors of light emitted by the light-emitting units. The first electrodes are disposed on the other side of the light-emitting units, and are configured to receive drive signals. The first encapsulation layer is configured to encapsulate the light-emitting units to avoid the mutual effect of any adjacent two light-emitting units 101. At least two of the plurality of light-emitting units are connected as an integrated structure, such that the alignment precision of bonding in subsequently bonding process is ensured, and the yield of the products is improved.

In the embodiments of the present disclosure, S401 to S408 may also be used to manufacture the display substrate. In some embodiments, the display substrate is manufactured upon S401 to S408, the second substrate is removed from the side of the drive circuit 1022, and the pin 1126 is formed on the side of the drive circuit 1022, such that the pads of the drive backplane is fixedly connected to the pin 1126, and the light-emitting assembly 10 is connected to the drive backplane.

In some embodiments, in the case that the display substrate needs to be manufactured, the size of the second target structure acquired in S402 is larger, and the number of drive circuits is great. That is, a desired product is acquired by selecting an appropriate second target structure.

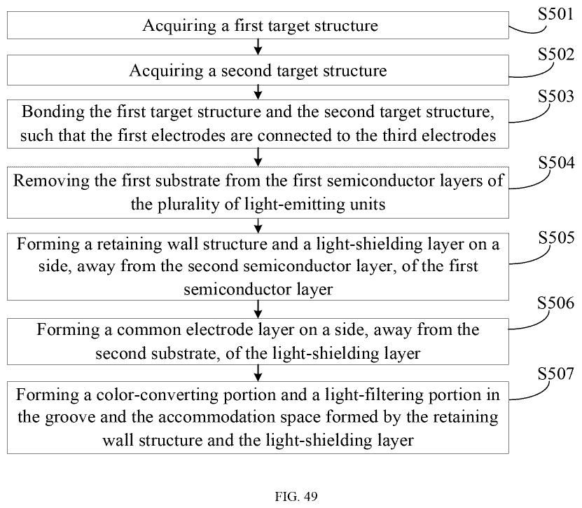

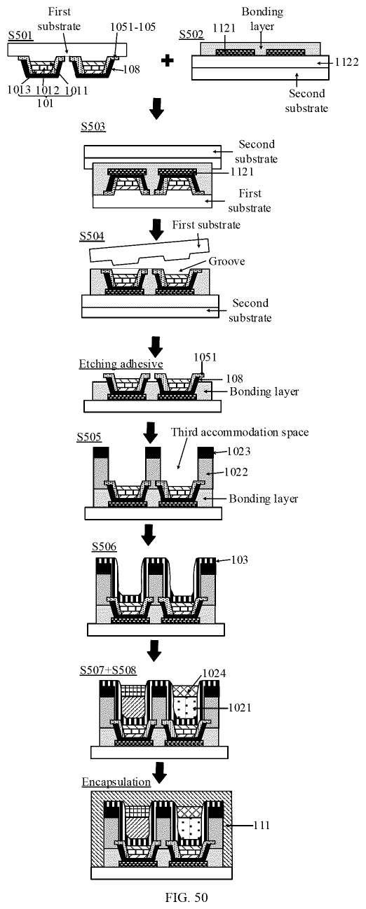

FIG. 49 is a flowchart of a method for manufacturing a light-emitting assembly according to some embodiments of the present disclosure. FIG. 50 is a schematic flowchart of a method for manufacturing a light-emitting assembly according to some embodiments of the present disclosure. FIG. 51 is a top view of a flowchart of some processes in a method for manufacturing a light-emitting assembly according to some embodiments of the present disclosure. Referring to FIG. 49 to FIG. 51, the method includes following processes.

In S501, a first target structure is acquired.

In the embodiments of the present disclosure, the first target structure includes a first substrate, and a plurality of light-emitting units 101, first electrodes 104, a first encapsulation layer 105, and a filling layer 106 that are disposed on the first substrate.

In some embodiments, the process of acquiring the first target structure is the same as that in S401, and for accompanying drawings, reference may be made to FIG. 46 to FIG. 48, which is not described again herein in the embodiments of the present disclosure.

In S502, a second target structure is acquired.

In the embodiments of the present disclosure, for related description of S502, reference may be made to detailed description of S302, which is not described again herein in the embodiments of the present disclosure.

In S503, the first target structure and the second target structure are bonded, such that the first electrodes are connected to the third electrodes.

In the embodiments of the present disclosure, for related description of S503, reference may be made to detailed description of S303, which is not described again herein in the embodiments of the present disclosure.

In S504, the first substrate is removed from the first semiconductor layers of the plurality of light-emitting units.

In the embodiments of the present disclosure, for related description of S504, reference may be made to detailed description of S304, which is not described again herein in the embodiments of the present disclosure.

In S505, a retaining wall structure and a light-shielding layer are formed on a side, away from the second semiconductor layer, of the first semiconductor layer.

In the embodiments of the present disclosure, prior to formation of the retaining wall structure 1022 and the light-shielding layer 1023, the bonding layer 109 on the drive unit 112 is etched to expose part of the blocking portion 108. In the thickness direction of the light-emitting layer 1012, a ratio of an exposed portion of the blocking portion 108 to a height of the blocking portion 108 ranges from 10% to 90%.

In addition, upon etching of the bonding layer 109, part of the first encapsulation layer 105 is exposed. That is, a distance between the face, away from the drive unit 112, of the bonding layer 109 and the drive unit 112 is less than a maximum distance between the first encapsulation layer 105 and the drive unit 112.

Upon etching of the bonding layer 109, the retaining wall structure 1022 and the light-shielding layer 1023 are acquired by a single process, or the retaining wall structure 1022 and the light-shielding layer 1023 are respectively acquired by two processes.

Referring to FIG. 50, at least part of the retaining wall structure 1022 and the light-shielding layer 1023 is disposed between the first encapsulation layer 105 and the bonding layer 109, and covers the sidewall of encapsulation pattern 1051 of the first encapsulation layer 105. As such, the retaining wall structure 1022 and the light-shielding layer 1023 are configured to block light to avoid crosstalk of the light. In addition, the retaining wall structure wraps the sidewall of encapsulation pattern 1051 of the first encapsulation layer 105, and thus the bonding force of the retaining wall structure is improved to ensure the reliability of the retaining wall structure.

In S506, a common electrode layer is formed on a side, away from the second substrate, of the light-shielding layer.

In the embodiments of the present disclosure, prior to formation of the common electrode layer 103, the first semiconductor layer 1011 needs to be shallow etched to wash the face of the first semiconductor layer 1011 and remove impurities on the face of the first semiconductor layer 1011.

Referring to FIG. 50, as the common electrode layer 103 is formed on the side, away from the second substrate, of the light-shielding layer 1023, the common electrode layer 103 is disposed on a slope of the sidewall of the light-shielding layer 1023 and the sidewall of the retaining wall structure 1022, such that a length of the common electrode layer 103 is increased.

Even though the common electrode layer 103 is a shared film layer of a plurality of light-emitting units 101, and light emitted by the light-emitting units 101 may diffract to the common electrode layer 103 to crosstalk to adjacent light-emitting units 101, a crosstalk path of light is increased as the length of the common electrode layer 103 is great in the embodiments of the present disclosure, and thus the possibility of the crosstalk is reduced.

Furthermore, one part of the common electrode layer 103 is disposed in the groove, and the other part of the common electrode layer 103 is disposed outside the groove (that is, disposed above the light-shielding layer 1023). A distance between the portion in the groove and the second substrate is less than a distance between the portion outside the accommodation space and the second substrate. That is, a face, away from the second substrate, of the common electrode layer 103 is a non-flat face.

In S507, a color-converting portion and a light-filtering portion are sequentially formed in the groove and the accommodation space formed by the retaining wall structure and the light-shielding layer.

In the embodiments of the present disclosure, referring to FIG. 50, the color-converting portion 1021 and the light-filtering portion 1024 are sequentially formed in the groove and the accommodation space formed by the retaining wall structure 1022 and the light-shielding layer 1023.

As the color-converting portion 1021 is disposed in the groove, the contact area of the color-converting portion 1021 and the common electrode layer 103 is increased, and the contact bonding force of the color-converting portion 1021 and the common electrode layer 103 is improved to avoid separation of the color-converting portion 1021. In addition, the planarization layer 110 is not disposed in the scheme, and thus the whole thickness of the entire structure is reduced to facilitate achieving the thinning effect.

The color-converting portion 1021 includes a first color-converting portion, a second color-converting portion, and a third color-converting portion. The first color-converting portion converts the light at the first wavelength to light at the second wavelength, the second color-converting portion converts the light at the first wavelength to light at the third wavelength, and the third color-converting portion converts the light at the first wavelength to light at the fourth wavelength.

A color of the light at the second wavelength is red, and the first color-converting portion converts blue light at the first wavelength to red light at the second wavelength. A color of the light at the third wavelength is green, and the second color-converting portion converts blue light at the first wavelength to green light at the third wavelength. A color of the light at the fourth wavelength is blue, and the third color-converting portion converts blue light at the first wavelength to blue light at the fourth wavelength. The first wavelength and the fourth wavelength are equal or different.

Illustratively, assuming that the first wavelength and the fourth wavelength are equal, the first color-converting portion includes red QDs, the second color-converting portion includes green QDs, and the third color-converting portion is a transparent portion, then the transparent portion is configured to transmit the light at the first wavelength emitted by the light-emitting units 101. For example, the transparent portion is made of a transparent OC.

Referring to FIG. 46, the light-filtering portion 1024 includes a first light-filtering portion transmitting the light at the second wavelength, a second light-filtering portion transmitting the light at the third wavelength, and a third light-filtering portion transmitting the light at the fourth wavelength. The first light-filtering portion is a red color resistance block, corresponds to a location of the first color-converting portion, and is configured to transmit red light at the second wavelength converted by the first color-converting portion. The second light-filtering portion is a green color resistance block, corresponds to a location of the second color-converting portion, and is configured to transmit green light at the third wavelength converted by the second color-converting portion. The third light-filtering portion is a blue color resistance block or a transparent portion, corresponds to a location of the third color-converting portion, and is configured to transmit blue light at the fourth wavelength converted by the third color-converting portion.

Eventually, a third encapsulation layer 111 is disposed on a side, away from the second substrate, of the color-converting assembly 102 to encapsulate the light-emitting assembly 10. The third encapsulation layer 111 wraps edges of a plurality of light-emitting units 101, such that the plurality of light-emitting units 101 are whole encapsulated, corrosion of related structures of the light-emitting assembly 10 due to exposure is avoided, and the yield of the light-emitting assembly 10 is ensured.

In some embodiments, the encapsulation layer is made of an inorganic material, for example, a single layer of SiNx, SiOx, AlO3, or TiO, or a laminated later of combination thereof. In addition, the encapsulation layer further includes an organic film layer acquired by an ink-jet printing process.

In the embodiments of the present disclosure, upon bonding of the light-emitting unit to the drive unit, the color-converting assembly is directly formed on the second substrate (the glass substrate) including the drive unit and the light-emitting unit to achieve color display. The massive transfer process is not required in the method, such that the probability of the light leakage from the sidewall and crosstalk leakage between adjacent light-emitting units is reduced, the production efficiency and the yield are improved, and the production cost is reduced.

In addition, the color-converting assembly is formed on the second substrate (the glass substrate) including the drive unit and the light-emitting unit to achieve color display, such that mismatching in bonding the color-converting assembly is avoided. It should be noted that the basic principle of the manufacturing sequence is to first perform the high temperature process and then perform the low temperature process. As the temperature for manufacturing the color-converting assembly is low, and the temperature for manufacturing the drive circuit is high, the color conversion layer and the color film layer are directly formed on the second substrate (the glass substrate) including the drive unit and the light-emitting unit upon formation of the drive unit and bonding of the light-emitting unit to the drive circuit, and the process compatibility is not violated.

In summary, the embodiments of the present disclosure provide a method for manufacturing a light-emitting assembly. The light-emitting assembly includes a plurality of light-emitting units, a color-converting layer, a common electrode layer, first electrodes, and a first encapsulation layer. The color-converting layer is disposed on one side of the light-emitting units, and is configured to convert colors of light emitted by the light-emitting units. The first electrodes are disposed on the other side of the light-emitting units, and are configured to receive drive signals. The first encapsulation layer is configured to encapsulate the light-emitting units to avoid the mutual effect of any adjacent two light-emitting units 101. At least two of the plurality of light-emitting units are connected as an integrated structure, such that the alignment precision of bonding in subsequently bonding process is ensured, and the yield of the products is improved.

In the embodiments of the present disclosure, S501 to S507 may also be used to manufacture the display substrate. In some embodiments, the display substrate is manufactured upon S501 to S507, the second substrate is removed from the side of the drive circuit 1022, and the pin 1126 is formed on the side of the drive circuit 1022, such that the pads of the drive backplane is fixedly connected to the pin 1126, and the light-emitting assembly 10 is connected to the drive backplane.

In some embodiments, in the case that the display substrate needs to be manufactured, the size of the second target structure acquired in S502 is larger, and the number of drive circuits is great. That is, a desired product is acquired by selecting an appropriate second target structure.

In the embodiments of the present disclosure, a shape of the light-emitting assembly acquired in the above five methods may also be in a circular shape (FIG. 9 and FIG. 25), a rectangular shape (FIG. 38, FIG. 39, FIG. 45, and FIG. 51), or in other shapes, which is not limited in the embodiments of the present disclosure.

In addition, accompanying drawings in the embodiments of the present disclosure are illustrated by taking the light-emitting assembly 10 including three circular light-emitting units arranged in a triangular shape as an example, and the embodiments of the present disclosure do not limit the number of light-emitting units in the light-emitting assembly 10, the arrangement and the shape of the light-emitting units.

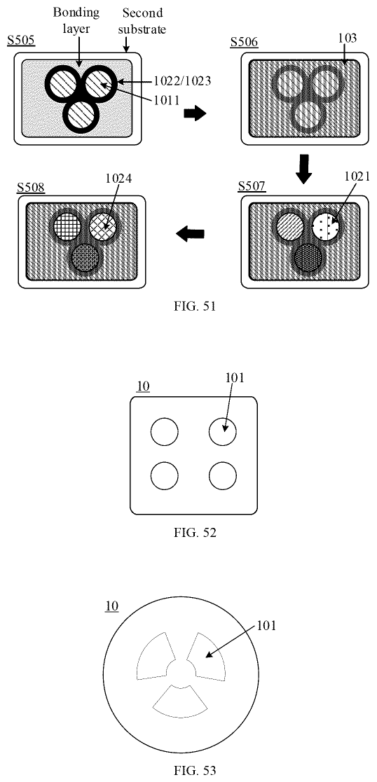

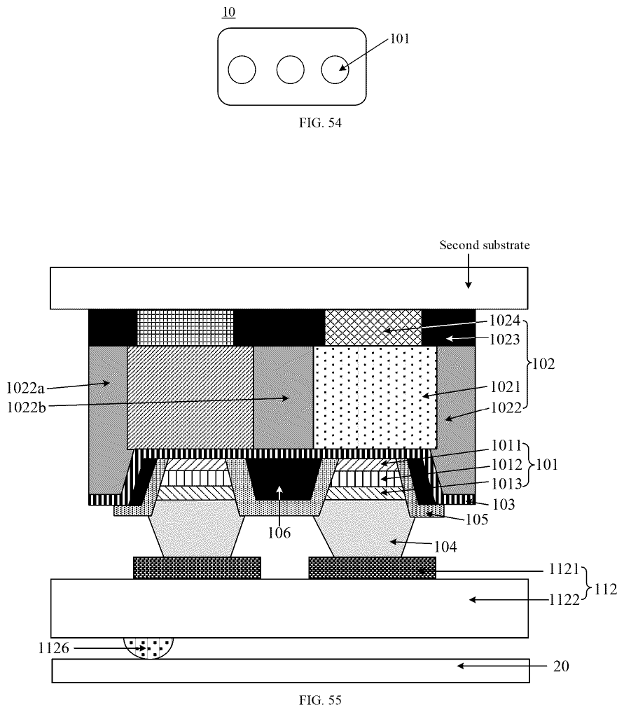

For example, as shown in FIG. 52, the light-emitting assembly 10 includes four circular light-emitting units, and the four light-emitting units are arranged in two rows and two columns. For example, as shown in FIG. 53, the light-emitting assembly 10 includes three fan light-emitting units, and the three light-emitting units are arranged in an annulus shape. For example, as shown in FIG. 53, the light-emitting assembly 10 includes three circular light-emitting units, and the three light-emitting units are arranged in one row.

Furthermore, the shape, the size, and the number of the light-emitting assemblies in the light-emitting chip or the display substrate acquired by the above five methods are not limited in the embodiments of the present disclosure.

Embodiments of the present disclosure further provide a light-emitting chip. The light-emitting chip includes the light-emitting assembly in the above embodiments. An area of an orthographic projection of the light-emitting chip on a light-emitting plane of the light-emitting chip is less than or equal to 1 square millimeter.

Embodiments of the present disclosure further provide a display substrate. The display substrate includes a drive backplane and the light-emitting assemblies shown in FIG. 3 to FIG. 5. The drive backplane is configured to bear the plurality of light-emitting assemblies 10, and supply drive signals to the light-emitting assemblies 10.

In some embodiments, one light-emitting assembly compose a light-emitting chip. The light-emitting chips are arranged in the drive backplane in an array, and are electrically connected to the drive backplane. Alternatively, a plurality of light-emitting assemblies compose a light-emitting chip, and a bonding layer between adjacent light-emitting assemblies is continuous.

Illustratively, the light-emitting chip includes a plurality of light-emitting assemblies arranged in an array, and each of the plurality of light-emitting assemblies composes a pixel. Each pixel includes a red pixel, a green pixel, and a blue pixel.

Embodiments of the present disclosure further provide a display substrate. Referring to FIG. 55, the display substrate 00 includes a drive backplane 20 and a plurality of light-emitting assemblies 10. The display substrate further includes a bonding layer between the common electrode layer and the drive units. At least part of each of the plurality of light-emitting units is disposed in the bonding layer.

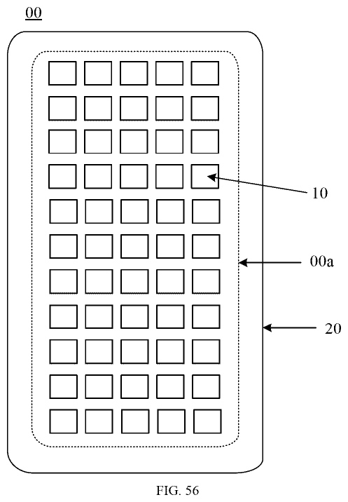

Referring to FIG. 56, the plurality of light-emitting assemblies 10 are disposed in a display region 00a of the display substrate 00, and are arranged in an array. The drive backplane is configured to supply drive signals to the drive units 112 through a plurality of pins 1126 in the plurality of light-emitting assemblies 10, such that the drive units 112 drive the light-emitting units to emit light.

As the display substrate achieves basically the same technical effects as the light-emitting assemblies in the above embodiments, and thus the technical effects of the display device are not repeated herein for brevity.

The terms used in the embodiments of the present disclosure are only intended to explain the embodiments of the present disclosure, rather than to limit the present disclosure. Unless otherwise defined, technical or scientific terms used in the embodiments of the present disclosure shall have ordinary meaning understood by persons of ordinary skill in the art to which the disclosure belongs.

The terms used in the embodiments of the present disclosure are only intended to explain the embodiments of the present disclosure, rather than to limit the present disclosure. Unless otherwise defined, technical or scientific terms used in the embodiments of the present disclosure shall have ordinary meaning understood by persons of ordinary skill in the art to which the disclosure belongs. The terms “first,” “second,” “third,” and the like used in the description and claims of the present disclosure are not intended to indicate any order, quantity or importance, but are merely used to distinguish the different components. Similarly, the terms “a,” “an,” and the like are not intended to limit the quantity, and only represent that at least one exists. The terms “comprise” or “include” and the like are used to indicate that the element or object preceding the terms covers the element or object following the terms and its equivalents, and shall not be understood as excluding other elements or objects. The terms “connect” or “contact” and the like are not intended to be limited to physical or mechanical connections, but may include electrical connections, either direct or indirect connection. The terms “on,” “under,” “left,” and “right” are only used to indicate the relative positional relationship. When the absolute position of the described object changes, the relative positional relationship may change accordingly.

Described above are merely optional embodiments of the present disclosure, and are not intended to limit the present disclosure. Any modifications, equivalent replacements, improvements and the like made within the spirit and principles of the present disclosure should be encompassed within the scope of protection of the present disclosure.

What is claimed is:

1. A light-emitting assembly, comprising:
a plurality of light-emitting units, wherein each of the plurality of light-emitting units comprises a first semiconductor layer, a light-emitting layer, and a second semiconductor layer that are laminated;
a color-converting portion, disposed on a side, away from the light-emitting layer, of the first semiconductor layer;
a common electrode layer, disposed between the first semiconductor layer and the color-converting portion, electrically connected to the first semiconductor layer, and connected to at least two of the plurality of light-emitting units;
first electrodes, disposed on a side, away from the light-emitting layer, of the second semiconductor layer and electrically connected to the second semiconductor layer, the first electrodes being in one-to-one correspondence with the plurality of light-emitting units; and
a first encapsulation layer, at least enclosing sidewalls of the plurality of light-emitting units;
wherein in a thickness direction of the light-emitting layer, a distance between the first electrodes and the common electrode layer is less than a span of the first encapsulation layer in the thickness direction.

2. The light-emitting assembly according to claim 1, further comprising: a color-converting assembly, wherein
the color-converting assembly comprises the color-converting portion;
for each of the plurality of light-emitting units, the first encapsulation layer exposes the first semiconductor layer from a side, facing towards the color-converting portion, of the first semiconductor layer, such that the first semiconductor layer is electrically connected to the common electrode layer; and
a target region is present between the first encapsulation layer and the color-converting assembly, and the light-emitting assembly further comprises a filling layer, wherein the filling layer is disposed in the target region, and a side, close to the color-converting assembly, of the filling layer is coplanar with an end, close to the color-converting assembly, of the first encapsulation layer.

3. The light-emitting assembly according to claim 2, wherein
the filling layer is made of a conductive material, an opening is defined in a portion, between any adjacent two of the plurality of light-emitting units, in the first encapsulation layer, and the filling layer is exposed from the opening; and
the light-emitting assembly further comprises second electrodes, wherein at least part of each of the second electrodes is disposed in the opening, and each of the second electrodes is connected to the common electrode layer via the filling layer exposed from the opening.

4. The light-emitting assembly according to claim 2, wherein
the filling layer comprises a first end face in contact with the common electrode layer and a second end face in contact with a side, away from the color-converting assembly, of the first encapsulation layer, wherein the first end face is coplanar with the end, close to the color-converting assembly, of the first encapsulation layer; and
the filling layer further comprises a first side face, wherein the first side face is in contact with a portion, surrounding each of at least two of the plurality of light-emitting units, in the first encapsulation layer.

5. The light-emitting assembly according to claim 1, further comprising: a color-converting assembly, wherein the color-converting assembly comprises the color-converting portion, and further comprises:
a retaining wall structure, wherein the retaining wall structure defines a plurality of first accommodation spaces, wherein each of the plurality of first accommodation spaces corresponds to a light-emitting region of one of the plurality of light-emitting units, and the color-converting portion is at least disposed in the plurality of first accommodation spaces, and is configured to convert colors of light emitted by the plurality of light-emitting units;
a light-shielding layer, wherein the light-shielding layer defines a plurality of second accommodation spaces, wherein each of the plurality of second accommodation spaces corresponds to one of the plurality of first accommodation spaces; and
a light-filtering portion, wherein the light-filtering portion is at least disposed in the plurality of second accommodation spaces, and is configured to transmit light converted by the color-converting portion;
wherein the retaining wall structure comprises a first portion in an edge region of the plurality of light-emitting units and a second portion between any adjacent two of the plurality of light-emitting units, wherein a height of the second portion is less than a height of the first portion, and a difference between the height of the first portion and the height of the second portion is 10% to 90% of a thickness of each of the plurality of light-emitting units.

6. (canceled)

7. (canceled)

8. The light-emitting assembly according to claim 1, wherein
for each of the plurality of light-emitting units, the second semiconductor layer is exposed from a side, away from the color-converting portion, of the first encapsulation layer, such that the second semiconductor layer is electrically connected to the first electrodes; and
a distance between an end portion, close to the color-converting portion, of the first encapsulation layer and the color-converting portion is less than a distance between a face, close to the color-converting portion, of the first semiconductor layer and the color-converting portion.

9. The light-emitting assembly according to claim 8, wherein a face on the side, away from the color-converting portion, of the first encapsulation layer is coplanar with a side, away from the color-converting portion, of the second semiconductor layer.

10. The light-emitting assembly according to claim 8, further comprising: a blocking portion at least surrounding the sidewall of the each of the plurality of light-emitting units, wherein the blocking portion absorbs or reflects light emitted by the plurality of light-emitting units, and the blocking portion surrounding the sidewall of the each of the plurality of light-emitting units is disposed on a side, away from the plurality of light-emitting units, of the first encapsulation layer.

11. The light-emitting assembly according to claim 10, wherein the blocking portion is made of a metal, and the blocking portion is further disposed on a side, away from the color-converting portion, of the second semiconductor layer and is electrically connected to the second semiconductor layer; wherein
the blocking portion is one of the first electrodes;
the blocking portion is disposed on a side, away from the second semiconductor layer, of the first electrodes, and is electrically connected to the second semiconductor layer over the first electrodes; or
the blocking portion is disposed between the first electrodes and the second semiconductor layer, and is electrically connected to the second semiconductor layer and the first electrodes.

12. The light-emitting assembly according to claim 8, wherein the first encapsulation layer comprises a plurality of separate encapsulation patterns, wherein each of the plurality of encapsulation patterns encloses the sidewall of one of the plurality of light-emitting units.

13. The light-emitting assembly according to claim 8, wherein the common electrode layer comprises a first electrode region and a second electrode region, wherein the first electrode region is disposed in a groove defined by the first encapsulation layer and the first semiconductor layer, and the second electrode region surrounds the first electrode region.

14. The light-emitting assembly according to claim 13, wherein
the light-emitting assembly further comprises a planarization layer between the common electrode layer and the color-converting portion, wherein the planarization layer fills the groove; and
the light-emitting assembly further comprises a color-converting assembly, wherein the color-converting assembly comprises the color-converting portion, and further comprises:
a retaining wall structure, wherein the retaining wall structure defines a plurality of first accommodation spaces, wherein each of the plurality of first accommodation spaces corresponds to a light-emitting region of one of the plurality of light-emitting units, and the color-converting portion is at least disposed in the plurality of first accommodation spaces and is configured to convert colors of light emitted by the plurality of light-emitting units;
a light-shielding layer, wherein the light-shielding layer defines a plurality of second accommodation spaces, wherein each of the plurality of second accommodation spaces corresponds to one of the plurality of first accommodation spaces; and
a light-filtering portion, wherein the light-filtering portion is at least disposed in the plurality of second accommodation spaces, and is configured to transmit light converted by the color-converting portion.

15. The light-emitting assembly according to claim 14, wherein a distance between a face, away from the common electrode layer, of the planarization layer and the first electrodes is greater than or equal to the span of the first encapsulation layer in the thickness direction, and in the thickness direction of the light-emitting layer, a ratio h3:h4 of the distance h3 between the first electrodes and the common electrode layer to the span h4 of the first encapsulation layer in the thickness direction ranges from 0.1 to 0.9.

16. The light-emitting assembly according to claim 13, wherein at least part of the color-converting portion is disposed in the groove, and is disposed on a side, away from the plurality of light-emitting units, of the common electrode layer.

17. The light-emitting assembly according to claim 16, further comprising: a color-converting assembly, wherein the color-converting assembly comprises the color-converting portion, and further comprises:
a retaining wall structure, wherein the retaining wall structure defines a plurality of first accommodation spaces, wherein each of the plurality of first accommodation spaces corresponds to a light-emitting region of one of the plurality of light-emitting units, and the color-converting portion is at least disposed in the plurality of first accommodation spaces, and is configured to convert colors of light emitted by the plurality of light-emitting units;
a light-shielding layer, wherein the light-shielding layer defines a plurality of second accommodation spaces, wherein each of the plurality of second accommodation spaces corresponds to one of the plurality of first accommodation spaces; and
a light-filtering portion, wherein the light-filtering portion is at least disposed in the plurality of second accommodation spaces, and is configured to transmit light converted by the color-converting portion.

18. The light-emitting assembly according to claim 12, wherein
the common electrode layer comprises a first electrode region and a second electrode region, wherein the first electrode region is disposed in a groove defined by the first encapsulation layer and the first semiconductor layer, and the second electrode region surrounds the first electrode region;
at least part of the color-converting portion is disposed in the groove, and is disposed on a side, away from the plurality of light-emitting units, of the common electrode layer; and
the light-emitting assembly comprises the a color-converting assembly, wherein the color-converting assembly comprises the color-converting portion, and further comprises:
a retaining wall structure, wherein the retaining wall structure defines a plurality of first accommodation spaces, wherein each of the plurality of first accommodation spaces corresponds to a light-emitting region of one of the plurality of light-emitting units, and the color-converting portion is at least disposed in the plurality of first accommodation spaces, and is configured to convert colors of light emitted by the plurality of light-emitting units;
a light-shielding layer, wherein the light-shielding layer defines a plurality of second accommodation spaces, wherein each of the plurality of second accommodation spaces corresponds to one of the plurality of first accommodation spaces; and
a light-filtering portion, wherein the light-filtering portion is at least disposed in the plurality of second accommodation spaces, and is configured to transmit light converted by the color-converting portion;
wherein the retaining wall structure wraps edges of the plurality of encapsulation patterns, and the common electrode layer is disposed between the retaining wall structure and the color-converting portion.

19. (canceled)

20. The light-emitting assembly according to claim 5, wherein
the color-converting portion comprises a red color-converting portion, a green color-converting portion, and a blue color-converting portion, wherein the red color-converting portion is configured to convert the light emitted by the plurality of light-emitting units to red light, the green color-converting portion is configured to convert the light emitted by the plurality of light-emitting units to green light, and the blue color-converting portion is configured to convert the light emitted by the plurality of light-emitting units to blue light; and
the light-filtering portion comprises a red light-filtering portion, a green light-filtering portion, and a blue light-filtering portion, wherein the red light-filtering portion is configured to transmit light converted by the red color-converting portion, the green light-filtering portion is configured to transmit light converted by the green color-converting portion, and the blue light-filtering portion is configured to transmit light converted by the blue color-converting portion;
wherein the light emitted by the plurality of light-emitting units is blue light, the blue color-converting portion is a transparent portion, and the blue light-filtering portion is a transparent portion.

21. The light-emitting assembly according to claim 5, wherein the retaining wall structure is made of a non-transparent material.

22. (canceled)

23. (canceled)

24. (canceled)

25. A display substrate, comprising: a drive backplane and a plurality of light-emitting assemblies as defined in claim 21, wherein
each of the plurality of light-emitting assemblies comprises:
a plurality of light-emitting units, wherein each of the plurality of light-emitting units comprises a first semiconductor layer, a light-emitting layer, and a second semiconductor layer that are laminated;
a color-converting portion, disposed on a side, away from the light-emitting layer, of the first semiconductor layer;
a common electrode layer, disposed between the first semiconductor layer and the color-converting portion, electrically connected to the first semiconductor layer, and connected to at least two of the plurality of light-emitting units;
first electrodes, disposed on a side, away from the light-emitting layer, of the second semiconductor layer and electrically connected to the second semiconductor layer, the first electrodes being in one-to-one correspondence with the plurality of light-emitting units;
a first encapsulation layer, at least enclosing sidewalls of the plurality of light-emitting units; and
a color-converting assembly, wherein the color-converting assembly comprises the color-converting portion and further comprises: a retaining wall structure, wherein the retaining wall structure defines a plurality of first accommodation spaces, wherein each of the plurality of first accommodation spaces corresponds to a light-emitting region of one of the plurality of light-emitting units, and the color-converting portion is at least disposed in the plurality of first accommodation spaces, and is configured to convert colors of light emitted by the plurality of light-emitting units; a light-shielding layer, wherein the light-shielding layer defines a plurality of second accommodation spaces, wherein each of the plurality of second accommodation spaces corresponds to one of the plurality of first accommodation spaces; and a light-filtering portion, wherein the light-filtering portion is at least disposed in the plurality of second accommodation spaces, and is configured to transmit light converted by the color-converting portion; wherein
the retaining wall structure comprises a first portion in an edge region of the plurality of light-emitting units and a second portion between any adjacent two of the plurality of light-emitting units, wherein a height of the second portion is less than a height of the first portion, and a difference between the height of the first portion and the height of the second portion is 10% to 90% of a thickness of each of the plurality of light-emitting units;
the retaining wall structure is made of a non-transparent material; and
in a thickness direction of the light-emitting layer, a distance between the first electrodes and the common electrode layer is less than a span of the first encapsulation layer in the thickness direction;
the drive backplane is configured to bear the plurality of light-emitting assemblies, and supply drive signals to the plurality of light-emitting assemblies; and
one of the plurality of light-emitting assemblies composes a light-emitting chip, wherein light-emitting chips are arranged on the drive backplane in an array, and are electrically connected to the drive backplane; or some of the plurality of light-emitting assemblies compose a light-emitting chip, and a bonding layer between adjacent light-emitting assemblies in the plurality of light-emitting assemblies is continuous.

26. A display substrate, comprising: a drive backplane and a plurality of light-emitting assemblies, wherein
each of the plurality of light-emitting assemblies comprises: a plurality of light-emitting units, wherein each of the plurality of light-emitting units comprises a first semiconductor layer, a light-emitting layer, and a second semiconductor layer that are laminated; a color-converting portion, disposed on a side, away from the light-emitting layer, of the first semiconductor layer; a common electrode layer, disposed between the first semiconductor layer and the color-converting portion, electrically connected to the first semiconductor layer, and connected to at least two of the plurality of light-emitting units; first electrodes, disposed on a side, away from the light-emitting layer, of the second semiconductor layer and electrically connected to the second semiconductor layer, the first electrodes being in one-to-one correspondence with the plurality of light-emitting units; and a first encapsulation layer, at least enclosing sidewalls of the plurality of light-emitting units; wherein in a thickness direction of the light-emitting layer, a distance between the first electrodes and the common electrode layer is less than a span of the first encapsulation layer in the thickness direction; and
the drive backplane is configured to bear the plurality of light-emitting assemblies, and supply drive signals to the plurality of light-emitting assemblies.

27-36. (canceled)
